(19) United States
(12) Patent Application Publication
(10) Pub. No.: US 2026/0278209 A1
(43) Pub. Date: Sep. 17, 2026

(54) METHODS AND SYSTEMS FOR AUTOMATED SIMULATION ACTIVITY AND SYNTHETIC DATA GENERATION

(71) Applicant: NVIDIA Corporation, Santa Clara, CA (US)

(72) Inventors: Akul Santhosh, Santa Clara, CA (US); Shenxin Jiang, Santa Clara, CA (US); Xunlei Wu, Cary, NC (US); Yilin Zhao, Los Altos, CA (US); Arnav Chandra Komaragiri, San Jose, CA (US)

(21) Appl. No.: 19/080,691

(22) Filed: Mar. 14, 2025

(51) Int. Cl. G06F 30/27; A63F 13/57

(52) U.S. Cl. CPC G06F 30/27; A63F 13/57

(57) ABSTRACT

Apparatuses, systems, and techniques for automated activity simulation and synthetic data generation are provided. A first action associated with an asset in an environment in accordance with a simulation of the asset in the environment is detected. Short-term historical data associated with the asset is identified. The short-term historical data includes first prior simulation events of the simulation and associated with the asset that occurred during a first time period. Second prior simulation events of the simulation and associated with at least one of the first action or an additional asset in the environment is determined based on long-term historical data including simulation events associated with assets of the environment that occurred during a second time period. A simulation command for a second action associated with the asset in accordance with the simulation is generated based on the first prior simulation events and the second prior simulation events.

### TECHNICAL FIELD

At least one embodiment pertains to methods and systems for automated activity simulation and synthetic data generation. For example, an artificial intelligence (AI) model can predict an action to be performed with respect to an asset in an environment based on short-term historical data associated with the asset and long-term historical data associated with the environment. The AI model can additionally or alternatively generate a simulation command that, when executed, performs the predicted action.

### BACKGROUND

Simulations can be used for large-scale scene understanding of environments involving real-world objects (e.g., humans) by creating a virtual representation of real-world scenarios. An open-ended simulation refers to a type of simulation where scenarios evolve dynamically based on complex interactions, rather than following a predefined script. Such type of simulations can be useful for testing decision-making in environments where human behavior and external factors are unpredictable. It can be difficult for simulation designers and developers to manually craft realistic simulations that accurately reflect real-world scenarios.

### BRIEF DESCRIPTION OF DRAWINGS

Various embodiments in accordance with the present disclosure will be described with reference to the drawings, in which:

FIG. 1 is a block diagram of an example system architecture, according to at least one embodiment;

FIG. 2 is a block diagram of an example asset management engine, according to at least one embodiment;

FIG. 3 is a block diagram of an example simulation component, an example asset memory component, and an example asset command component, according to at least one embodiment;

FIG. 4 depicts an example method of generating a simulation command for an action associated with an asset, according to at least one embodiment;

FIG. 5 depicts an example method of modifying a scene of a simulation, according to at least one embodiment;

FIG. 6 depicts an example method of performing simulation operations to simulation an action with respect to an asset, according to at least one embodiment;

FIG. 7 depicts an example method of generating a rendering of actions pertaining to assets of a simulation, according to at least one embodiment;

FIG. 8A-8B depict an example graphical user interface, according to at least one embodiment;

FIG. 9 is a block diagram of an example predictive system, according to at least one embodiment;

FIG. 10 depicts an example method of performing robotic operations to cause a robotic component to perform an action predicted by an AI model, according to at least one embodiment;

FIG. 11A illustrates inference and/or training logic, according to at least one embodiment;

FIG. 11B illustrates inference and/or training logic, according to at least one embodiment;

FIG. 12 illustrates an example data center system, according to at least one embodiment;

FIG. 13 illustrates a computer system, according to at least one embodiment;

FIG. 14 illustrates a computer system, according to at least one embodiment;

FIG. 15 illustrates at least portions of a graphics processor, according to one or more embodiments;

FIG. 16 illustrates at least portions of a graphics processor, according to one or more embodiments;

FIG. 17 is an example data flow diagram for an advanced computing pipeline, in accordance with at least one embodiment;

FIG. 18 is a system diagram for an example system for training, adapting, instantiating and deploying machine learning models in an advanced computing pipeline, in accordance with at least one embodiment;

FIGS. 19A and 19B illustrate a data flow diagram for a process to train a machine learning model, as well as client-server architecture to enhance annotation tools with pre-trained annotation models, in accordance with at least one embodiment;

FIG. 20A illustrates an example of an autonomous vehicle, according to at least one embodiment;

FIG. 20B illustrates an example of camera locations and fields of view for the autonomous vehicle of FIG. 20A, according to at least one embodiment;

FIG. 20C illustrates an example system architecture for the autonomous vehicle of FIG. 20A, according to at least one embodiment; and

FIG. 20D illustrates a system for communication between cloud-based server(s) and the autonomous vehicle of FIG. 20A, according to at least one embodiment.

### DETAILED DESCRIPTION

Embodiments of the present disclosure relate to methods and systems for automated activity simulation and synthetic data generation. An online platform can provide users with tools to create, simulate, and visualize complex virtual environments. Such platform can enable users to define a scene and/or objects of a scene for simulation in a virtual environment and can execute the simulation of the user-defined scene (e.g., using computing resources of the platform). In some instances, the simulation can involve or otherwise include open-ended tasks performed with respect to the objects of the scene, where objects interact with other objects, terrain, changing circumstances, etc. according to the simulation. Conventionally, a user manually defines actions or activities for each object of the scene, including a set of possible reactions of a respective object (e.g., in response to an action or activity of another object). In an illustrative example, a simulation can involve a simulated warehouse environment including virtual objects representing objects that would be in a real-world warehouse environment (e.g., shelving, boxes, equipment, etc.) and/or virtual avatars or non-playable characters (NPCs) representing humans that would work in the real-world warehouse environment. A user defining such a simulation would define the traits, actions, and reactions of each virtual object, virtual avatar, and/or NPC (referred to collectively as “virtual assets”) within the simulated environment, including but not limited to, locations where the virtual asset may be located in the simulated environment, how the virtual asset may move around in the simulated environment, how the virtual asset may react to changes or interruptions of the scene of the simulated environment, how the virtual asset may act or react to other virtual assets in the simulated environment, and so forth.

It can be difficult and/or time consuming for a user to manually define each possible action or activity that can occur with respect to each virtual asset of a scene in a simulated environment. In some instances, a user is not able to conceive each possible action or scenario that could occur in the simulated environment. Therefore, the simulation and/or the outcome of the simulation may not be an accurate or realistic representation of the scene in a real-world environment. In light of this, it can take a significant amount of time for a user to define and/or refine the actions or activities of the virtual assets, which can involve multiple runs or executions of the simulation (e.g., until the user is satisfied with the activity in the simulated scene). Each run or execution of a simulation can consume a significant amount of computing resources (e.g., processing cycles, memory space, network bandwidth), and running or executing the simulation multiple times can consume even an even larger amount of computing resources. Such consumption makes the computing resources unavailable to other processes of the platform and/or a system including the platform, which can increase an overall latency and decrease an overall efficiency of the system.

Further, some platforms or systems can offer additional tools and resources to users, including tools and resources to perform tasks associated with an artificial intelligence (AI) model. In an illustrative example, an online platform (or a system including the online platform) can provide users with access to tools and resources relating to tasks such as image detection, image or environment understanding, etc., which can be performed using one or more AI models (e.g., image detection models, image understanding models, etc.). A scene of a simulated environment can include visual details and information that would be useful for training AI models to perform such tasks. However, conventional systems do not offer techniques to provide data or information associated with a simulated environment that is in a format suitable for training AI models to perform such tasks, without using or accessing additional AI models or other system components to obtain such data or information. For example, to obtain data or information associated with visual details of a simulated scene for training an AI model, techniques of conventional systems involve providing an image or a 3D model representing the simulated scene as an input to one or more additional AI models (e.g., image understanding models, image captioning models, etc.) and obtaining additional data to be used for training the AI model (e.g., a description of the scene of the image or 3D model, a caption representing a visual detail of the image or 3D model) based on one or more outputs of the additional AI models. Using or accessing such additional AI models can consume a significant amount of computing resources which are unavailable to other processes of the system, further increasing of the overall latency and decreasing the overall efficiency of the system.

Embodiments of the present disclosure address the above and other deficiencies by providing AI-based techniques for automated activity simulation and synthetic data generation. A platform can provide one or more tools or resources to enable a user to create or otherwise access a simulation of a scene in an environment. Each virtual asset (e.g., virtual object, virtual avatar, NPC, etc.) of the simulation can be supported by a designated simulation agent of the platform, which interfaces with multiple subsystems that predict actions to be performed by or with respect to the virtual asset, generate simulation commands associated with the predicted actions and execute the generated simulation commands in accordance with the simulation. Such subsystems can include a simulation subsystem (e.g., responsible for initiating requests for a simulation command to perform an action associated with a virtual asset and executing generated simulation commands for the requested action), a memory subsystem (e.g., responsible for storing and/or retrieving data or information associated with a particular virtual asset and/or a simulated scene), and a command subsystem (e.g., responsible for predicting actions associated with a virtual asset and generating simulation commands for the predicted actions).

In some embodiments, the platform can provide the user with access to a graphical user interface (GUI) (e.g., via a client device of the user), which enables the user to provide information associated with a simulation to be run or otherwise executed using computing resources (e.g., processing devices, memory resources, etc.) of the platform. Such information can include, for example, an indication of an environment (e.g., an overall context or condition) of the simulation, a scene (e.g., an arrangement of assets in the environment and/or interactions between such assets) of the simulation, and/or one or more virtual assets of the scene. A virtual asset can include a virtual object, a virtual avatar (e.g., which is controllable by the user during the simulation) or a non-playable character (e.g., which is not controllable by the user during the simulation). In some embodiments, the user can provide a natural language user query via the GUI, which includes the indication of the simulation environment, the simulation scene, and/or the one or more virtual assets of the simulation scene. In accordance with embodiments described herein, the platform can provide a prompt associated with the natural language query as an input to an AI model (e.g., a large language model (LLM)) and obtain one or more outputs of the AI model, which include one or more simulation operations associated with a set of actions pertaining to the virtual assets, in accordance with the simulation information of the natural language query. The platform can perform the one or more simulation operations to generate a rendering of the set of actions in accordance with the simulation and can present the generated rendering of the set of actions to the client device of the user to provide the user with access to the simulation. In other or similar embodiments, the user can provide one or more model files to the platform (e.g., via the GUI of the client device), which include or otherwise define the set of actions pertaining to the virtual assets and the platform can execute the provided model files to generate the rendering of the set of actions, as described herein.

As described herein, a simulation agent can be allocated to each respective virtual asset of the simulation (e.g., during initialization of the simulation). During execution of the simulation, the simulation agent for a respective virtual asset can detect an action associated with the virtual asset. In an illustrative example, the simulated environment can be a virtual warehouse and a virtual asset can include a worker in the virtual warehouse. The simulation agent for the worker can detect that a virtual object, such as a box, has fallen from a shelf in the virtual warehouse within the vicinity of the worker, which can correspond to a detected action associated with the worker. The simulation agent for the virtual asset can provide information pertaining to the detected action to the simulation subsystem and the simulation subsystem can generate a request for a simulation command to perform an action associated with the virtual asset (e.g., in response to the box falling from the shelf). The simulation subsystem can generate the request and can forward the request to the command subsystem, which obtains information associated with the simulation environment and/or the simulation scene and information associated with prior actions or activities associated with the virtual asset and/or other virtual assets of the simulation. Information associated with the simulation environment can include, for example, an indication of a state or context of the simulation environment (e.g., “the simulation environment represents a virtual warehouse”), a state or context of the simulation scene (e.g., “the simulated scene depicts objects on shelves and workers moving around the warehouse,” “a box fell from the shelf in the warehouse”), and other such information. In some embodiments, the command subsystem can obtain the information associated with the simulated environment and/or the simulated scene from a long-term historical data structure maintained by the memory subsystem, as described below. The command subsystem can obtain information associated with the actions or activities of the virtual asset(s) from the long-term historical data structure and/or a short-term historical data structure maintained by the memory subsystem, as described below.

The short-term historical data structure of the memory subsystem can store short-term historical data that indicates prior simulation events (e.g., actions or activities) associated with the virtual assets of the simulation. Such short-term historical data can indicate prior simulation events that occurred during a recent time period. The long-term historical data structure of the memory subsystem can store long-term historical data that indicates prior simulation events associated with the virtual assets that occurred during a time period beyond the recent time period. During the simulation, the memory subsystem can continuously update the short-term historical data structure and the long-term historical data structure to include short-term historical data and long-term historical data, respectively, both of which represent “memories” of the virtual asset throughout the simulation. The command subsystem can provide the memory subsystem with an indication of the virtual asset for which the action was detected and the obtained information associated with the simulated environment and/or the simulated scene. The memory subsystem can identify short-term historical data from the short-term historical data structure that is associated with the virtual asset and provide the identified short-term historical data to the command subsystem. The memory subsystem can identify long-term historical data from the long-term historical data structure that indicate prior simulation events that are relevant to the state or context of the simulated environment and/or the simulated scene. In some embodiments, the memory subsystem can provide the state or context of the simulated environment and/or the simulated scene as an input to a simulation event relevance model that is trained to identify long-term historical data that is relevant to a given state or context. The memory subsystem can obtain one or more outputs of the simulation event relevance model, which can include an indication of long-term historical data that is relevant to the state or context of the simulated environment and/or the simulated scene. The memory subsystem can provide the indicated long-term historical data to the command subsystem (e.g., with the identified short-term historical data).

The command subsystem can generate a prompt based on the state or context of the simulated environment/scene, the short-term historical data, and the long-term historical data and can provide the generated prompt as an input to a command generation AI model. The command generation AI model can be trained to generate simulation commands for actions or activities to be performed with respect to one or more virtual assets of a simulation based on given state or context data and given historical data. The command subsystem can obtain one or more outputs of the command generation AI model, which can indicate one or more actions to be performed with respect to the virtual asset (e.g., the worker) and one or more simulation operations associated with the action. At least one of the one or more simulation operations can include a simulation command that, when executed, simulates the indicated action with respect to the virtual asset. In accordance with the previous illustrative example, the short-term historical data for the worker can include recent actions of the worker and the long-term historical data for the environment/scene can indicate another box that previously fell from another shelf in the virtual warehouse. The action indicated by the one or more outputs of the command generation AI model can include the worker picking up the fallen box and putting it back on the shelf, and the one or more simulation operations can include commands to simulate the worker performing these actions.

The command subsystem can provide the one or more simulation operations to the simulation subsystem and the simulation subsystem can execute the commands of the simulation operation(s), in some embodiments. By executing the commands, the simulation subsystem can simulate the performance of the action with respect to the virtual asset and can provide a rendering of the simulated performance to the client device of the user, in some embodiments. In some embodiments, the simulation subsystem can transmit requests for simulation commands for actions associated with multiple virtual assets of the simulation (e.g., at or around the same time period). The command subsystem can provide the simulation operations including such simulation commands, as described above, and the simulation subsystem can add each simulation command to a command queue according to a particular order or execution. Thus, embodiments of the present disclosure enable coordinated actions or activities of virtual assets of a simulation, which can make the simulation more accurate and realistic.

As indicated above, the output(s) of the command generation model can include an indication of an action to be performed with respect to the virtual asset. In some embodiments, the indication can include a natural language description of the action. The platform can obtain one or more images or a 3D model representing the performance of the action and can use the obtained one or more images/3D model with the natural language description of the action to train another AI model to perform other tasks, such as image detection, image or environment understanding, etc. For example, the platform (or another component or entity of a system that includes the platform) can generate a training input that includes the one or more images/3D model and a target output including the natural language description of the action depicted by the image(s)/3D model, and can include the generated training input and the target output in a training data set for training the AI model to perform the image detection and/or image or environment understanding tasks.

Aspects and embodiments of the present disclosure provide techniques to enable simulation systems to predict actions or activities of virtual assets of a simulation based on historical data collected for the virtual assets and/or the scene or environment of the simulation. Therefore, the actions and/or activities of the virtual assets can be accurate or realistic to actions and/or activities of objects, humans, etc., in a real-world environment, which increases the overall accuracy of the simulation. In light of this, fewer computing resources (e.g., processing cycles, memory space, etc.) are consumed in defining and executing the simulation, and such computing resources are made available to other processes of the system, which increases the overall efficiency and decreases the overall latency of the system.

Further, as described herein, AI model(s) that predict actions and/or activities corresponding to virtual assets of a simulation can provide a natural language description representing the predicted action or activity, which can be used in training data for training other types of AI models. Such natural language description can be used as synthetic data for training a machine learning model to perform tasks for which real-world data is expensive or impractical to collect. This can increase the amount of training data that is available for training such types of AI models without consuming additional computing resources to obtain such training data, which therefore increases the accuracy of such AI models and further reduces the overall amount of computing resources consumed by the system.

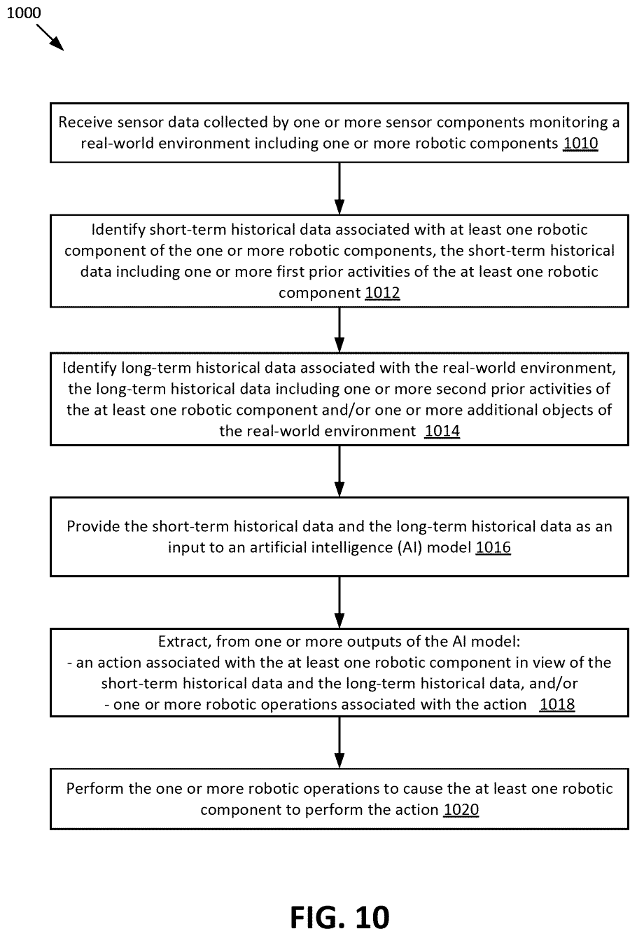

It should be noted that although some embodiments of the present disclosure are described with respect to virtual assets of a simulated environment, such embodiments can also be applied with respect to robotic components in a real-world environment. For example, embodiments of the present disclosure can be applied to perform robotic operations to cause a robotic component of a real-world environment to perform an action predicted by an AI model based on short-term historical data associated with the robotic component and long-term historical data associated with the robotic component and/or other objects (e.g., other robotic components, etc.) of the real-world environment. Further details regarding such embodiments are provided with respect to FIG. 10, and described elsewhere herein.

The systems and methods described herein may be used for a variety of purposes. By way of example and without limitation, these purposes may include systems or applications for online multiplayer gaming, machine control, machine locomotion, machine driving, synthetic data generation, model training, perception, augmented reality, virtual reality, mixed reality, robotics, security and surveillance, autonomous or semi-autonomous machine applications, deep learning, environment simulation, data center processing, conversational AI, light transport simulation (e.g., ray tracing, path tracing, etc.), collaborative content creation for 3D assets, digital twin systems, cloud computing and/or any other suitable applications.

Disclosed embodiments may be comprised in a variety of different systems such as systems for participating on online gaming, automotive systems (e.g., a control system for an autonomous or semi-autonomous machine, a perception system for an autonomous or semi-autonomous machine), systems implemented using a robot, aerial systems, medial systems, boating systems, smart area monitoring systems, systems for performing deep learning operations, systems for performing simulation operations, systems implemented using an edge device, systems incorporating one or more virtual machines (VMs), systems for performing synthetic data generation operations, systems implemented at least partially in a data center, systems for performing conversational AI operations, systems for performing light transport simulation, systems for performing collaborative content creation for 3D assets, systems for generating or maintaining digital twin representations of physical objects, systems implemented at least partially using cloud computing resources, and/or other types of systems.

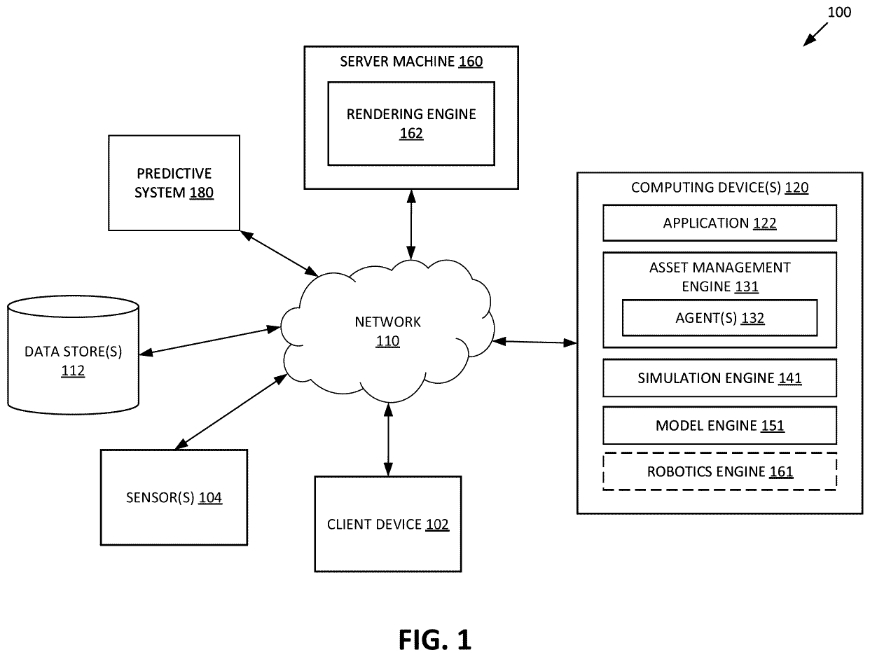

FIG. 1 is a block diagram of an example system architecture 100, according to at least one embodiment. The system architecture 100 (also referred to as “system” herein) may include a client device 102, one or more sensor(s) 104 (collectively referred to as sensors 104), one or more data stores 112 (collectively and individually referred to as data store 112), one or more computing device(s) 120 (collectively and individually referred to as computing device 120), one or more server machines (e.g., server machine 160), and/or a predictive system 180, each connected to a network 110. In implementations, network 110 may include a public network (e.g., the Internet), a private network (e.g., a local area network (LAN) or wide area network (WAN)), a wired network (e.g., Ethernet network), a wireless network (e.g., an 802.11 network or a Wi-Fi network), a cellular network (e.g., a Long Term Evolution (LTE) network), routers, hubs, switches, server computers, and/or a combination thereof.

Computing device 120 may be a desktop computer, a laptop computer, a smartphone, a tablet computer, a server, or any suitable computing device capable of performing the techniques described herein. In some embodiments, computing device 120 may be a component of or otherwise associated with a cloud computing platform, a three-dimensional (3D) graphics collaboration platform, or any other such type of platform. For example, computing device 120 may be, or may be a component of, a server machine of a cloud computing platform. In such embodiments, computing device 120 may be coupled to one or more edge devices (not shown) via network 110. An edge device refers to a computing device that enables communication between computing devices at the boundary of two networks. For example, an edge device may be connected to computing device 120, client device 102, data store 112, sensors 104, server machine 160, and/or predictive system 180 via network 110, and may be connected to one or more endpoint devices (not shown) via another network. In such example, the edge device can enable communication between computing device 120, data store 112, server machine 160, and/or predictive system 180 and the one or more endpoint devices. In other or similar embodiments, computing device 120 may be, or may be a component of, an edge device. For example, computing device 120 may facilitate communication between data store 112, client device 102, server machine 160, and/or predictive system 180, which are connected to computing device 120 via network 110, and one or more endpoint devices that are connected to computing device 120 via another network.

In still other or similar embodiments, computing device 120 may be, or may be a component of, an endpoint device. For example, computing device 120 may be, or may be a component of, devices, such as, but not limited to: televisions, smart phones, cellular telephones, personal digital assistants (PDAs), portable media players, netbooks, laptop computers, electronic book readers, tablet computers, desktop computers, set-top boxes, gaming consoles, autonomous vehicles, surveillance devices, and the like. In such embodiments, computing device 120 may be connected to data store 112, client device 102, server machine 160, and/or predictive system 180 via network 110. In other or similar embodiments, computing device 120 may be connected to an edge device (not shown) of system 100 via a network and the edge device of system 100 may be connected to data store 112, client device 102, server machine 160, and/or predictive system 180 via network 110. In yet other or similar embodiments, computing device 120 may be a component of client device 102.

The client devices 102A-N (collectively and individually referred to as client device(s) 102 herein) may each include computing devices such as personal computers (PCs), laptops, mobile phones, smart phones, tablet computers, netbook computers, network-connected televisions, etc. In other or similar embodiments, client devices 102A-N can include or be connected to a virtual reality (VR) device (e.g., a VR headset) that is configured to provide a VR experience to a user of computing device 120. The VR device can be a monolithic VR device (e.g., a VR headset that includes a dedicated processor and/or power source) or another type of VR device, in some embodiments. In some implementations, client devices 102A-N may also be referred to as “user devices.” Each client device may include a content viewer. In some implementations, a content viewer may be an application that provides a user interface (UI) for users to view or upload content, such as images, video items, web pages, documents, etc. For example, the content viewer may be a web browser that can access, retrieve, present, and/or navigate content (e.g., web pages such as Hyper Text Markup Language (HTML) pages, digital media items, etc.) served by a web server. The content viewer may render, display, and/or present the content to a user. The content viewer may also include an embedded media player (e.g., a Flash® player or an HTML5 player) that is embedded in a web page (e.g., a web page that may provide information about a product sold by an online merchant). In another example, the content viewer may be a standalone application (e.g., a mobile application or app) that allows users to view digital media items (e.g., digital video items, digital images, electronic books, etc.).

Sensors 104 can be configured to generate data, such as visual data, audio data, etc., associated with an environment. The sensors can include an image sensor (e.g., a camera), a light detection and ranging (LIDAR) sensor, a radio detection and ranging (RADAR) sensor, sound navigation and ranging (SONAR) sensor, an ultrasonic sensor, a microphone, and other sensor types. In some embodiments, the data collected and/or generated by the sensors may represent a perception of the environment by the sensors. It should be noted that although some embodiments of the present disclosure are directed to image data (e.g., an image) generated by one or more sensors 104, embodiments of the present disclosure may be applied to any type of data generated by sensors 104 (e.g., LIDAR data, RADAR data, SONAR data, ultrasonic data, audio data, etc.).

In some embodiments, sensors 104 may be a component of, or may be otherwise connected to, computing device 120 and/or client device 102. For example, as described above, computing device 120 may be, or may be a component of, an endpoint device. In such embodiments, sensor 104 may be a camera component of computing device 120 that is configured to generate an image and/or video data associated with the environment. In other or similar embodiments, sensor 104 may be a device, or a component of or otherwise connected to a device that is separate and distinct from computing device 120. For example, as described above, computing device 120 may be, or may be a component of, a cloud computing platform or an edge device. In such embodiments, sensor 104 may be a device (e.g., a surveillance camera, a device of an autonomous vehicle, etc.) that is connected to computing device 120, data store 112, client device 102, server machine 160, and/or predictive system 180 via network 110 or another network.

In some implementations, data store 112 is a persistent storage that is capable of storing content items (e.g., images) and data associated with the stored content items (e.g., object data, image metadata, etc.) as well as data structures to tag, organize, and index the content items and/or object data. Data store 112 may be hosted by one or more storage devices, such as main memory, magnetic or optical storage based disks, tapes or hard drives, NAS, SAN, and so forth. In some implementations, data store 112 may be a network-attached file server, while in other embodiments data store 112 may be some other type of persistent storage such as an object-oriented database, a relational database, and so forth, that may be hosted by computing device 120 or one or more different machines coupled to the computing device 120 via network 110 or another network.

Data store 112 may be or may include a domain-specific or organization-specific repository or data base. In some embodiments, computing device 120, client device 102, sensors 104, server machine 160, and/or predictive system 180 may only be able to access data store via network 110, which may be a private network. In other or similar embodiments, data stored at data store 112 may be encrypted and may be accessible to computing device 120, client device 102, sensors 104, server machine 160, and/or predictive system 180 via an encryption mechanism (e.g., a private encryption key, etc.). In additional or alternative embodiments, data store 112 may be a publicly accessible data store that is accessible to any device via a public network.

In some embodiments, computing device 120 can provide users (e.g., of client devices 102) with access to one or more applications 122. In some embodiments, users of computing device 120 can access the features and functionalities of application 122 via an application instance running using a client device 102. An application instance refers to a collection or grouping of resources used to execute features and functionalities of application 122 via client device 102. In an illustrative example, an application instance can include a portion or segment of instructions (e.g., code) associated with application 122 that is executed by computing resources of client device 102 to provide a user with access to the features or functionalities of application 122. Multiple client devices 102 can execute the instructions to provide respective users with access to the application 122 (e.g., simultaneously). Each instance of application 122 provided via a client device 102 can be isolated from other application instances provided via other client devices, in some embodiments.

In some embodiments, application 122 can enable the users to access, create, modify, etc. a virtual scene or virtual environment. A virtual scene or virtual environment, as described herein, refers to a simulated or digital representation of a configuration of virtual assets (e.g., characters, objects, design elements, etc.). In some embodiments, computing device 120 can be or can otherwise correspond to a 3D graphs collaboration platform, such as the Omniverse™ Platform by NVIDIA Corporation. Application 122 can, in some embodiments, provide users with access to tools or resources that enable the users to create or modify a virtual scene. In some embodiments, the tools or resources can include virtual asset design or development tools, graphics rendering resources, and so forth. A user can access the tools or resources via an instance of application 122 running via a respective client device 102 to create and/or modify virtual assets in the virtual scene. In an illustrative example, a virtual scene or virtual environment can include a video game scene that includes one or more virtual assets including characters, objects, design elements, etc. The user can engage with tools or resources of application 122 to add/remove virtual assets from the virtual scene, modify an appearance of virtual assets of the virtual scene, and so forth. It should be noted that some embodiments and examples of the present disclosure refer to the virtual scene including a video game environment. However, embodiments of the present disclosure can be applied to any kind of virtual scene and/or any kind of virtual asset, as described herein. In some embodiments, computing device 120 can provide users with access to avatars and/or other assets using features or functionality of an avatar engine, such as Avatar Cloud Engine™ by NVIDIA Corporation.

As illustrated in FIG. 1, computing device 120 can include an asset management engine 131, a simulation engine 141, and/or a model engine 151, in some embodiments. In additional or alternative embodiments, asset management engine 131, simulation engine 141, and/or model engine 151 can reside at one or more server machines (e.g., server machine 160, another server machine not shown, etc.). In such embodiments, computing device 120 can access asset management engine 131, simulation engine 141, and/or model engine 151 using network 110.

Asset management engine 131 can be configured to manage data associated with an asset or a resource (e.g., a virtual avatar, a non-playable character (NPC), a 3D object) that is included as a virtual asset in a virtual scene or a virtual environment. An asset can include any type of object (e.g., an object, a non-object, etc.) that can be depicted or otherwise included in a virtual scene. In some embodiments, an object can include a character object, a scenery object, clothing items, accessories, gear, etc. for a character object, and so forth. A virtual avatar refers to a virtual asset (e.g., a character asset, etc.) for which actions or activities can be controlled by one or more users of the simulation. A non-playable character refers to a virtual asset that may interact with virtual avatars or other assets of a virtual environment, but its actions or activities may not be controlled by user(s) of the simulation. A virtual object (e.g., a 3D object) refers to a virtual asset that is part of a scene or activity of a simulation, but may not interact with other virtual assets and/or may not be controlled by user(s) of the simulation. In an illustrative example, a virtual scene or virtual environment may include a virtual avatar asset (e.g., a character asset that is controllable by a user of a simulation), one or more NPC assets (e.g., a non-character asset that each may interact with the virtual avatar asset in accordance with the virtual scene or virtual environment), and/or one or more virtual objects, (e.g., 3D objects of the virtual scene or virtual environment which the character asset and non-character asset(s) may interact in accordance with the simulation). It should be noted that although some embodiments of the present disclosure refer specifically to virtual avatar assets or NPC assets, such embodiments can be applied to virtual object assets, and vice versa.

In some embodiments, each asset of a virtual scene or virtual environment can be associated with a respective agent 132, which facilitates generation and/or execution of simulation commands to cause an action or activity to be performed with respect to the asset in accordance with an operation of a simulation including the asset (also referred to as a simulation operation). A simulation operation, as referred to herein, refers to a process or calculation that is performed in accordance with a simulation. A simulation operation can involve execution of a simulation command, which can include or otherwise correspond to an instruction executed by an engine (e.g., simulation engine 141) to cause an action or activity to be performed with respect to an asset, as described herein.

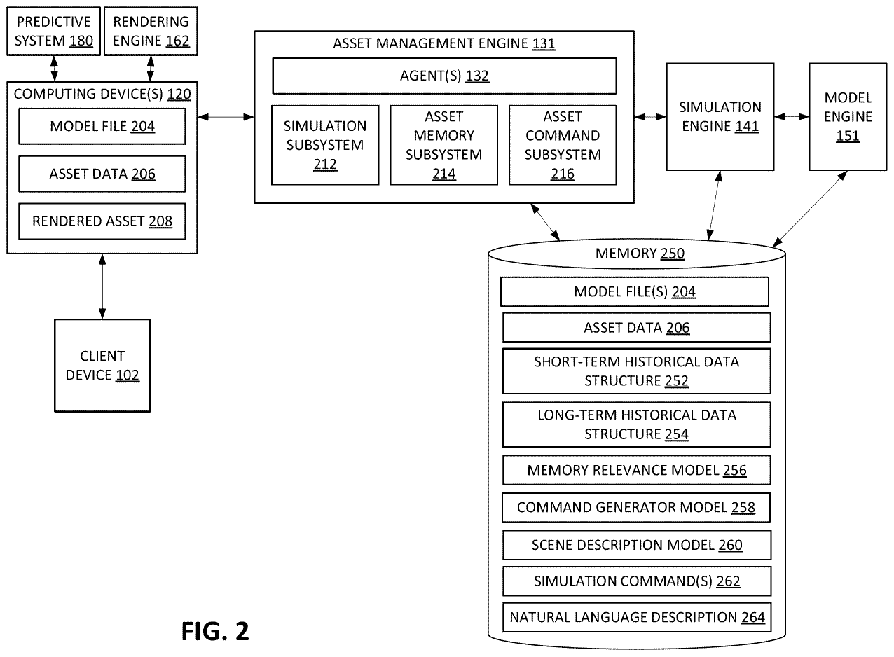

An action or activity can be performed with respect to an asset (and/or a robotic component) if the asset performs the action or activity or another asset (or another robotic component or object in a real-world environment) performs the action or activity, and the asset is affected by the performed action or activity. In some embodiments, each asset of a simulation may be associated with a respective agent 132 (e.g., which manages the simulation operations for only that asset). In other or similar embodiments, an agent 132 can manage the simulation operations for multiple assets (e.g., that share common characteristics, that are located in a common region of the virtual environment, etc.). In an illustrative example, each virtual avatar and/or NPC asset of the simulation can be associated with a distinct agent 132 and another agent 132 can be associated with one or more additional virtual object assets (e.g., which are part of the virtual environment by not controllable as would be a virtual avatar). As described herein, an agent 132 can be configured for an asset during an initialization period of the application 122 and/or at any other time period after the initialization period. An agent 132 associated with a respective asset can facilitate generation and/or execution of a simulation command to cause an action or activity to be performed with respect to an asset of a simulation in accordance with embodiments described below with respect to simulation subsystem 212, asset memory subsystem 214, and asset command subsystem 216 of asset management engine 131, described with respect to FIGS. 2-9.

Simulation engine 141 can be, or can include a physics simulation engine that is configured to generate simulation data associated with an object based on the simulated behavior of the object in view of rigid-body dynamics and/or soft-body dynamics of the object. In some embodiments, simulation engine 141 can be or can otherwise execute using PhysX® from NVIDIA Corporation, or other similar physical simulation techniques. As described herein, simulation engine 141 can execute one or more simulation commands provided by or otherwise obtained from asset management engine 131. An output of simulation engine 141 can include characteristic data of the asset and/or the virtual scene or virtual environment, which represents a simulated action or response of the asset in accordance with the action or activity of the simulation command. In an illustrative example, a simulation command provided by or otherwise obtained from asset management engine 131 can involve an activity of a virtual avatar or a NPC asset walking from one region of a virtual environment to another region of the virtual environment. An output of the simulation engine 141 can include characteristic data of the virtual avatar or NPC asset representing a simulated action or response of the virtual avatar or NPC asset upon performance of the simulated activity.

Model engine 151 can be configured to generate and/or update a model file that, when rendered, depicts an asset, an action or activity performed with respect to an asset, and/or a response to an action or activity performed with respect to an asset. A model file refers to a file or other such type of data set including a set of rendering commands that, when executed by rendering engine 162, generate a rendering of the asset, the action or activity performed with respect to the asset, and/or a response to an action or activity performed with respect to the asset. Model engine 151 can generate and/or update a model file based on simulation data obtained from simulation engine 141, in some embodiments. In other or similar embodiments, model engine 151 can generate a model file based on information associated with the asset (e.g., as provided by a user of client device 102 and/or as obtained from asset management engine 131, as described herein).

Rendering engine 162 can render display data and/or image data based on a model file for transmission to and/or presentation by client device 102. Rendering engine 162 can leverage any number of processing units (e.g., graphical processing units (GPUs)) and/or nodes thereof for rendering the display data and/or image data from the object data. In some embodiments, rendering engine 162 can execute ray tracing (e.g., real time ray tracing) and/or path tracing using one or more GPUs to generate photo-realistic renderings of assets associated with a model file. As described above, a model file can include data and/or commands executed by rendering engine 162 to render a 3D object (e.g., an object, a virtual avatar, etc.).

In some embodiments, the a model file can include asset data that indicates a bone structure associated with an asset, an indication of a mesh (e.g., a polygon mesh) for the asset, and/or an indication of one or more blend shapes (also referred to as morph targets) for the asset. The bone structure can include one or more bones that are each indicated by a bone index. The mesh can include one or more polygons made up of vertices, edges, and faces. Each blend shape can represent a distinct representation of at least a portion of the asset. For example, object data can include blend shapes for one or more faces of a virtual avatar and/or NPC asset, including a frowning face, a smiling face, and so forth. The object data can, in some embodiments, include an indication of a motion vector for each vertex of at least a portion of the mesh. A motion vector can indicate a degree and/or a direction of a motion of a respective vertex in accordance with an animation of the 3D object. In an illustrative example, a motion vector can include at least three values each indicating a degree of movement of the vertex according to a respective axis of motion (e.g., an x-axis, a y-axis, a z-axis, etc.). A positive value can indicate movement in a positive direction along the axis, while a negative value can indicate movement in a negative direction along the axis.

As illustrated in FIG. 1, computing device 120 can optionally include a robotics engine 161. Robotics engine 161 can be configured to perform operations and/or execute commands associated with robotic components of an environment (e.g., a real-world environment). In some embodiments, asset management engine 131 can generate commands associated with actions or activities of a robotic component of a real-world environment (e.g., in response to sensor data collected by sensors 104) and robotics engine 161 can execute such commands to cause the action or activity to be performed with respect to the robotic component in the real-world environment. It should be noted that although some embodiments are described herein with respect to commands associated with an action and/or activity of a robotic component in a real-world environment, such embodiments can be applied with respect to commands associated with an action and/or activity of a virtual asset (e.g., a virtual avatar, a NPC, a virtual object, etc.) of a virtual scene or virtual environment in accordance with a simulation, and vice versa. Further details regarding robotic components in a real-world environment are provided herein with respect to FIG. 10.

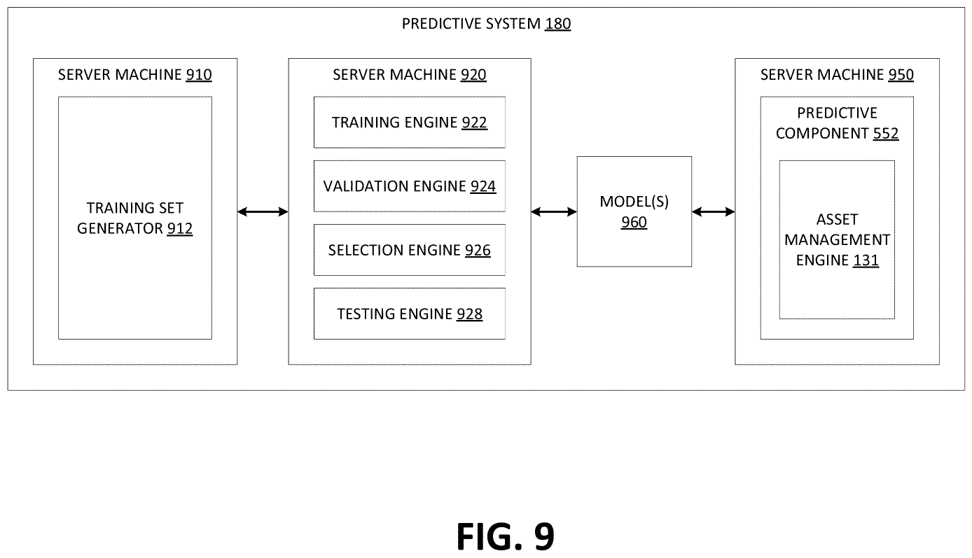

System 100 can include a predictive system 180, in some embodiments. The predictive system 180 can train and/or access one or more AI models that are described with respect to asset management engine 131 herein. In some embodiments, predictive system can include one or more AI servers (e.g., server machine 910, server machine 920, server machine 950, etc.), which trains and/or accesses AI model(s) that predict actions or activities to be performed with respect to an asset and/or a robotic component and generates commands associated with such actions. Further details regarding predictive system 180 and such AI model(s) are described with respect to FIG. 9 and elsewhere.

In some implementations, client device 102, sensors 104, computing device 120, data store 112, server machine 160, and/or predictive system 180, may be one or more computing devices computing devices (such as a rackmount server, a router computer, a server computer, a personal computer, a mainframe computer, a laptop computer, a tablet computer, a desktop computer, etc.), data stores (e.g., hard disks, memories, databases), networks, software components, and/or hardware components that may be used to enable action or activity prediction and/or command generation, in accordance with embodiments of the present disclosure. It should be noted that in some other implementations, the functions of client device 102, sensors 104, computing device 120, data store 112, server machine 160, and/or predictive system 180 may be provided by a fewer number of machines. For example, in some implementations, computing device 120, server machine 160, and/or predictive system 180 may be integrated into a single machine, while in other implementations, computing device 120, server machine 160, and/or predictive system 180 may be integrated into multiple machines. In addition, in some implementations one or more of server machine 160, and/or predictive system 180 may be integrated into computing device 120. In general, functions described in implementations as being performed by computing device 120, server machine 160, and/or predictive system 180 may also be performed on one or more edge devices (not shown) and/or client devices (not shown), if appropriate. In addition, the functionality attributed to a particular component may be performed by different or multiple components operating together. computing device 120, server machine 160, and/or predictive system 180 may also be accessed as a service provided to other systems or devices through appropriate application programming interfaces.

It should be noted that although FIG. 1 illustrates asset management engine 131, simulation engine 141, model engine 151, and optionally robotics engine 161 as part of computing device 120, in additional or alternative embodiments, asset management engine 131, simulation engine 141, model engine 151, and/or robotics engine 161 can reside on one or more server machines that are remote from computing device 120. It should be noted that in some other implementations, the functions of computing device 120, server machine 160, and/or predictive system 180 can be provided by more or a fewer number of machines. For example, in some implementations, components and/or modules of computing device 120, server machine 160, and/or predictive system 180 may be integrated into a single machine, while in other implementations components and/or modules of any of computing device 120, server machine 160, and/or predictive system 180 may be integrated into multiple machines. In some embodiments or examples, asset management engine 131, simulation engine 141, model engine 151, and/or robotics engine 161 can be included as part of a streaming analytics toolkit, such as DeepStream SDK by NVIDIA Corporation®.

In general, functions described in implementations as being performed computing device 120, server machine 160, and/or predictive system 180 can also be performed on the client device 102 in other implementations. In addition, the functionality attributed to a particular component can be performed by different or multiple components operating together. Computing device 120 can also be accessed as a service provided to other systems or devices through appropriate application programming interfaces, and thus is not limited to use in websites.

In implementations of the disclosure, a “user” can be represented as a single individual. However, other implementations of the disclosure encompass a “user” being an entity controlled by a set of users and/or an automated source. For example, a set of individual users federated as a community in a social network can be considered a “user.” Further to the descriptions above, a user may be provided with controls allowing the user to make an election as to both if and when systems, programs, or features described herein may enable collection of user information (e.g., information about a user's social network, social actions, or activities, profession, a user's preferences, or a user's current location), and if the user is sent content or communications from a server. In addition, certain data can be treated in one or more ways before it is stored or used, so that personally identifiable information is removed. For example, a user's identity can be treated so that no personally identifiable information can be determined for the user, or a user's geographic location can be generalized where location information is obtained (such as to a city, ZIP code, or state level), so that a particular location of a user cannot be determined. Thus, the user can have control over what information is collected about the user, how that information is used, and what information is provided to the user.

FIG. 2 is a block diagram of an example asset management engine 131, according to at least one embodiment. As described above, computing device 120 can provide users with access to a rendering of a simulated representation of a virtual asset in a virtual scene or virtual environment. Asset management engine 131 can facilitate generation and/or execution of simulation commands to cause an action or activity to be performed with respect to an asset, in accordance with the simulation, as described herein. Each virtual asset of the simulation can be associated with a respective agent 132, which is configured to facilitate the generation and/or execution of simulation commands to cause an action or activity to be performed with respect to the associated asset, as described herein. In some embodiments, an agent 132 for an asset can be configured during an initialization period for a simulation and/or after an initialization period of the simulation (e.g., during a run-time period of the simulation), as described herein.

As illustrated in FIG. 2, computing device 120, asset management engine 131, simulation engine 141, and/or model engine 151 are connected (e.g., via network 110) to memory 250. Memory 250 can store data or information associated with executing simulations, as described herein. In some embodiments, memory 250 can be, or can be included in, data store(s) 112. In other or similar embodiments, memory 250 can be any other type of memory of or otherwise accessible to components of system 100.

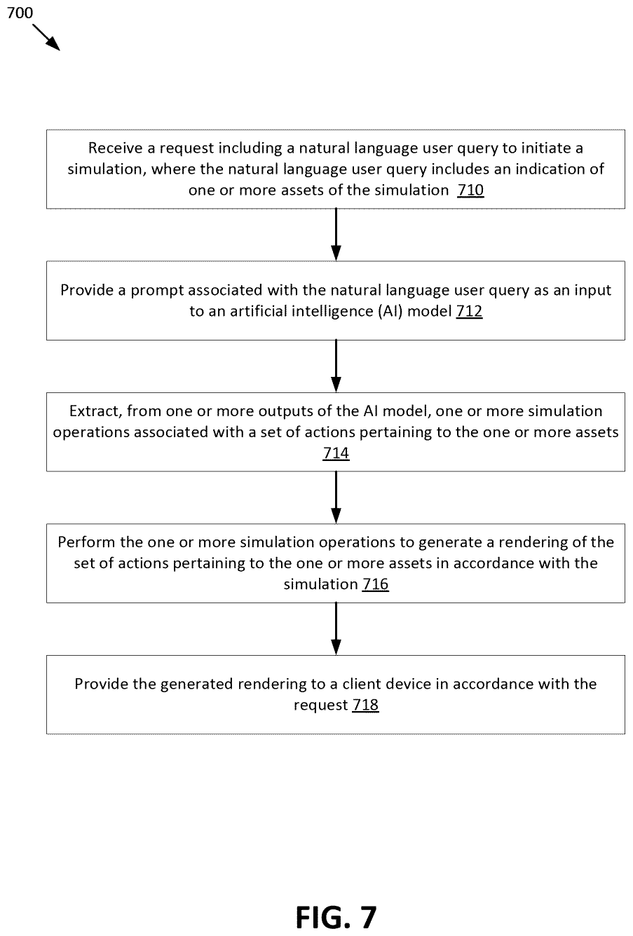

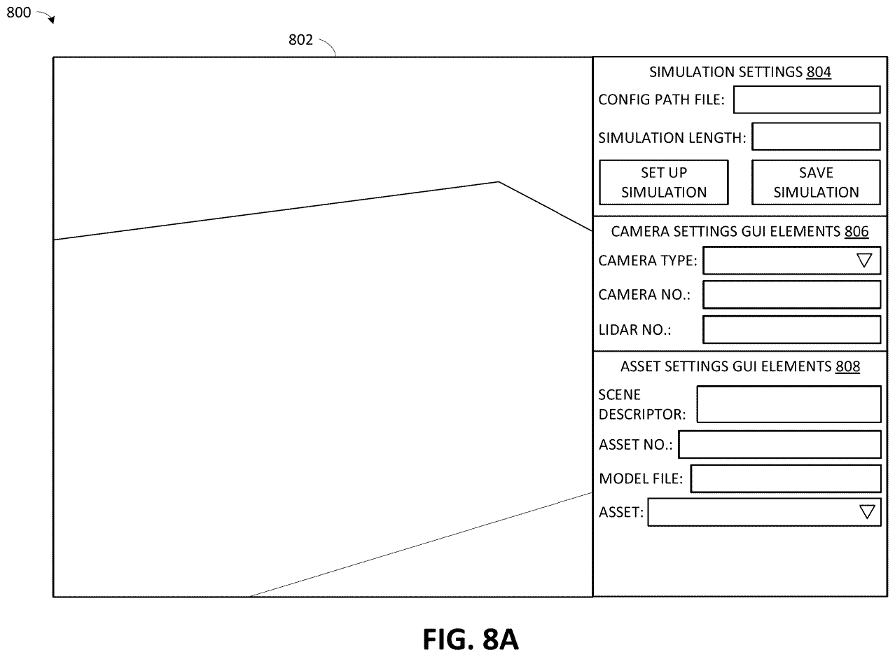

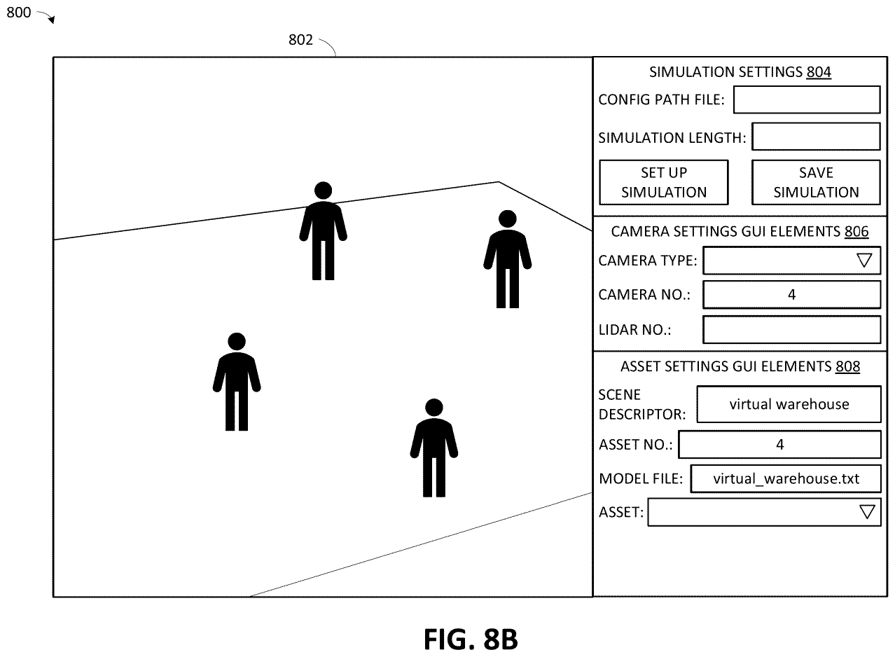

In some embodiments, computing device 120 can initialize a simulation by executing one or more initialization files for the simulation. An initialization file can be a type of model file 204 that includes instructions, commands, data, and other types of information associated with initializing or configuring the simulation. An initialization file is also referred to as a configuration file. In an illustrative example, an initialization model file 204A can include simulation parameters (e.g., a time window for the simulation, a time interval for updates of the simulation, a simulation type, etc.), define assets of the simulation (e.g., a type of the asset, an initial state of the asset, behavior models that are invoked or otherwise accessed for the asset in accordance with the simulation, a task or mission of the asset, etc.), a state of the simulation environment (e.g., weather conditions, environmental terrain, external factors, etc.), and other such type of information. In some embodiments, asset management engine 131 and/or simulation engine 126 can obtain the initialization model file 204A from a user of client device 102 and/or from memory 250. In other or similar embodiments, asset management engine 131 can generate an initialization model file 204A for a simulation based on asset data 206 provided by a user via client device 102. Further details regarding generating an initialization model file 204A for a simulation based on asset data 206 provided by a user are described herein with respect to FIGS. 7 and 8A-8B.

Upon obtaining the initialization model file 204A for a simulation, simulation engine 141 and/or model engine 151 can execute the initialization model file 204A to initialize the simulation. In some embodiments, upon execution of the initialization model file 204, simulation engine 141 may parse contents of the initialization model file 204A to extract relevant configurations associated with the simulation, set up the simulation environment in accordance with the extracted configurations, and/or initialize each asset of the simulation in accordance with the specific attributes and behaviors, as defined by the initialization model file 204. An asset may be initialized by creating or otherwise updating an asset identifier for the asset (e.g., based on information included in the initialization model file 204A). Based on the execution of the initialization model file 204, asset management engine 131 (or another component of computing device 120) can additionally or alternatively configure an agent 132 for each asset of the simulation (e.g., as indicated by the initialization model file 204). As described above, an agent 132 for an asset of a simulation refers to a software component that represents and manages the behavior and state of that asset within the simulation environment. The agent 132 can act as an intermediary between simulation subsystem 212, asset memory subsystem 214, and/or asset command subsystem 216 and the specific asset the agent 132 is assigned to. When an asset is introduced or initialized for a simulation, a corresponding agent 132 is instantiated, which can involve defining parameters such as the asset's type, initial conditions, and other asset-specific attributes.

As described herein, an agent 132 for a respective asset can facilitate generation and/or execution of simulation commands to cause an action or activity to be performed with respect to the asset in accordance with the simulation. Agent 132 can facilitate the generation and/or execution of simulation commands using simulation subsystem 212, asset memory subsystem 214, and/or asset command subsystem 216 of asset management engine 131. Simulation subsystem 212 can initiate requests for a simulation command to perform an action or activity associated with a virtual asset and executing generated commands for the requested action or activity. Asset memory subsystem 214 can store and/or retrieve data or information associated with a particular asset and/or a simulated scene. Asset command subsystem 216 can obtain predicted actions or activities associated with a virtual asset based on data or information associated with the asset and can generate the simulation commands for the predicted actions or activities.

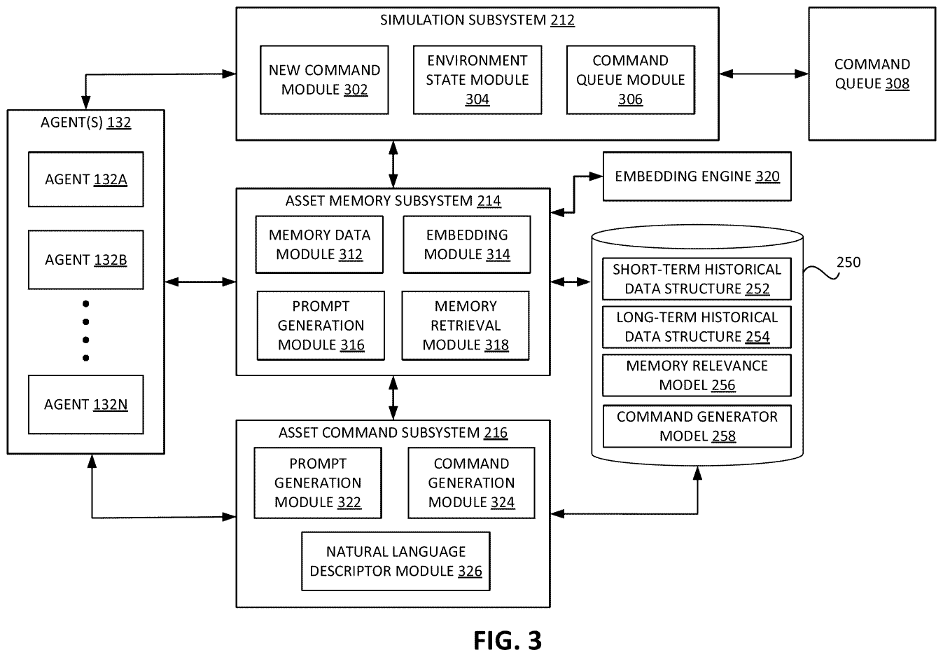

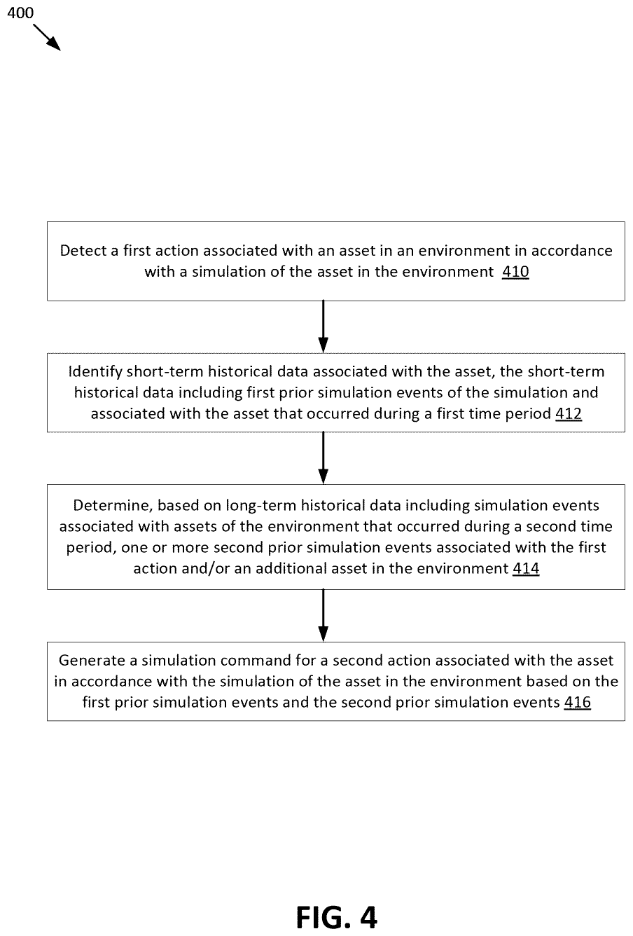

FIG. 3 illustrates an example simulation subsystem 212, an example asset memory subsystem 214, and an example asset command subsystem 216, according to at least one embodiment. A brief description of modules of simulation subsystem 212, asset memory subsystem 214, and asset command subsystem 216 is provided below. Further details regarding simulation subsystem 212, asset memory subsystem 214, and asset command subsystem 216, and their respective modules, are described herein with respect to FIGS. 4-7.

As illustrated by FIG. 3, simulation subsystem 212 can include a new command module 302, an environment state module 304, and/or a command queue module 306. New command module 302 can be configured to initiate the generation of a new simulation command associated with an action or activity with respect to an asset (e.g., in response to a request from an agent 132 associated with the asset). Environment state module 304 can be configured to obtain a state of the virtual scene or virtual environment before or during a time period that the request to initiate generation of a new simulation command is received. Command queue module 306 can add a generated simulation command to a command queue 308, which includes simulation commands that are to be executed by simulation engine 141, as described herein.

As further illustrated by FIG. 3, asset memory subsystem 214 includes a memory data module 312, an embedding module 314, a prompt generator module 316, and/or a memory retrieval module 318. Generally, asset memory subsystem 214 can be configured to manage memory data associated with assets of a simulation which can be included in a short-term historical data structure 252 and/or a long-term historical data structure 254 (e.g., residing at memory 250) and can identify memory data that is relevant to a requested action or activity of an asset. Memory data for a respective asset can include a prior action or prior activity performed by or with respect to the asset, in light of a context of the simulation scene or simulation environment during a time period that the prior action or prior activity was performed. Such prior action or prior activity is also referred to as a simulation event. Memory data module 312 can generate a memory data object that includes a mapping between an identifier for an asset of the simulation and a description (e.g., a natural language description) of an action or activity performed by or with respect to the asset and/or of the scene or environment of the simulation during performance of the action or activity. In some embodiments, memory data module 312 can obtain the description based on one or more outputs of command generator model 258, as described in further detail below. In other or similar embodiments, memory data module 312 can obtain the description based on an output of another AI model (e.g., a large language model (LLM)) trained to generate a description of a simulation (e.g., as the simulation is performed or executed). In other or similar embodiments, a user of client device 102 can provide the description using the GUI of client device 102. Upon obtaining the description, memory data module 312 can generate the memory data object by generating a mapping between the description and the asset identifier. In some embodiments, memory data module 312 can store the memory data object at short-term historical data structure 252 and/or long-term historical data structure 254, as described below.

Short-term historical data structure 252 can store memory data objects of one or more assets of a simulation that occurred within a first time period relative to a current time period (e.g., when a request for a new simulation command is received). The first time period can have a fixed length (e.g., as defined by an operator or developer of system 100 and/or computing device 120), in some embodiments. For example, the first time period can have a length of one hour, multiple hours, one day, etc. from the current time period. In other or similar embodiments, the short-term historical data structure 252 can include memory data objects associated with a particular number of simulation events for a respective asset. For example, the short-term historical data structure 252 can include memory data associated with the five most recent simulation events of a respective asset. Accordingly, the short-term historical data structure 252 can include memory data for a time period corresponding to the five most recent simulation events.

The long-term historical data structure 254 can include memory data objects for each asset of the simulation throughout the entirety (or at least a portion) of the simulation, in some embodiments. In other or similar embodiments, long-term historical data structure 254 can include memory data objects for assets of another simulation (e.g., that was performed prior to or during the simulation). In some embodiments, embedding module 314 can generate an embedding for each memory data object of the long-term historical data structure 254, which can be stored at the long-term historical data structure 254 in place of the memory data object (e.g., thereby reducing the overall amount of memory space consumed to store information of each memory data object). An embedding refers to a mathematical representation of data that can be understood by AI models and/or machine learning models. An embedding can include or otherwise correspond to a dense, lower-dimensional representation of data, which preserves important relationships and/or semantic properties of the original data. An embedding, as described herein, can include, but is not limited to, a word embedding (e.g., a Word2Vec embedding, a Global Vectors for Word Representation (GloVe) embedding, a FastText embedding, etc.), a sentence embedding, an image embedding, a graph embedding, and so forth. Embedding module 314 can generate an embedding by providing a memory data object as an input to an embedding engine 320. An embedding engine 320 refers to a software component, hardware component, firmware component, or hybrid component (e.g., combination of software, hardware, and/or firmware) that convers high-dimensional or categorical data into a continuous, dense vector representation in a lower-dimensional space. A type of the embedding engine 320 can correspond to a type of the embedding that is generated (e.g., a word embedding engine, a sentence embedding engine, an image embedding engine, a graph embedding engine, etc.). Embedding engine 320 can reside at any of the components or systems of system 100 (e.g., computing device 120, client device 102, etc.) and/or at another system connected to or otherwise accessible to system 100. In some embodiments, embedding engine 320 can include or otherwise correspond to an embedding inference model, such as NVIDIA Embedding NIM of NVIDIA Corporation.

As described above, embedding module 314 can generate an embedding for a memory data object by providing the memory data object as an input to the embedding engine 320 and obtaining one or more outputs from the embedding engine 320, which include the generated embedding. Upon obtaining the generated embedding, embedding module 314 can store the generated embedding at short-term historical data structure 252 and/or long-term historical data structure 254 (e.g., with the original memory data object or in place of the memory data object). In some embodiments, long-term historical data structure 254 can include memory data objects and/or embeddings representing the memory data for each asset of the simulation (and/or the other simulation), and short-term historical data structure 254 can include the original (e.g., “un-embedded”) memory data objects associated with a respective asset.

Once a memory data object of the short-term historical data structure 254 is associated with a time period that is longer than the first time period relative to the current time period, memory data module 312 can move the memory data object from the short-term historical data structure 252 to the long-term historical data structure 254. In some embodiments, embedding module 314 can generate the embedding for the memory data object and store the generated embedding at the long-term historical data structure 254, as described above. Upon storing a memory data object and/or an embedding generated for the memory data object at the long-term historical data structure 254, memory data module 312 can remove (e.g., erase, write over, etc.) the memory data object at the short-term historical data structure 252.

Prompt generation module 314 can generate prompts to be provided to memory relevance model 256, which is trained to predict memory data that is relevant to a requested action or activity. The generated prompt can include information associated with a state or context of the virtual scene or virtual environment prior to receiving the request for the new command of the action or activity. In some embodiments, the information included in the generated prompt can include a natural language description of the state or context of the virtual scene or the virtual environment and/or one or more simulation events associated with the asset and/or an additional asset of the virtual scene or the virtual environment. Memory retrieval module 318 can be configured to feed the generated prompt as an input to the memory relevance model 256 and obtain one or more outputs of the memory relevance model 256. The one or more outputs can indicate entries of the short-term historical data structure 252 and/or the long-term historical data structure 254 that include memory data having a degree of relevance to the requested action or activity that satisfies one or more relevance criteria (e.g., exceeds a relevance threshold, etc.). Memory retrieval module 318 can retrieve the memory data from the entries identified by the one or more outputs of the memory relevance model 256, as described herein.

As further illustrated by FIG. 3, asset command subsystem 216 can include a prompt generation module 322, a command generation module 324, and/or a natural language descriptor module 326. Generally, asset command subsystem 216 can obtain a generated command to perform an action or activity with respect to an asset based on memory data associated the asset and/or the requested action or activity. Prompt generation module 322 can generate a prompt that is provided as an input to command generator model 258. Prompt generation module 322 can generate the prompt based on memory data obtained according to embodiments described with respect to asset memory subsystem, as provided herein. Command generation module 324 can provide the generated prompt as an input to command generation model 258 and can obtain one or more outputs of the command generation model 258. The one or more outputs can include a predicted action or activity to be performed with respect to the asset and/or one or more simulation operations associated with the predicted action or activity. The simulation operation(s) can include one or more simulation commands that, when executed by simulation engine 141, cause the action or activity to be performed with respect to the asset, in accordance with the simulation. In some embodiments, the one or more outputs of the command generation model 258 can include a natural language description of the predicted action or activity. Natural language descriptor module 326 can extract the natural language description from the one or more outputs, in such embodiments. In other or similar embodiments, natural language descriptor module 326 can generate a natural language description of the action or activity performed with respect to the asset based on the indicated action or activity and/or the simulation operation(s). Natural language descriptor module 326 can provide the obtained natural language description to predictive system 180 for additional training of memory relevance model 256, command generator model 258, and/or another model of or otherwise associated with system 100.

Further details regarding simulation subsystem 212, asset memory subsystem 214, and asset command subsystem 216 are provided herein with respect to FIGS. 4-7 below. For purposes of explanation and illustration only, embodiments of FIGS. 4-7, and other embodiments of the description, are described with respect to a simulation of a virtual warehouse environment that includes virtual box objects on virtual shelf objects, and virtual workers (e.g., virtual avatars or NPC assets) in the virtual warehouse environment. A first agent 132A can be associated with a first virtual worker (e.g., a first virtual avatar or NPC asset) and one or more second agents 132B-132N can be associated with one or more second virtual workers and/or one or more virtual objects in the virtual warehouse environment. It should be noted that such embodiments and examples are provided for purposes of explanation and illustration only, and are not intended to be limiting. Such embodiments and examples can be applied to any type of assets in any type of simulation environment. Further, such embodiments and examples can be applied to robotic components in a real-world environment, in accordance with embodiments described with respect to FIG. 10 and elsewhere.

FIG. 4 depicts an example method 400 of generating a simulation command for an action associated with an asset, according to at least one embodiment. In some embodiments, method 400 can be performed by computing device 120. For example, one or more operations of method 400 can be performed by asset management engine 131, simulation engine 141, and/or model engine 151, in some embodiments. Method 400 may be performed by one or more processing units (e.g., CPUs and/or GPUs), which may include (or communicate with) one or more memory devices. In at least one embodiment, method 400 may be performed by multiple processing threads (e.g., CPU threads and/or GPU threads), each thread executing one or more individual functions, routines, subroutines, or operations of the method. In at least one embodiment, processing threads implementing method 300 may be synchronized (e.g., using semaphores, critical sections, and/or other thread synchronization mechanisms). Alternatively, processing threads implementing method 400 may be executed asynchronously with respect to each other. Various operations of method 400 may be performed in a different order compared with the order shown in FIG. 4. Some operations of the methods may be performed concurrently with other operations. In at least one embodiment, one or more operations shown in FIG. 4 may not always be performed.

At block 410, processing logic detects a first action associated with an asset in an environment in accordance with a simulation of the asset in the environment. As described above, in an illustrative example, an agent 132A can be associated with a first worker (e.g., a first virtual avatar or NPC asset) in a simulated warehouse environment. The first action associated with the asset may be performed or otherwise caused by another asset of the simulation, in some embodiments. In other or similar embodiments, the first action may be detected based on a notification received from a client device 102 in response to a detection of a user interaction with one or more GUI elements of a GUI of the client device 102. In accordance with the illustrative examples herein, the first action associated with the first worker can include a virtual box object falling from a virtual shelf object at a location that is within a threshold distance from the asset in the virtual warehouse. In yet another example, the first action can be detected upon receiving a notification of a user interaction with a GUI of client device 102, where the notification corresponds to a request to cause the asset to move toward the virtual box object on the virtual shelf object in the virtual warehouse. Upon detection of the first action by agent 132A, agent 132A can provide a request to new command module 302 for one or more new simulation commands associated with an action to be performed by the first asset. In some embodiments, the action to be performed by the first asset may be determined based on one or more outputs of command generator model 258, as described herein. In other or similar embodiments, the request to new command module 302 from agent 132A can include an indication of a target action to be performed by the first worker (e.g., as included in the notification received from client device 102). As will be seen herein, command generator model 258 can predict an updated action to be performed by the first worker (e.g., in view of short-term historical data and/or long-term memory data of the first worker and/or the simulation).

At block 412, processing logic identifies short-term historical data associated with the asset, the short-term historical data including first prior simulation events of the simulation and associated with the asset that occurred during a first time period. As described above, the short-term historical data structure 252 can store memory data objects associated with one or more assets of a simulation that occurred within a first time period relative to a current time period (e.g., a time period that a new simulation command is requested for an asset, etc.). The first time period can have a fixed length (e.g., as defined by an operator or developer of system 100 and/or computing device 120) and/or can have a length corresponding to a time period during which a fixed number of simulation events for a respective asset is detected. For example, the short-term historical data structure 252 can store memory data for the five most recent simulation events detected for a respective asset (e.g., each of which occurred within the first time period).

In some embodiments, short-term historical data structure 252 can include one or more entries, where each entry includes at least a first field and a second field. The first field can include an asset identifier for a respective asset of the simulation and the second field can include the memory data object and/or a generated embedding for a simulation event that falls within the first time period. In other or similar embodiments, short-term historical data structure 252 can include or otherwise correspond to one or more memory caches, where each memory cache stores the short-term historical data associated with a respective asset of the simulation (e.g., the five most recent simulation events for the respective asset). New command module 302 can receive the request for the new simulation commands for the asset (e.g., the first worker) and can transmit an instruction to asset memory subsystem 214 to identify memory data object(s) associated with the asset. Memory retrieval module 318 can identify one or more entries and/or a memory cache of the short-term historical data structure 252 associated with the asset and can extract or otherwise copy the short-term historical data (e.g., including the first prior simulation events) from the identified entries and/or memory cache. For example, memory retrieval module 318 can identify one or more entries and/or a memory cache of short-term historical data structure 252 including or otherwise associated with the asset identifier for the asset and can extract the short-term historical data (e.g., the memory data object(s)) from the identified entries and/or memory cache.

At block 414, processing logic determines, based on long-term historical data including simulation events associated with the assets of the environment that occurred during a second time period, one or more second prior simulation events associated with the first action and/or an additional asset in the environment. In some embodiments, prompt generation module 316 can generate a prompt that is provided as an input to memory relevance model 256 to cause memory relevance model 256 to identify memory objects of long-term historical data structure 254 having a degree of relevance to the current environment or current scene of the simulation that satisfies one or more relevance criteria. In some embodiments, upon receiving a request from an agent 132 (e.g., agent 132A) for a new simulation command for an action or activity to be performed with respect to an asset, environment state module 304 can determine a current state of the virtual scene or virtual environment and provide the current state to asset memory subsystem 214. The current state can reflect a state of one or more assets of the virtual scene or virtual environment which may or may not include the asset for which the new simulation command is requested. In some embodiments, environment state module 304 can determine the current state of the virtual scene based on actions or activities associated with each command of command queue 308 and/or each command that was recently executed by simulation engine 141 (e.g., within a current time period). In other or similar embodiments, environment state module 304 can provide data associated with a current time period of the simulation as an input to a state understanding AI model (not shown) and obtaining one or more outputs of the state understanding AI model.

Prompt generation module 316 can generate the prompt based on the current state of the virtual scene or virtual environment and can provide the generated prompt as an input to the memory relevance model 256. In some embodiments, the generated prompt can include the current state of the virtual scene or the virtual environment and an instruction to identify embeddings and/or memory data objects of the long-term historical data structure 254 that satisfy one or more relevancy criteria (e.g., have a degree of relevance to the current state that exceed a relevancy threshold, etc.). In other or similar embodiments, embedding module 314 can generate an embedding based on the current state of the virtual scene or virtual environment, as described above, and the generated prompt can include the generated embedding (e.g., with the instruction to identify the relevant embeddings and/or memory data objects from the long-term historical data structure 254). Memory retrieval module 318 can obtain one or more outputs of the memory relevance model 256, which can indicate a relevance score for one or more embeddings/memory data objects of the long-term historical data structure 254 and/or one or more regions or entries of long-term historical data structure 254 that include embeddings and/or memory data objects that satisfy one or more relevancy criteria. A relevance score can indicate a degree of relevance between the simulation event of the embedding/memory data object and the current scene or current environment of the simulation. Memory retrieval module 318 can determine that an embedding/memory data object satisfies one or more relevancy criteria by determining that an associated relevance score exceeds a threshold relevance score.

In some embodiments, memory retrieval module 318 can extract the embeddings and/or memory data objects from the regions or entries of the long-term historical data structure 254 that include the embeddings and/or memory data objects (e.g., as indicated by the output(s) of the memory relevance model 256 or determined otherwise) and determine the simulation events (e.g., the one or more second prior simulation events) based on the extracted embeddings and/or memory data objects. In some embodiments, memory retrieval module 318 can provide an extracted embedding to embedding engine 320 and embedding engine 320 can generate or otherwise obtain a description of the simulation event (e.g., by reversing the embedding operation or function applied to generate the embedding).

In accordance with the previous illustrative example(s), the first action associated with the first worker in the virtual warehouse environment can include a virtual box falling from a virtual shelf object at a location that is within a threshold distance from the asset in the virtual warehouse. The prior simulation events identified to be relevant to the current scene or current environment of the simulation (e.g., from long-term historical data structure 254) can include instances when other virtual objects (e.g., other virtual boxes, virtual objects of other simulations, etc.) have fallen and actions taken by assets (e.g., the first worker, other workers of the simulation, other assets of other simulations, etc.) in response to the fallen virtual objects.

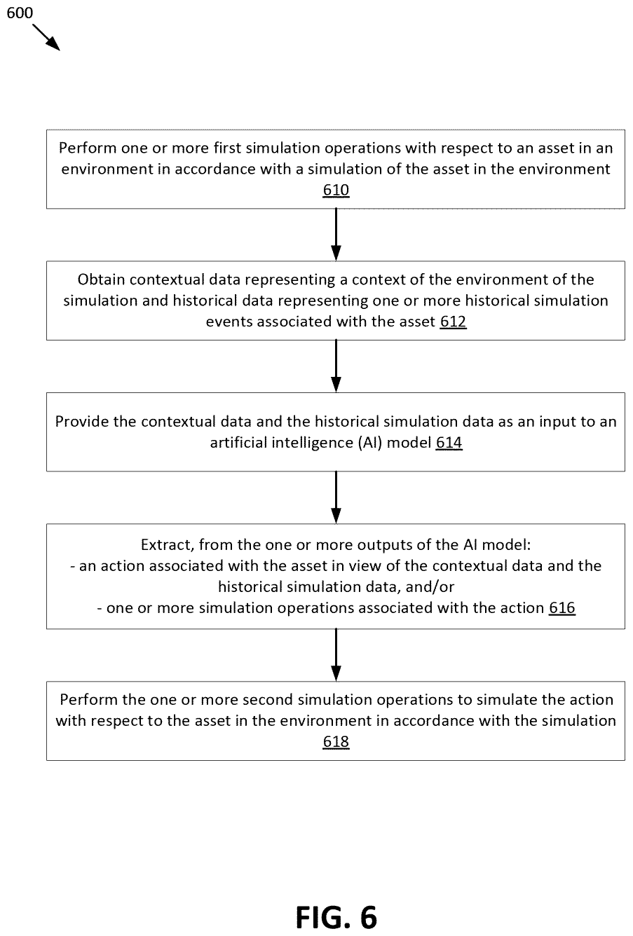

At block 416, processing logic generates a simulation command for a second action associated with the asset in accordance with the simulation of the asset in the environment based on the first prior simulation events and the second prior simulation events. Asset memory subsystem 214 can provide the first prior simulation events (e.g., obtained from the short-term historical data structure 252) and the second prior simulation events (e.g., obtained from the long-term historical data structure 254) to asset command subsystem 216 and asset command subsystem 216 can generate the simulation command 262 in accordance with embodiments described herein with respect to FIGS. 6-7. In some embodiments, asset command subsystem 216 can provide an indication of the one or more first prior simulation events and the one or more second prior simulation events as an input to a command generation AI model (e.g., command generator model 258) and can obtain one or more outputs of the command generation model. The one or more outputs can include a set of simulation commands 262 pertaining to actions associated with the asset (e.g., the first worker) in accordance with the simulation. Command queue module 306 can add the set of simulation commands 262 to command queue 308 and simulation engine 141 can execute the set of simulation commands 262 to cause the first action to be performed with respect to the asset, as described herein. In accordance with previous illustrative examples, the simulation command 262 can cause the first worker to walk over the virtual box that has fallen from the virtual shelf and place the virtual box on the virtual shelf.

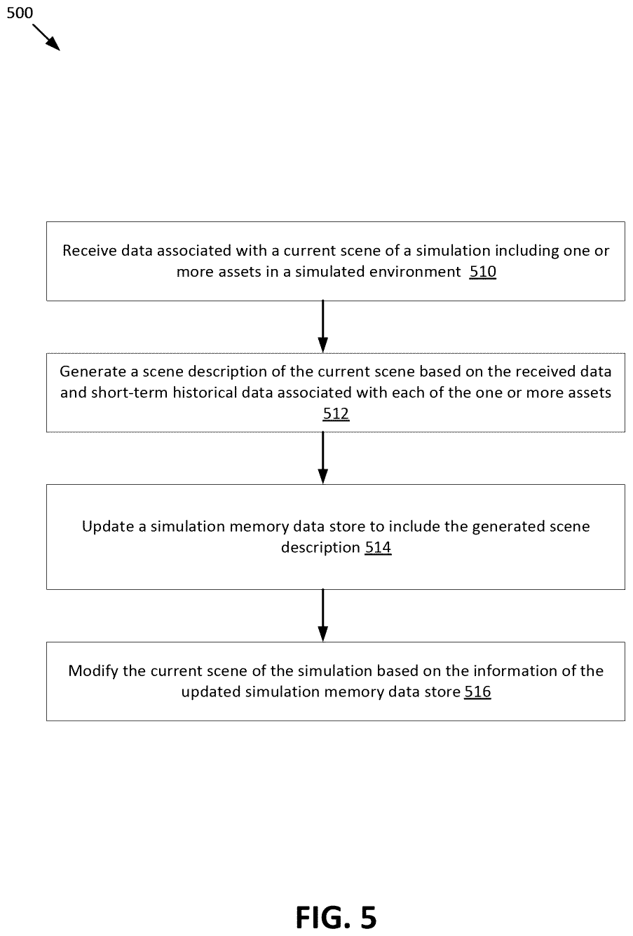

FIG. 5 depicts an example method 500 of modifying a scene of a simulation, according to at least one embodiment. In some embodiments, method 500 can be performed by computing device 120. For example, one or more operations of method 500 can be performed by asset management engine 131, simulation engine 141, and/or model engine 151, in some embodiments, in some embodiments. Method 500 may be performed by one or more processing units (e.g., CPUs and/or GPUs), which may include (or communicate with) one or more memory devices. In at least one embodiment, method 500 may be performed by multiple processing threads (e.g., CPU threads and/or GPU threads), each thread executing one or more individual functions, routines, subroutines, or operations of the method. In at least one embodiment, processing threads implementing method 500 may be synchronized (e.g., using semaphores, critical sections, and/or other thread synchronization mechanisms). Alternatively, processing threads implementing method 500 may be executed asynchronously with respect to each other. Various operations of method 500 may be performed in a different order compared with the order shown in FIG. 5. Some operations of the methods may be performed concurrently with other operations. In at least one embodiment, one or more operations shown in FIG. 5 may not always be performed.

At block 510, processing logic receives data associated with a current scene of a simulation including one or more assets in a simulated environment. In some embodiments, the data associated with the current scene can include a current state of a virtual scene or a virtual environment of a simulation. Environment state module 304 can determine the current scene and/or the current state in accordance with previously described embodiments, and can provide the determined current scene and/or current state to asset memory subsystem 214.

At block 512, processing logic generates a scene description of the current scene based on the received data and short-term historical data associated with each of the one or more assets. The short-term historical data can include one or more prior simulation events of the simulation and associated with the one or more assets that occurred during a prior time period of a prior time window. In some embodiments, memory data module 312 can identify memory data objects associated with the one or more assets from short-term historical data structure 252. Memory data module 312 can identify memory data objects associated with a particular asset and/or each asset of the simulation, in accordance with previously described embodiments. In some embodiments, memory data module 312 can generate the scene description of the current scene by providing the current scene and/or current state of the simulation and the identified memory data objects as an input to a scene description model 260 that is trained to generate a description of a simulation environment based on given data. Scene description model 260 can include a LLM or other such type model that is capable of generate a description of a simulation environment. Memory data module 312 can obtain one or more outputs of the scene description model 260, which can include a generated scene description.

At block 514, processing logic updates a simulation memory data store to include the generated scene description. The simulation memory data store can include information associated with the simulation during the prior time period and at least an additional time period of the prior time window. In some embodiments, the simulation memory data store can correspond to the long-term historical data structure 254. Memory data module 312 can provide the generated description as an input to embedding engine 320 and can obtain one or more outputs of the embedding engine 320, which can include a fixed-length embedding vector representing the scene description, in accordance with previously described embodiments. Memory data module 312 can update the long-term historical data structure 254 to include the generated embedding, in accordance with previously described embodiments. Memory data module 312 can additionally or alternatively update the short-term historical data structure 252 to include the generated scene description and/or the generated embedding. For example, upon determining that one or more time period criteria associated with the simulation event indicating the generated scene description are satisfied, memory data module 312 can copy or otherwise store the generated scene description and/or the generated embedding at the short-term historical data structure, in accordance with previously described embodiments. The one or more time period criteria can be satisfied if a time period during which actions or activities represented by the generated scene description is within a threshold distance from a current time period. In response to determining that the time period criteria are not satisfied (e.g., or are no longer satisfied), memory data module 312 can copy generated scene description and/or the generated embedding from the short-term historical data structure 252 to the long-term historical data structure 254, in accordance with previously described embodiments.

At block 516, processing logic modifies the current scene of the simulation based on the information of the updated simulation memory data store. In some embodiments, memory retrieval module 318 can retrieve memory data objects and/or generated embeddings from the short-term historical data structure 252 and/or the long-term historical data structure 254, in accordance with previously described embodiments, and can provide such memory data objects and/or generated embeddings to asset command subsystem 216. Asset command subsystem 216 can generate a set of simulation commands 262 that, when executed by simulation engine 141, modify the current scene of the simulation. Further details regarding generating the set of simulation commands 262 are provided herein with respect to FIGS. 6-7. In some embodiments, asset command subsystem 216 can modify the current scene of the simulation by detecting an action associated with at least one asset of the environment, in accordance with a simulation. Asset memory subsystem 214 can obtain a natural language description of the current scene of the simulation in view of the action, as described above, and can determine that a degree of relevance between the natural language description of the current scene and the generated scene description satisfies one or more relevance criteria (e.g., based on one or more outputs of memory relevance model 256), as described above. Responsive to a determination that the degree of relevance satisfies the one or more relevancy criteria, asset command subsystem 216 can provide the natural language description of the current scene and the generated scene description as an input to a command generation AI model (e.g., command generator model 258) and can obtain one or more outputs of the command generation AI model. The one or more outputs can include a set of simulation command 262 pertaining to additional actions associated with the asset in accordance with the simulation. Asset command subsystem 216 can extract at least one of the set of commands and command queue module 306 can provide the extracted command(s) to command queue 308 for execution by simulation engine 141, as described herein.

FIG. 6 depicts an example method 600 of performing simulation operations to simulation an action with respect to an asset, according to at least one embodiment. In some embodiments, method 600 can be performed by computing device 120. For example, one or more operations of method 600 can be performed by asset management engine 131, simulation engine 141, and/or model engine 151, in some embodiments, in some embodiments. Method 600 may be performed by one or more processing units (e.g., CPUs and/or GPUs), which may include (or communicate with) one or more memory devices. In at least one embodiment, method 600 may be performed by multiple processing threads (e.g., CPU threads and/or GPU threads), each thread executing one or more individual functions, routines, subroutines, or operations of the method. In at least one embodiment, processing threads implementing method 600 may be synchronized (e.g., using semaphores, critical sections, and/or other thread synchronization mechanisms). Alternatively, processing threads implementing method 600 may be executed asynchronously with respect to each other. Various operations of method 600 may be performed in a different order compared with the order shown in FIG. 6. Some operations of the methods may be performed concurrently with other operations. In at least one embodiment, one or more operations shown in FIG. 6 may not always be performed.

At block 610, processing logic performs one or more first simulation operations with respect to an asset in an environment in accordance with a simulation of the asset in the environment. The one or more first simulation operations can include one or more simulation commands 262 executed by simulation engine 141, in accordance with previously described embodiments. In some embodiments, execution of the one or more simulation commands 262 can cause the asset to perform a first action or activity or cause the first action or activity to be performed with respect to the asset, as described above. In accordance with previous illustrative examples, the asset can include a first worker of a virtual warehouse environment and execution of the one or more simulation commands 262 of the first simulation operations can involve a virtual box object falling from a virtual shelf object in the virtual warehouse environment.

At block 612, processing logic obtains contextual data representing a context of the environment of the simulation and historical data representing one or more historical simulation events associated with the asset. Environment state module 304 can obtain contextual data representing the context of the environment of the simulation, in accordance with previously described embodiments. Memory retrieval module 318 can obtain memory data objects associated with the asset from short-term historical data structure 252, in accordance with previously described embodiments. In some embodiments, retrieval module 318 can additionally or alternatively obtain memory data objects and/or embeddings associated with simulation events that are relevant to the context of the environment from long-term historical data structure 254, in accordance with previously described embodiments.

At block 614, processing logic provides the contextual data and the historical simulation data as an input to an AI model. The AI model can correspond to command generator model 258, in some embodiments. In some embodiments, prompt generation module 322 of asset command subsystem 216 can generate a prompt that, when provided to command generator model 258, cause command generator model 258 to generate a set of one or more simulation operations including one or more simulation commands 262 that, when executed by simulation engine 141, cause an action or activity to be performed with respect to the asset. Command generator model 258 can also predict the action or activity to be performed with respect to the asset, in some embodiments. In some embodiments, the generated prompt by the prompt generation module 322 can include a description of the context of the environment and the historical simulation data obtained from the short-term historical data structure 252 and/or the long-term historical data structure 254, and an instruction to predict an action or activity to be performed with respect to the asset based on the given context and historical simulation data and/or generate a set of simulation operations associated with the actions. Command generation module 324 can provide the generated prompt as an input to the command generator model 258, as described herein.

At block 616, processing logic extracts, from the one or more outputs of the AI model, an action associated with the asset in view of the contextual data and the historical simulation data, and/or one or more simulation operations associated with the action. One or more outputs of command generator model 258 can include a predicted action or activity to be performed with respect to the asset, in view of the context of the environment and the historical simulation data, and a set of simulation operations associated with the action. The one or more simulation operations can include a simulation command that, when executed by simulation engine 141, cause the action or activity to be performed with respect to the asset in accordance with the simulation. In accordance with the previous illustrative examples, the simulation operation(s) can include a simulation command that, when executed, causes the first worker to pick up the virtual box object and place it on the virtual shelf object in the virtual warehouse environment.

At block 618, processing logic performs the one or more second simulation operations to simulate the action with respect to the asset in the environment in accordance with the simulation. Command generation module 324 can perform the one or more second simulation operations by providing the simulation command(s) 262 to command queue module 306. Command queue module 306 can add the simulation command(s) 262 to command queue 308. In some embodiments, command queue module 306 can add the simulation command(s) 262 to command queue 308 based on a priority associated with the simulation command(s) 262 relative to other commands of the queue 308. For example, command queue module 306 can add the simulation command(s) 262 to a place in the command queue 308 that is ahead of or behind other commands of the command queue 308 based on a determination that the simulation command(s) 262 has a higher or lower priority, respectively, than other commands of the command queue 308. Simulation engine 141 can execute the simulation command(s) 262 to cause the action or activity to be performed with respect to the asset, in accordance with embodiments described herein. The simulation command priority may be determined based on a command queue protocol provided by a developer or operator of system 100 and/or may be included in one or more outputs of command generator model 258.

In some embodiments, asset command subsystem 216 can generate simulation operations and/or commands for assets of a simulation in batches, rather than individually. For example, during a simulation, simulation subsystem 212 can receive requests from multiple agents 132 (e.g., agent 132A, 132B, etc.) for new commands to be performed with respect to the associated assets of the simulation. Asset command subsystem 216 can obtain the context of the simulation environment as described above, which may be common to each asset of the simulation. Asset command subsystem 216 can obtain historical simulation data associated with each asset and associated with the simulation environment context, as described above. Prompt generation module 322 can therefore generate one or more prompts (e.g., a single prompt, multiple prompts) for command generator model 258 that include the simulation context and the obtained historical simulation data for each asset. Command generation module 324 can provide the generated one or more prompts as an input to command generator model 258, which can cause command generator model 258 to generate a set of simulation operations including simulation command(s) 262 for actions or activities to be performed with respect to each asset of the simulation. In an illustrative example, one or more outputs of the command generator model 258 can include a predicted action to be performed with respect to the first worker of the virtual warehouse environment and another predicted action to be performed with respect to a second worker of the virtual warehouse environment, in view of the first action performed with respect to the first worker. The set of operations of the one or more outputs can additionally or alternatively include a set of simulation command(s) 262 that, when executed, cause both the first action and the second action to be performed with respect to the first and second worker. Therefore, the generation of simulation operation(s) and/or simulation command(s) 262 can be performed in batches.

As described herein, the output(s) of the command generator model 258 can include an indication of an action or activity associated with an asset (e.g., the first worker of the virtual warehouse environment), in view of contextual data associated with the simulation scene and historical simulation data obtained from short-historical data structure 252 and/or long-term historical data structure 254. In some embodiments, the indication of the action or activity associated with the asset can include a natural language description of the action or activity. Natural language descriptor module 326 of asset command subsystem 216 can extract the natural language description 264 of the action or activity from the one or more outputs of command generator model 258 and can provide the extracted natural language description 264 to predictive system 180 to be used to train other AI models (e.g., object detection models, scene understanding models, etc.). In some embodiments, natural language descriptor module 326 can provide contextual data and/or historical simulation data provided as an input to the command generator model 258 with the natural language description 264.

As described herein, simulation engine 141 can execute simulation commands 262 of simulation queue 308. Model engine 151 can generate and/or update model file(s) 204 based on the execution of the simulation commands 262 such that, when the model file(s) 204 are rendered, a depiction of the action or activity performed with respect to the asset is generated. Rendering engine 162 can execute the model file(s) 204, as described above to generate a rendering of the action or activity performed with respect to the asset and can provide the generated rendering to client device 102 for presentation to the user via the GUI.

As described herein, the execution of the simulation commands 262 can cause an action or activity to be performed with respect to an asset (e.g., the first worker of the virtual warehouse environment). For example, execution of the simulation commands 262 can cause the first worker to walk over to the virtual box object that has fallen off the virtual shelf object and place the virtual box object on the virtual shelf object, in accordance with the simulation. Based on the execution of such simulation command 262, asset memory subsystem 214 can update short-term historical data structure 252 and/or long-term historical data structure 254 to include one or more memory data objects associated with such action or activity. For example, memory data module 312 can obtain a memory data object for the simulation event of the first worker picking up the virtual box object and placing it on the virtual shelf object and can add the memory data object to a region of short-term historical data structure 252 allocated for memory data objects associated with the first worker, as described herein. In some embodiments, memory data module 312 may remove (e.g., erase, write over, etc.) another memory data object associated with the first worker, such as a memory data object that no longer satisfies the time period criteria and replace the removed data object with the added memory data object. In additional or alternative embodiments, embedding module 314 can generate an embedding for the new memory data object, as described above, and can store the generated embedding at long-term historical data structure 254. Upon receiving a new request from the agent 132A of the first worker, asset memory subsystem 214 and asset command subsystem 216 can generate a new simulation command for the first worker based on the updated memory data objects/embeddings stored in the short-term historical data structure 252 and/or the long-term historical data structure 254, as described herein.

FIG. 7 depicts an example method 700 of generating a rendering of actions pertaining to assets of a simulation, according to at least one embodiment. In some embodiments, method 700 can be performed by computing device 120. For example, one or more operations of method 700 can be performed by asset management engine 131, simulation engine 141, and/or model engine 151, in some embodiments, in some embodiments. Method 700 may be performed by one or more processing units (e.g., CPUs and/or GPUs), which may include (or communicate with) one or more memory devices. In at least one embodiment, method 700 may be performed by multiple processing threads (e.g., CPU threads and/or GPU threads), each thread executing one or more individual functions, routines, subroutines, or operations of the method. In at least one embodiment, processing threads implementing method 700 may be synchronized (e.g., using semaphores, critical sections, and/or other thread synchronization mechanisms). Alternatively, processing threads implementing method 700 may be executed asynchronously with respect to each other. Various operations of method 700 may be performed in a different order compared with the order shown in FIG. 7. Some operations of the methods may be performed concurrently with other operations. In at least one embodiment, one or more operations shown in FIG. 7 may not always be performed.

At block 710, processing logic receives a request including a natural language user query to initiate a simulation. The natural language user query can include an indication of one or more assets of the simulation. As described above, embodiments of the present disclosure can allow a user of application 122 to initiate a simulation with respect to an asset by providing a natural language user query via a GUI of client device 102. FIGS. 8A-8B illustrate an example GUI 800, according to at least one embodiment. As illustrated in FIG. 8A, GUI 800 can include a simulation region 802 that depicts rendered assets of a simulation (e.g., rendered asset 208), as described herein. In some embodiments, no assets of the simulation may be initialized or configured during an initialization period, and therefore simulation region 802 may be blank and/or may include a rendering of default assets (e.g., which are common to each simulation associated with application 122).

GUI 800 can additionally or alternatively include one or more regions that enable a user to provide information or data associated with a simulation. For example, GUI 800 can include a simulation setting region 804, that enables a user to select a configuration or initialization file 204A (e.g., via a configuration path file GUI element) associated with the simulation. Simulation setting region 804 can additionally or alternatively include a GUI element that enables the user to specify a length of a time period for the simulation, a GUI element that enables the user to request initialization of the simulation (e.g., a “set up simulation” button), and/or a GUI element that enables the user to save the simulation (e.g., the settings or parameters of the simulation and/or the outcome of the simulation) to a memory (e.g., memory 250).

GUI 800 can additionally or alternatively include region that includes one or more camera settings UI elements 806. For example, as illustrated in FIG. 8A, the camera setting GUI elements 806 can include GUI elements that enable a user to specify a type of camera that is to be simulated or used in capturing simulation data of the simulation, specify the number of cameras that are to be simulated or used in capturing simulation data of the simulation, and/or specify the number of sensors (e.g., light detection and ranging (LIDAR) sensors) that are to be simulated or used in capturing simulation data of the simulation. Other types of camera settings GUI elements 806 can be included in GUI 800, in accordance with embodiments described herein.

GUI 800 can additionally or alternatively include a region that includes one or more asset settings GUI elements 808, which enable a user to provide details or specify settings regarding assets of a simulation. As illustrated by FIG. 8A, asset settings GUI elements 808 can include a “scene descriptor” element that enables a user to provide a natural language description of a simulation that is to be performed, in accordance with embodiments described herein. The “scene descriptor” element (or another asset setting GUI element 808) can enable a user to provide asset data 206 for each asset of the simulation, which can include a natural language description of a role or character of one or more assets (e.g., virtual avatars, NPC assets, etc.) of the simulation. In accordance with previous illustrated examples, a user can provide a natural language description of “configure a simulation of a virtual warehouse that includes virtual box objects on virtual shelves. The virtual warehouse should include multiple workers, at least one of which is controllable and the rest are NPC assets.” Such natural language description of the requested simulation can be included with or otherwise correspond to the natural language user query to initiate the simulation, as described herein. As also illustrated by FIG. 8A, asset settings GUI elements 808 can additionally or alternatively include a GUI element that enables a user to specify a number of assets of the simulation, a GUI element that enables the user to provide or otherwise specify a model file 204 associated with one or more assets, the scene, or the environment of the simulation, and/or a GUI element that enables the user to select an asset for inclusion in the simulation (e.g., from a set of default simulation assets, from a previously performed simulation, etc.).

It should be noted that the organization and structure of GUI 800 is provided for purposes of example and illustration only, and is not intended to be limiting. GUI 800 can have a different organization or structure, and/or can have additional or fewer regions than described herein, in accordance with embodiments of the present disclosure. Further, GUI 800 can include additional or alternative GUI elements that enables the users to configure or define settings of a simulation, in accordance with embodiments described herein.

Referring back to FIG. 7, at block 712, processing logic provides a prompt associated with the natural language user query as an input to an AI model. In some embodiments, prompt generation module 322 can generate a prompt to be provided as an input to command generator model 258 that will cause command generator model 258 to generate a set of simulation operations including simulation command 262 to perform a set of actions pertaining to the one or more assets indicated by the natural language query. Asset memory subsystem 214 may identify simulation events (e.g., of prior simulations or of other simulations performed at other systems) that are relevant to the context of the simulation requested by the user. In accordance with previously described embodiments, asset memory subsystem 214 can identify memory data objects and/or embeddings of long-term historical data structure 254 that are relevant to the context of the requested simulation and can provide the simulation events of such identified memory data objects and/or embeddings to asset command subsystem 216, as described herein. In accordance with previous illustrative embodiments, the simulation events provided by asset memory subsystem 214 can be simulation events of another simulation of a virtual warehouse environment. Prompt generation module 322 can generate the prompt for command generator model 258 to include information of the natural language query (e.g., the type of simulation environment, the assets of the simulation, etc.) and/or the simulation events provided by asset memory subsystem 214. Command generation module 324 can provide the generated prompt as an input to command generator model 258, in accordance with previously described embodiments.

At block 714, processing logic extracts, from one or more outputs of the AI model, one or more simulation operations associated with a set of actions pertaining to the one or more assets. As described herein, the one or more outputs of command generator model 258 can include an indication of one or more actions or activities to be performed with respect to assets of the simulation and a set of operations including simulation command 262 that, when executed by simulation engine 141, cause the actions or activities to be simulated with respect to the assets. In some embodiments, the one or more simulation operations can include a sequence of simulation commands 262 that are to be performed throughout the duration of the simulation, in accordance with the purpose or context of the simulation. Such simulation command 262 can be included or otherwise used to generate an initialization model file 204A that, when executed, generates the rendering of the simulation, as described herein. As described herein, command queue module 306 can add the simulation command 262 of the one or more outputs of command generator model 258 to command queue 308. In some embodiments, natural language descriptor module 326 can obtain a natural language description of the actions or activities performed with respect to the assets of the simulation, in accordance with previously described embodiments.

At block 716, processing logic performs the one or more simulation operations to generate a rendering of the set of actions pertaining to the one or more assets in accordance with the simulation. Simulation engine 141 can execute the simulation commands 262 included in command queue 308, as described herein. Model engine 151 can generate and/or update a model file 204 associated with the simulation and rendering engine 162 can generate the rendered asset(s) 208 of the simulation, as described above. At block 718, processing logic provides the generated rendering to a client device in accordance with the request. As illustrated by FIG. 8B, client device 102 can update GUI 800 to include the rendered asset(s) 208 in the simulation region 802.

In some embodiments, upon receiving the natural language user query for the simulation via GUI 800, asset management engine 131 can instantiate a respective agent 132 for each asset referenced by the natural language user query. Additionally or alternatively, asset management engine 131 can allocate a region of short-term historical data structure 252 to store memory data objects associated with each respective asset, as described herein. During the simulation, asset management engine 131 can update or obtain additional simulation commands 262 for assets of the simulation, based on the evolution of the simulated scene.

FIG. 9 is a block diagram of an example predictive system 180, according to at least one embodiment. In some embodiments, predictive system 180 can be configured to train one or more artificial intelligence models 960, such as memory relevance model 256, command generator model 258, and/or scene description model 260.

Artificial intelligence models 960 can include one or more language models (e.g., LLMs), as described above, or any other type of artificial intelligence models that are trained to perform tasks pertaining to the above described embodiments. For example, machine learning models 960 can include AI models that employ or implement techniques including, but not limited to, neural network techniques (e.g., artificial neural network, convolutional neural network, etc.), support vector machine (SVM) techniques, decision-making techniques, logistic regression techniques, linear regression techniques, random forest techniques, Naïve Bayes classifier techniques, K-nearest neighbors techniques, K-means clustering, regression analysis techniques, vector-based techniques, principal component analysis techniques, hierarchical clustering techniques, logistics-based techniques, normal distribution techniques, XGBoost techniques, gradient boosting techniques, decision tree learning techniques, AdaBoost techniques, boosting techniques, Bayesian inference techniques, ridge regression techniques, stochastic gradient descent techniques, and so forth.

As illustrated in FIG. 9, predictive system 180 can include a training set generator 912 (e.g., residing at server machine 910), a training engine 922, a validation engine 924, a selection engine 926, and/or a testing engine 928 (e.g., each residing at server machine 920), and/or a predictive component 952 (e.g., residing at server machine 950). Training set generator 912 may be capable of generating training data (e.g., a set of training inputs and a set of target outputs) to train model(s) 960. Artificial intelligence models 960 (collectively and individually referred to as model 960 herein) can include one or more LLMs, as described above, or any other type of machine learning model that is trained to perform tasks pertaining to the above described embodiments. Each LLM can include a general-purpose LLM (e.g., a LLM trained on a wide variety of data, making it capable of handling a broad range of tasks across different domains) or a specific-purpose LLM or domain-specific LLM (e.g., a LLM trained to perform specific tasks associated with a particular purpose of domain).

As mentioned above, training set generator 912 can generate training data for training model 960. Training set generator 912 obtain training data for training model 960 and can organize or otherwise group the training data for training model 960 (e.g., according to the purpose of the model). In some embodiments, training set generator 912 can initialize a training set T (e.g., for training a respective model 960) to null (e.g., { }). The training data included in the training set T to train a respective model 960 may depend on the type of task to be performed by the model 960. For example, as described herein, memory relevance model 256 may be trained to predict a degree of relevance between a current context or a current scene of a simulation and memory data objects and/or embeddings associated with prior simulation events of the simulation (e.g., as stored in long-term historical data structure 254). In some embodiments, the training data used to train memory relevance model 256 can include one or more pairs of simulation scene context description and memory data objects and/or embeddings and an indication of a degree of relevance between the simulation scene context description and the memory data objects and/or embeddings. The degree of relevance can include a binary value (e.g., “0” or “1”) indicating relevance (e.g., “1”) or non-relevance (e.g., “0”) and/or can include an integer or percentage value indicating the degree of relevance. For example, a value of “0” can indicate no relevance, a value of “0.5” or “50%” can indicate partial relevance, and a value of “1” can indicate full relevance. Other types of data can be used to indicate the degree of relevance, in accordance with embodiments described herein. The data used to train the memory relevance model 256 can include simulation event data captured for prior simulations at system 100 and/or simulations performed at other systems, in some embodiments.

In another example, as described herein, command generator model 258 can be trained to predict an action or activity to be performed with respect to an asset of a simulation and/or to generate simulation operations associated with the asset, where the simulation operations can include or otherwise correspond to simulation command 262 that, when executed cause the action or activity to be performed with respect to the asset in accordance with the simulation. In such example, the training data set can include a simulation scene context description (e.g., of a prior simulation), one or more simulation events associated with the prior simulation, and/or an action or activity performed with respect to an asset in response to or in view of the one or more simulation events. Additionally or alternatively, the training data set can include simulation operations associated with the performed action or activity.

In yet another example, as described herein, scene description model 260 can be trained to generate a natural language description of a current context or a current scene of a simulation. In such example, the training data set can include simulation data associated with a prior simulation (e.g., a model file 204, a set of simulation operations or commands, an indication of an outcome of the simulation based on the performance of the set of simulation operations or commands, etc.) and a natural language description of the context or scene of the prior simulation. The natural language description may be provided by a user of system 100 (or another system that performed the simulation) or can be obtained in accordance with other techniques.

Upon obtaining training data, as described above, training set generator 912 can add the training data to the training set T and can determine whether training set T is sufficient for training model 960. Training set T can be sufficient for training model 960 if training set T includes a threshold amount of training data, in some embodiments. In response to determining that training set T is not sufficient for training, training set generator 912 can identify additional data and can generate additional training data based on the additional data. In response to determining that training set T is sufficient for training, training set generator 912 can provide training set T to train model 960. In some embodiments, training set generator 912 provides the training set T to training engine 922.

Training engine 922 can train a machine learning model 960 using the training data (e.g., training set T) from training set generator 912. The artificial intelligence model 960 can refer to the model artifact that is created by the training engine 922 using the training data that includes training inputs and/or corresponding target outputs (correct answers for respective training inputs). The training engine 922 can find patterns in the training data that map the training input to the target output (the answer to be predicted), and provide the machine learning model 960 that captures these patterns. The machine learning model 960 can be composed of, e.g., a single level of linear or non-linear operations (e.g., a support vector machine (SVM or may be a deep network, i.e., a machine learning model that is composed of multiple levels of non-linear operations). An example of a deep network is a neural network with one or more hidden layers, and such a machine learning model may be trained by, for example, adjusting weights of a neural network in accordance with a backpropagation learning algorithm or the like. In one aspect, the training set is obtained by training set generator 912 hosted by server machine 910.

Validation engine 924 may be capable of validating a trained machine learning model 960 using a corresponding set of features of a validation set from training set generator 912. The validation engine 924 may determine an accuracy of each of the trained AI models 960 based on the corresponding sets of features of the validation set. The validation engine 924 may discard a trained model 960 that has an accuracy that does not meet a threshold accuracy. In some embodiments, the selection engine 926 may be capable of selecting a trained model 960 that has an accuracy that meets a threshold accuracy. In some embodiments, the selection engine 926 may be capable of selecting the trained model 960 that has the highest accuracy of the trained models 960.

The testing engine 928 may be capable of testing a trained model 960 using a corresponding set of features of a testing set from training set generator 912. For example, a first trained model 960 that was trained using a first set of features of the training set may be tested using the first set of features of the testing set. The testing engine 928 may determine a trained model 960 that has the highest accuracy of all of the trained models 960 based on the testing sets.

As described above, predictive system 180 can be configured to train a large language model. It should be noted that predictive system 180 can train the large language model in accordance with embodiments described herein and/or in accordance with other techniques for training a large language model. For example, large language model may be trained on a large amount of data, including prediction of one or more missing words in a sentence, identification of whether two consecutive sentences are logically related to each other, generation of next texts based on prompts, etc.

Predictive component 552 of server machine 550 may be configured to feed data as input to model 560 and obtain one or more outputs. As illustrated in FIG. 5, predictive component 552 can include asset management engine 121. Asset management engine 131 can feed data as input to model(s) 960, in accordance with previously described embodiments.

As noted above, although embodiments of the present disclosure are described with respect to simulations of assets in a virtual environment, such embodiments can also be applied to embodiments relating to robotic components in a real-world environment. FIG. 10 depicts an example method 1000 of performing robotic operations to cause a robotic component to perform an action predicted by an AI model, according to at least one embodiment. In some embodiments, method 1000 can be performed by computing device 120. For example, one or more operations of method 1000 can be performed by robotics engine 161, in some embodiments, in some embodiments. Method 1000 may be performed by one or more processing units (e.g., CPUs and/or GPUs), which may include (or communicate with) one or more memory devices. In at least one embodiment, method 1000 may be performed by multiple processing threads (e.g., CPU threads and/or GPU threads), each thread executing one or more individual functions, routines, subroutines, or operations of the method. In at least one embodiment, processing threads implementing method 1000 may be synchronized (e.g., using semaphores, critical sections, and/or other thread synchronization mechanisms). Alternatively, processing threads implementing method 1000 may be executed asynchronously with respect to each other. Various operations of method 1000 may be performed in a different order compared with the order shown in FIG. 10. Some operations of the methods may be performed concurrently with other operations. In at least one embodiment, one or more operations shown in FIG. 10 may not always be performed.

At block 1010, processing logic receives sensor data collected by one or more sensor components monitoring a real-world environment including one or more robotic components. The sensor components can include sensor(s) 104, described with respect to FIG. 1. For example, the sensor data can include camera sensors, LIDAR sensors, ultrasonic sensors, infrared (IR) sensors, inertial measurement unit (IMU) sensors, force/torque sensors, and so forth. A robotic component can include any component of a robotic device, including but not limited to a robotic arm, a drown, an autonomous vehicle, an industrial robot, and so forth. Sensor(s) 104 can collect sensor data representing conditions of the real-world environment that includes the robotic component and can provide (e.g., transmit) the collected sensor data to computing device 120 (e.g., via network 110).

At block 1012, processing logic identifies short-term historical data associated with at least one robotic component of the one or more robotic components. The short-term historical data includes one or more first prior activities of the at least one robotic component. In accordance with previously described embodiments, asset management engine 131 can instantiate an agent 132 for each robotic component of the real-world environment (e.g., during initialization of the robotic component). Short-term historical data associated with the robotic component can be stored at short-term historical data structure 252 and long-term historical data and/or embeddings generated based on long-term historical data can be stored at long-term historical data structure 254, as described herein. The agent 132 for the robotic component can receive the collected sensor data and can send a request to new command module 302 for a new command for an action or activity to be performed with respect to the robotic component in view of the collected sensor data. Asset memory subsystem 214 can identify memory data objects associated with the robotic component from short-term historical data structure 252, as described herein, which can indicate the one or more first prior activities of the robotic component.

At block 1014, processing logic identifies long-term historical data associated with the real-world environment. The long-term historical data includes one or more second prior activities of the at one robotic component and/or one or more additional objects of the real-world environment. Asset memory subsystem 214 can identify memory data objects and/or embeddings from long-term historical data structure 254 that are relevant to the current context of the real-world environment, based on the sensor data, as described herein. For example, asset memory subsystem 214 can obtain a natural language description of the current context of the real-world environment (e.g., from environment state module 304 and/or based on one or more outputs of scene description model 260), as described above, and can identify entries that include memory data objects and/or embeddings that have a degree of relevance to the current context that satisfy the relevance criteria, as described herein. The memory data objects and/or embeddings can include or otherwise correspond to the second prior activities of the robotic component and/or the additional object(s) of the real-world environment.

At block 1016, processing logic provides the short-term historical data and the long-term historical data as an input to an AI model. Asset memory subsystem 214 can provide the short-term historical data and/or the long-term historical data to asset command subsystem 216 and asset command subsystem can provide a prompt associated with the short-term historical data and/or the long-term historical data as an input to command generator model 258, as described above. At block 1018, processing logic extracts, from one or more outputs of the AI model, an action associated with the at least one robotic component in view of the short-term historical data and the long-term historical data, and/or one or more robotic operations associated with the action. Command generator model 258 can predict an action or activity to be performed with respect to the robotic component based on the given prompt, as described above. The one or more robotic operations can include robotic commands that, when executed by robotics engine 161, cause the action or activity to be performed with respect to the robotic component. The output(s) of command generator model 258 can additionally or alternatively include a natural language description of the action or activity, and natural language descriptor module 326 can extract the natural language description from the output(s), as described above. At block 1020, processing logic performs the one or more robotic operations to cause the at least one robotic component to perform the action. Robotics engine 161 can execute the robotic commands of the one or more robotic operations which cause the robotic component to perform the action or activity, in some embodiments.

### Inference and Training Logic

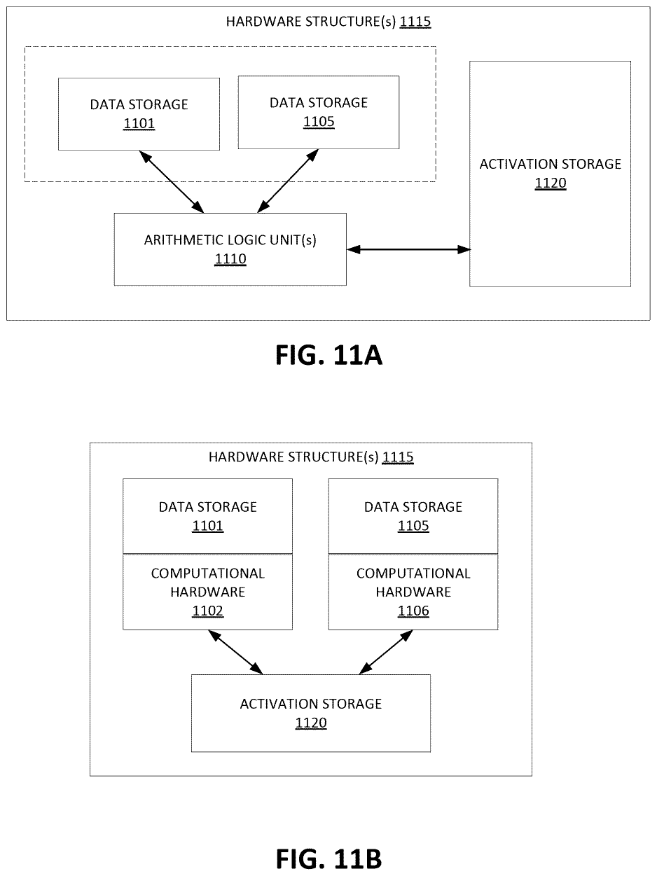

FIG. 11A illustrates inference and/or training logic 1115 used to perform inferencing and/or training operations associated with one or more embodiments. Details regarding inference and/or training logic 1115 are provided below in conjunction with FIGS. 11A and/or 11B.

In at least one embodiment, inference and/or training logic 1115 may include, without limitation, code and/or data storage 1101 to store forward and/or output weight and/or input/output data, and/or other parameters to configure neurons or layers of a neural network trained and/or used for inferencing in aspects of one or more embodiments. In at least one embodiment, training logic 1115 may include, or be coupled to code and/or data storage 1101 to store graph code or other software to control timing and/or order, in which weight and/or other parameter information is to be loaded to configure, logic, including integer and/or floating point units (collectively, arithmetic logic units (ALUs). In at least one embodiment, code, such as graph code, loads weight or other parameter information into processor ALUs based on an architecture of a neural network to which the code corresponds. In at least one embodiment, code and/or data storage 1101 stores weight parameters and/or input/output data of each layer of a neural network trained or used in conjunction with one or more embodiments during forward propagation of input/output data and/or weight parameters during training and/or inferencing using aspects of one or more embodiments. In at least one embodiment, any portion of code and/or data storage 1101 may be included with other on-chip or off-chip data storage, including a processor's L1, L2, or L3 cache or system memory.

In at least one embodiment, any portion of code and/or data storage 1101 may be internal or external to one or more processors or other hardware logic devices or circuits. In at least one embodiment, code and/or code and/or data storage 1101 may be cache memory, dynamic randomly addressable memory (“DRAM”), static randomly addressable memory (“SRAM”), non-volatile memory (e.g., Flash memory), or other storage. In at least one embodiment, choice of whether code and/or code and/or data storage 1101 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors.

In at least one embodiment, inference and/or training logic 1115 may include, without limitation, a code and/or data storage 1105 to store backward and/or output weight and/or input/output data corresponding to neurons or layers of a neural network trained and/or used for inferencing in aspects of one or more embodiments. In at least one embodiment, code and/or data storage 1105 stores weight parameters and/or input/output data of each layer of a neural network trained or used in conjunction with one or more embodiments during backward propagation of input/output data and/or weight parameters during training and/or inferencing using aspects of one or more embodiments. In at least one embodiment, training logic 1115 may include, or be coupled to code and/or data storage 1105 to store graph code or other software to control timing and/or order, in which weight and/or other parameter information is to be loaded to configure, logic, including integer and/or floating point units (collectively, arithmetic logic units (ALUs). In at least one embodiment, code, such as graph code, loads weight or other parameter information into processor ALUs based on an architecture of a neural network to which the code corresponds. In at least one embodiment, any portion of code and/or data storage 1105 may be included with other on-chip or off-chip data storage, including a processor's L1, L2, or L3 cache or system memory. In at least one embodiment, any portion of code and/or data storage 1105 may be internal or external to on one or more processors or other hardware logic devices or circuits. In at least one embodiment, code and/or data storage 1105 may be cache memory, DRAM, SRAM, non-volatile memory (e.g., Flash memory), or other storage. In at least one embodiment, choice of whether code and/or data storage 1105 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors.

In at least one embodiment, code and/or data storage 1101 and code and/or data storage 1105 may be separate storage structures. In at least one embodiment, code and/or data storage 1101 and code and/or data storage 1105 may be same storage structure. In at least one embodiment, code and/or data storage 1101 and code and/or data storage 1105 may be partially same storage structure and partially separate storage structures. In at least one embodiment, any portion of code and/or data storage 1101 and code and/or data storage 1105 may be included with other on-chip or off-chip data storage, including a processor's L1, L2, or L3 cache or system memory.

In at least one embodiment, inference and/or training logic 1115 may include, without limitation, one or more arithmetic logic unit(s) (“ALU(s)”) 1110, including integer and/or floating point units, to perform logical and/or mathematical operations based, at least in part on, or indicated by, training and/or inference code (e.g., graph code), a result of which may produce activations (e.g., output values from layers or neurons within a neural network) stored in an activation storage 1120 that are functions of input/output and/or weight parameter data stored in code and/or data storage 1101 and/or code and/or data storage 1105. In at least one embodiment, activations stored in activation storage 1120 are generated according to linear algebraic and or matrix-based mathematics performed by ALU(s) 1110 in response to performing instructions or other code, wherein weight values stored in code and/or data storage 1105 and/or code and/or data storage 1101 are used as operands along with other values, such as bias values, gradient information, momentum values, or other parameters or hyperparameters, any or all of which may be stored in code and/or data storage 1105 or code and/or data storage 1101 or another storage on or off-chip.

In at least one embodiment, ALU(s) 1110 are included within one or more processors or other hardware logic devices or circuits, whereas in another embodiment, ALU(s) 1110 may be external to a processor or other hardware logic device or circuit that uses them (e.g., a co-processor). In at least one embodiment, ALUs 1110 may be included within a processor's execution units or otherwise within a bank of ALUs accessible by a processor's execution units either within same processor or distributed between different processors of different types (e.g., central processing units, graphics processing units, fixed function units, etc.). In at least one embodiment, code and/or data storage 1101, code and/or data storage 1105, and activation storage 1120 may be on same processor or other hardware logic device or circuit, whereas in another embodiment, they may be in different processors or other hardware logic devices or circuits, or some combination of same and different processors or other hardware logic devices or circuits. In at least one embodiment, any portion of activation storage 1120 may be included with other on-chip or off-chip data storage, including a processor's L1, L2, or L3 cache or system memory. Furthermore, inferencing and/or training code may be stored with other code accessible to a processor or other hardware logic or circuit and fetched and/or processed using a processor's fetch, decode, scheduling, execution, retirement and/or other logical circuits.

In at least one embodiment, activation storage 1120 may be cache memory, DRAM, SRAM, non-volatile memory (e.g., Flash memory), or other storage. In at least one embodiment, activation storage 1120 may be completely or partially within or external to one or more processors or other logical circuits. In at least one embodiment, choice of whether activation storage 1120 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors. In at least one embodiment, inference and/or training logic 1115 illustrated in FIG. 11A may be used in conjunction with an application-specific integrated circuit (“ASIC”), such as Tensorflow® Processing Unit from Google, an inference processing unit (IPU) from Graphcore™, or a Nervana® (e.g., “Lake Crest”) processor from Intel Corp. In at least one embodiment, inference and/or training logic 1115 illustrated in FIG. 11A may be used in conjunction with central processing unit (“CPU”) hardware, graphics processing unit (“GPU”) hardware or other hardware, such as data processing unit (“DPU”) hardware, or field programmable gate arrays (“FPGAs”).

FIG. 11B illustrates inference and/or training logic 1115, according to at least one or more embodiments. In at least one embodiment, inference and/or training logic 1115 may include, without limitation, hardware logic in which computational resources are dedicated or otherwise exclusively used in conjunction with weight values or other information corresponding to one or more layers of neurons within a neural network. In at least one embodiment, inference and/or training logic 1115 illustrated in FIG. 11B may be used in conjunction with an application-specific integrated circuit (ASIC), such as Tensorflow® Processing Unit from Google, an inference processing unit (IPU) from Graphcore™, or a Nervana® (e.g., “Lake Crest”) processor from Intel Corp. In at least one embodiment, inference and/or training logic 1115 illustrated in FIG. 11B may be used in conjunction with central processing unit (CPU) hardware, graphics processing unit (GPU) hardware or other hardware, such as data processing unit (“DPU”) hardware, or field programmable gate arrays (FPGAs). In at least one embodiment, inference and/or training logic 1115 includes, without limitation, code and/or data storage 1101 and code and/or data storage 1105, which may be used to store code (e.g., graph code), weight values and/or other information, including bias values, gradient information, momentum values, and/or other parameter or hyperparameter information. In at least one embodiment illustrated in FIG. 11B, each of code and/or data storage 1101 and code and/or data storage 1105 is associated with a dedicated computational resource, such as computational hardware 1102 and computational hardware 1106, respectively. In at least one embodiment, each of computational hardware 1102 and computational hardware 1106 comprises one or more ALUs that perform mathematical functions, such as linear algebraic functions, only on information stored in code and/or data storage 1101 and code and/or data storage 1105, respectively, result of which is stored in activation storage 1120.

In at least one embodiment, each of code and/or data storage 1101 and 1105 and corresponding computational hardware 1102 and 1106, respectively, correspond to different layers of a neural network, such that resulting activation from one “storage/computational pair 1101/1102” of code and/or data storage 1101 and computational hardware 1102 is provided as an input to “storage/computational pair 1105/1106” of code and/or data storage 1105 and computational hardware 1106, in order to mirror conceptual organization of a neural network. In at least one embodiment, each of storage/computational pairs 1101/1102 and 1105/1106 may correspond to more than one neural network layer. In at least one embodiment, additional storage/computation pairs (not shown) subsequent to or in parallel with storage computation pairs 1101/1102 and 1105/1106 may be included in inference and/or training logic 1115.

### Data Center

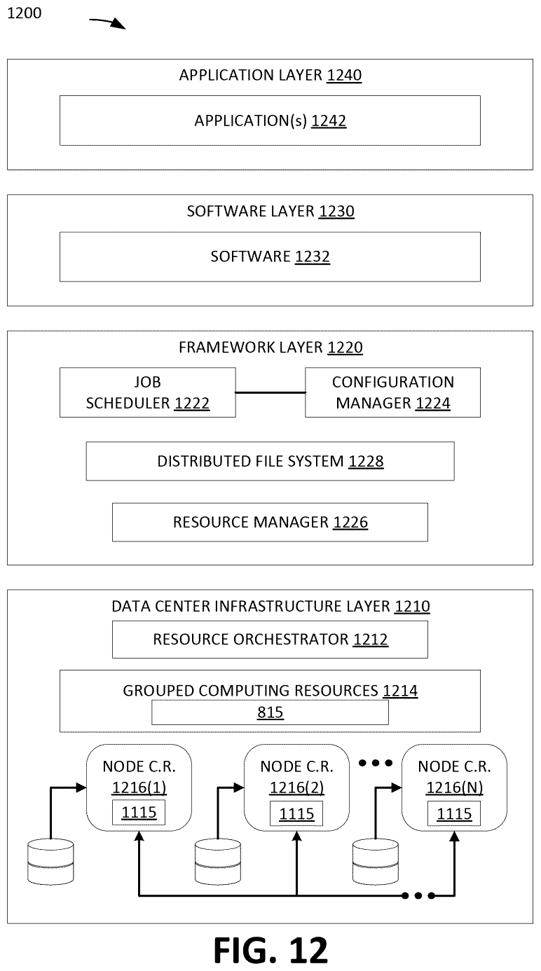

FIG. 12 illustrates an example data center 1200, in which at least one embodiment may be used. In at least one embodiment, data center 1200 includes a data center infrastructure layer 1210, a framework layer 1220, a software layer 1230, and an application layer 1240.

In at least one embodiment, as shown in FIG. 12, data center infrastructure layer 1210 may include a resource orchestrator 1212, grouped computing resources 1214, and node computing resources (“node C.R.s”) 1216(1)-1216(N), where “N” represents any whole, positive integer. In at least one embodiment, node C.R.s 1216(1)-1216(N) may include, but are not limited to, any number of central processing units (“CPUs”) or other processors (including accelerators, field programmable gate arrays (FPGAs), data processing units, graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 1216(1)-1216(N) may be a server having one or more of above-mentioned computing resources.

In at least one embodiment, grouped computing resources 1214 may include separate groupings of node C.R.s housed within one or more racks (not shown), or many racks housed in data centers at various geographical locations (also not shown). Separate groupings of node C.R.s within grouped computing resources 1214 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 1212 may configure or otherwise control one or more node C.R.s 1216(1)-1216(N) and/or grouped computing resources 1214. In at least one embodiment, resource orchestrator 1212 may include a software design infrastructure (“SDI”) management entity for data center 1200. In at least one embodiment, resource orchestrator may include hardware, software or some combination thereof.

In at least one embodiment, as shown in FIG. 12, framework layer 1220 includes a job scheduler 1222, a configuration manager 1224, a resource manager 1226 and a distributed file system 1228. In at least one embodiment, framework layer 1220 may include a framework to support software 1232 of software layer 1230 and/or one or more application(s) 1242 of application layer 1240. In at least one embodiment, software 1232 or application(s) 1242 may respectively include web-based service software or applications, such as those provided by Amazon Web Services, Google Cloud and Microsoft Azure. In at least one embodiment, framework layer 1220 may be, but is not limited to, a type of free and open-source software web application framework such as Apache Spark™ (hereinafter “Spark”) that may utilize distributed file system 1228 for large-scale data processing (e.g., “big data”). In at least one embodiment, job scheduler 1222 may include a Spark driver to facilitate scheduling of workloads supported by various layers of data center 1200. In at least one embodiment, configuration manager 1224 may be capable of configuring different layers such as software layer 1230 and framework layer 1220 including Spark and distributed file system 1228 for supporting large-scale data processing. In at least one embodiment, resource manager 1226 may be capable of managing clustered or grouped computing resources mapped to or allocated for support of distributed file system 1228 and job scheduler 1222. In at least one embodiment, clustered or grouped computing resources may include grouped computing resource 1214 at data center infrastructure layer 1210. In at least one embodiment, resource manager 1226 may coordinate with resource orchestrator 1212 to manage these mapped or allocated computing resources.

In at least one embodiment, software 1232 included in software layer 1230 may include software used by at least portions of node C.R.s 1216(1)-1216(N), grouped computing resources 1214, and/or distributed file system 1228 of framework layer 1220. The one or more types of software may include, but are not limited to, Internet web page search software, e-mail virus scan software, database software, and streaming video content software.

In at least one embodiment, application(s) 1242 included in application layer 1240 may include one or more types of applications used by at least portions of node C.R.s 1216(1)-1216(N), grouped computing resources 1214, and/or distributed file system 1228 of framework layer 1220. One or more types of applications may include, but are not limited to, any number of a genomics application, a cognitive compute, and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 1224, resource manager 1226, and resource orchestrator 1212 may implement any number and type of self-modifying actions based on any amount and type of data acquired in any technically feasible fashion. In at least one embodiment, self-modifying actions may relieve a data center operator of data center 1200 from making possibly bad configuration decisions and possibly avoiding underutilized and/or poor performing portions of a data center.

In at least one embodiment, data center 1200 may include tools, services, software, or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 1200. In at least one embodiment, trained machine learning models corresponding to one or more neural networks may be used to infer or predict information using resources described above with respect to data center 1200 by using weight parameters calculated through one or more training techniques described herein.

In at least one embodiment, data center may use CPUs, application-specific integrated circuits (ASICs), GPUs, DPUs FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 1115 are used to perform inferencing and/or training operations associated with one or more embodiments. Details regarding inference and/or training logic 1115 are provided below in conjunction with FIGS. 11A and/or 11B. In at least one embodiment, inference and/or training logic 1115 may be used in system FIG. 12 for inferencing or predicting operations based, at least in part, on weight parameters calculated using neural network training operations, neural network functions and/or architectures, or neural network use cases described herein.

Such components may be used to generate synthetic data imitating failure cases in a network training process, which may help to improve performance of the network while limiting the amount of synthetic data to avoid overfitting.

### Computer Systems

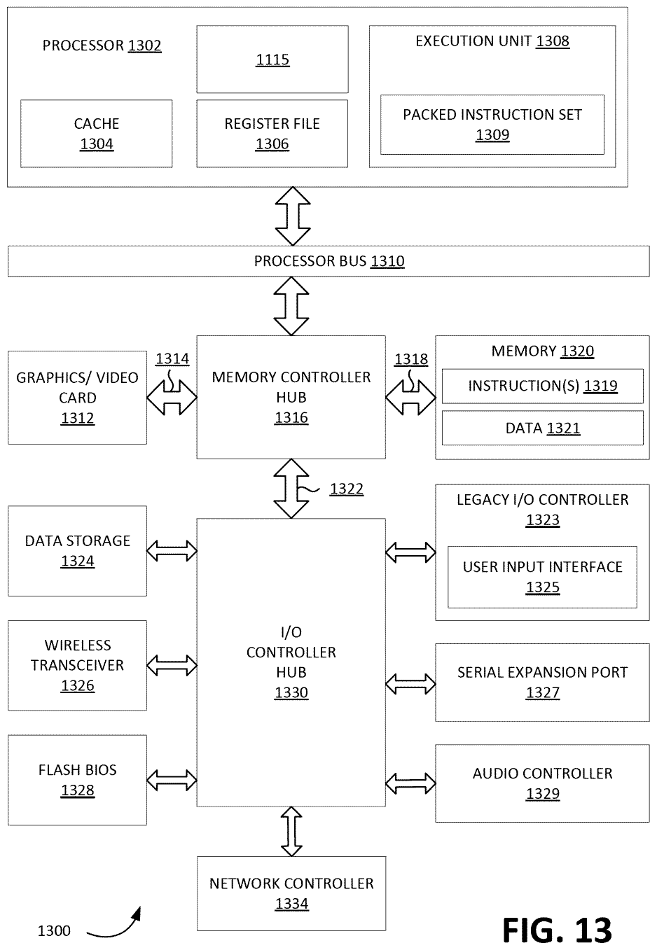

FIG. 13 is a block diagram illustrating an exemplary computer system, which may be a system with interconnected devices and components, a system-on-a-chip (SOC) or some combination thereof 1300 formed with a processor that may include execution units to execute an instruction, according to at least one embodiment. In at least one embodiment, computer system 1300 may include, without limitation, a component, such as a processor 1302 to employ execution units including logic to perform algorithms for process data, in accordance with present disclosure, such as in embodiment described herein. In at least one embodiment, computer system 1300 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 1300 may execute a version of WINDOWS' operating system available from Microsoft Corporation of Redmond, Wash., although other operating systems (UNIX and Linux for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), system on a chip, network computers (“NetPCs”), set-top boxes, network hubs, wide area network (“WAN”) switches, edge devices, Internet-of-Things (“IoT”) devices, or any other system that may perform one or more instructions in accordance with at least one embodiment.

In at least one embodiment, computer system 1300 may include, without limitation, processor 1302 that may include, without limitation, one or more execution units 1308 to perform machine learning model training and/or inferencing according to techniques described herein. In at least one embodiment, computer system 1300 is a single processor desktop or server system, but in another embodiment computer system 1300 may be a multiprocessor system. In at least one embodiment, processor 1302 may include, without limitation, a complex instruction set computer (“CISC”) microprocessor, a reduced instruction set computing (“RISC”) microprocessor, a very long instruction word (“VLIW”) microprocessor, a processor implementing a combination of instruction sets, or any other processor device, such as a digital signal processor, for example. In at least one embodiment, processor 1302 may be coupled to a processor bus 1310 that may transmit data signals between processor 1302 and other components in computer system 1300.

In at least one embodiment, processor 1302 may include, without limitation, a Level 1 (“L1”) internal cache memory (“cache”) 1304. In at least one embodiment, processor 1302 may have a single internal cache or multiple levels of internal cache. In at least one embodiment, cache memory may reside external to processor 1302. Other embodiments may also include a combination of both internal and external caches depending on particular implementation and needs. In at least one embodiment, register file 1306 may store different types of data in various registers including, without limitation, integer registers, floating point registers, status registers, and instruction pointer register.

In at least one embodiment, execution unit 1308, including, without limitation, logic to perform integer and floating point operations, also resides in processor 1302. In at least one embodiment, processor 1302 may also include a microcode (“ucode”) read only memory (“ROM”) that stores microcode for certain macro instructions. In at least one embodiment, execution unit 1308 may include logic to handle a packed instruction set 1309. In at least one embodiment, by including packed instruction set 1309 in an instruction set of a general-purpose processor 1302, along with associated circuitry to execute instructions, operations used by many multimedia applications may be performed using packed data in a general-purpose processor 1302. In one or more embodiments, many multimedia applications may be accelerated and executed more efficiently by using full width of a processor's data bus for performing operations on packed data, which may eliminate need to transfer smaller units of data across processor's data bus to perform one or more operations one data element at a time.

In at least one embodiment, execution unit 1308 may also be used in microcontrollers, embedded processors, graphics devices, DSPs, and other types of logic circuits. In at least one embodiment, computer system 1300 may include, without limitation, a memory 1320. In at least one embodiment, memory 1320 may be implemented as a Dynamic Random Access Memory (“DRAM”) device, a Static Random Access Memory (“SRAM”) device, flash memory device, or other memory device. In at least one embodiment, memory 1320 may store instruction(s) 1319 and/or data 1321 represented by data signals that may be executed by processor 1302.

In at least one embodiment, system logic chip may be coupled to processor bus 1310 and memory 1320. In at least one embodiment, system logic chip may include, without limitation, a memory controller hub (“MCH”) 1316, and processor 1302 may communicate with MCH 1316 via processor bus 1310. In at least one embodiment, MCH 1316 may provide a high bandwidth memory path 1318 to memory 1320 for instruction and data storage and for storage of graphics commands, data and textures. In at least one embodiment, MCH 1316 may direct data signals between processor 1302, memory 1320, and other components in computer system 1300 and to bridge data signals between processor bus 1310, memory 1320, and a system I/O 1322. In at least one embodiment, system logic chip may provide a graphics port for coupling to a graphics controller. In at least one embodiment, MCH 1316 may be coupled to memory 1320 through a high bandwidth memory path 1318 and graphics/video card 1312 may be coupled to MCH 1316 through an Accelerated Graphics Port (“AGP”) interconnect 1314.

In at least one embodiment, computer system 1300 may use system I/O 1322 that is a proprietary hub interface bus to couple MCH 1316 to I/O controller hub (“ICH”) 1330. In at least one embodiment, ICH 1330 may provide direct connections to some I/O devices via a local I/O bus. In at least one embodiment, local I/O bus may include, without limitation, a high-speed I/O bus for connecting peripherals to memory 1320, chipset, and processor 1302. Examples may include, without limitation, an audio controller 1329, a firmware hub (“flash BIOS”) 1328, a wireless transceiver 1326, a data storage 1324, a legacy I/O controller 1323 containing user input and keyboard interfaces 1325, a serial expansion port 1327, such as Universal Serial Bus (“USB”), and a network controller 1334, which may include in some embodiments, a data processing unit. Data storage 1324 may comprise a hard disk drive, a floppy disk drive, a CD-ROM device, a flash memory device, or other mass storage device.

In at least one embodiment, FIG. 13 illustrates a system, which includes interconnected hardware devices or “chips”, whereas in other embodiments, FIG. 13 may illustrate an exemplary System on a Chip (“SoC”). In at least one embodiment, devices may be interconnected with proprietary interconnects, standardized interconnects (e.g., PCIe) or some combination thereof. In at least one embodiment, one or more components of computer system 1300 are interconnected using compute express link (CXL) interconnects.

Inference and/or training logic 1115 are used to perform inferencing and/or training operations associated with one or more embodiments. Details regarding inference and/or training logic 1115 are provided below in conjunction with FIGS. 11A and/or 11B. In at least one embodiment, inference and/or training logic 1115 may be used in system FIG. 13 for inferencing or predicting operations based, at least in part, on weight parameters calculated using neural network training operations, neural network functions and/or architectures, or neural network use cases described herein.

Such components may be used to generate synthetic data imitating failure cases in a network training process, which may help to improve performance of the network while limiting the amount of synthetic data to avoid overfitting.

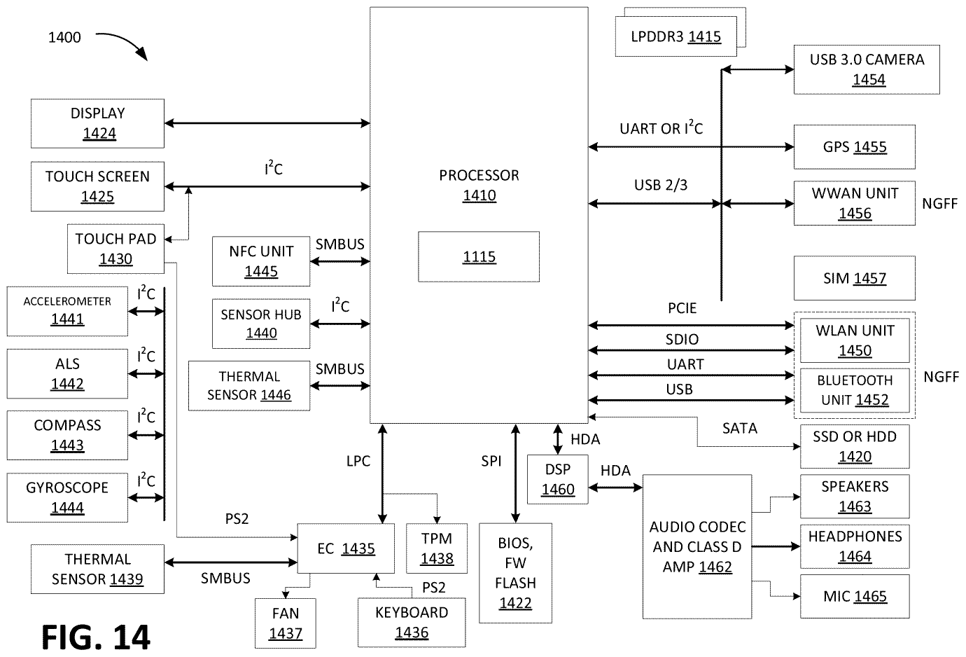

FIG. 14 is a block diagram illustrating an electronic device 1400 for utilizing a processor 1410, according to at least one embodiment. In at least one embodiment, electronic device 1400 may be, for example and without limitation, a notebook, a tower server, a rack server, a blade server, a laptop, a desktop, a tablet, a mobile device, a phone, an embedded computer, an edge device, an IoT device, or any other suitable electronic device.

In at least one embodiment, system 1400 may include, without limitation, processor 1410 communicatively coupled to any suitable number or kind of components, peripherals, modules, or devices. In at least one embodiment, processor 1410 coupled using a bus or interface, such as a 1° C. bus, a System Management Bus (“SMBus”), a Low Pin Count (LPC) bus, a Serial Peripheral Interface (“SPI”), a High Definition Audio (“HDA”) bus, a Serial Advance Technology Attachment (“SATA”) bus, a Universal Serial Bus (“USB”) (versions 1, 2, 3), or a Universal Asynchronous Receiver/Transmitter (“UART”) bus. In at least one embodiment, FIG. 14 illustrates a system, which includes interconnected hardware devices or “chips”, whereas in other embodiments, FIG. 14 may illustrate an exemplary System on a Chip (“SoC”). In at least one embodiment, devices illustrated in FIG. 14 may be interconnected with proprietary interconnects, standardized interconnects (e.g., PCIe) or some combination thereof. In at least one embodiment, one or more components of FIG. 14 are interconnected using compute express link (CXL) interconnects.

In at least one embodiment, FIG. 14 may include a display 1424, a touch screen 1425, a touch pad 1430, a Near Field Communications unit (“NFC”) 1445, a sensor hub 1440, a thermal sensor 1446, an Express Chipset (“EC”) 1435, a Trusted Platform Module (“TPM”) 1438, BIOS/firmware/flash memory (“BIOS, FW Flash”) 1422, a DSP 1460, a drive 1420 such as a Solid State Disk (“SSD”) or a Hard Disk Drive (“HDD”), a wireless local area network unit (“WLAN”) 1450, a Bluetooth unit 1452, a Wireless Wide Area Network unit (“WWAN”) 1456, a Global Positioning System (GPS) 1455, a camera (“USB 3.0 camera”) 1454 such as a USB 3.0 camera, and/or a Low Power Double Data Rate (“LPDDR”) memory unit (“LPDDR3”) 1415 implemented in, for example, LPDDR3 standard. These components may each be implemented in any suitable manner.

In at least one embodiment, other components may be communicatively coupled to processor 1410 through components discussed above. In at least one embodiment, an accelerometer 1441, Ambient Light Sensor (“ALS”) 1442, compass 1443, and a gyroscope 1444 may be communicatively coupled to sensor hub 1440. In at least one embodiment, thermal sensor 1439, a fan 1437, a keyboard 1436, and a touch pad 1430 may be communicatively coupled to EC 1435. In at least one embodiment, speaker 1463, headphones 1464, and microphone (“mic”) 1465 may be communicatively coupled to an audio unit (“audio codec and class d amp”) 1462, which may in turn be communicatively coupled to DSP 1460. In at least one embodiment, audio unit 1464 may include, for example and without limitation, an audio coder/decoder (“codec”) and a class D amplifier. In at least one embodiment, SIM card (“SIM”) 1457 may be communicatively coupled to WWAN unit 1456. In at least one embodiment, components such as WLAN unit 1450 and Bluetooth unit 1452, as well as WWAN unit 1456 may be implemented in a Next Generation Form Factor (“NGFF”).

Inference and/or training logic 1115 are used to perform inferencing and/or training operations associated with one or more embodiments. Details regarding inference and/or training logic 1115 are provided below in conjunction with FIGS. 11A and/or 11B. In at least one embodiment, inference and/or training logic 1115 may be used in system FIG. 14 for inferencing or predicting operations based, at least in part, on weight parameters calculated using neural network training operations, neural network functions and/or architectures, or neural network use cases described herein.

Such components may be used to generate synthetic data imitating failure cases in a network training process, which may help to improve performance of the network while limiting the amount of synthetic data to avoid overfitting.

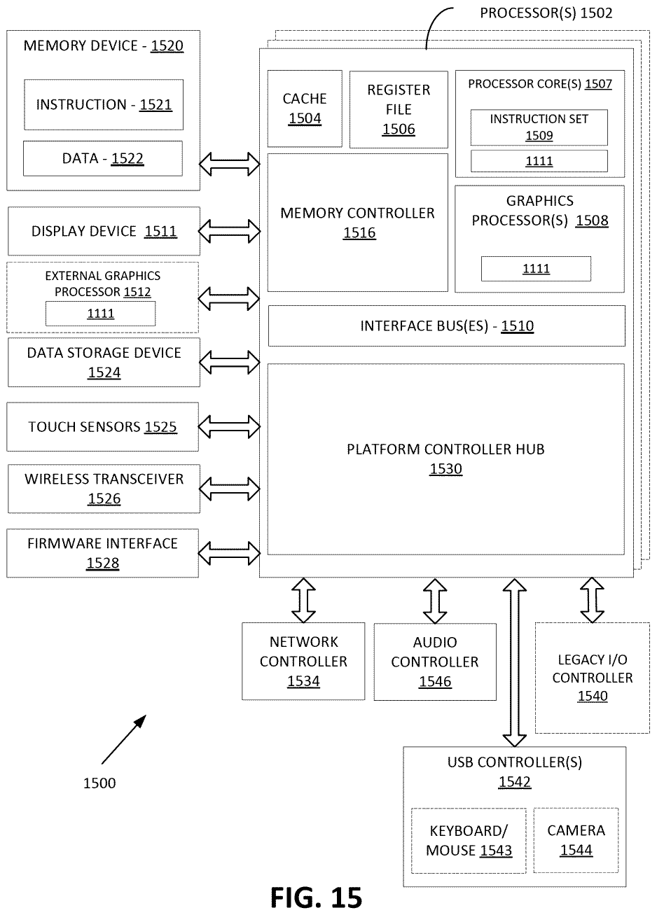

FIG. 15 is a block diagram of a processing system, according to at least one embodiment. In at least one embodiment, system 1500 includes one or more processors 1502 and one or more graphics processors 1508, and may be a single processor desktop system, a multiprocessor workstation system, or a server system having a large number of processors 1502 or processor cores 1507. In at least one embodiment, system 1500 is a processing platform incorporated within a system-on-a-chip (SoC) integrated circuit for use in mobile, handheld, edge, or embedded devices.

In at least one embodiment, system 1500 may include, or be incorporated within a server-based gaming platform, a game console, including a game and media console, a mobile gaming console, a handheld game console, or an online game console. In at least one embodiment, system 1500 is a mobile phone, smart phone, tablet computing device or mobile Internet device. In at least one embodiment, processing system 1500 may also include, couple with, or be integrated within a wearable device, such as a smart watch wearable device, smart eyewear device, augmented reality device, or virtual reality device. In at least one embodiment, processing system 1500 is a television or set top box device having one or more processors 1502 and a graphical interface generated by one or more graphics processors 1508.

In at least one embodiment, one or more processors 1502 each include one or more processor cores 1507 to process instructions which, when executed, perform operations for system and user software. In at least one embodiment, each of one or more processor cores 1507 is configured to process a specific instruction set 1509. In at least one embodiment, instruction set 1509 may facilitate Complex Instruction Set Computing (CISC), Reduced Instruction Set Computing (RISC), or computing via a Very Long Instruction Word (VLIW). In at least one embodiment, processor cores 1507 may each process a different instruction set 1509, which may include instructions to facilitate emulation of other instruction sets. In at least one embodiment, processor core 1507 may also include other processing devices, such a Digital Signal Processor (DSP).

In at least one embodiment, processor 1502 includes cache memory 1504. In at least one embodiment, processor 1502 may have a single internal cache or multiple levels of internal cache. In at least one embodiment, cache memory is shared among various components of processor 1502. In at least one embodiment, processor 1502 also uses an external cache (e.g., a Level-3 (L3) cache or Last Level Cache (LLC)) (not shown), which may be shared among processor cores 1507 using known cache coherency techniques. In at least one embodiment, register file 1506 is additionally included in processor 1502 which may include different types of registers for storing different types of data (e.g., integer registers, floating point registers, status registers, and an instruction pointer register). In at least one embodiment, register file 1506 may include general-purpose registers or other registers.

In at least one embodiment, one or more processor(s) 1502 are coupled with one or more interface bus(es) 1510 to transmit communication signals such as address, data, or control signals between processor 1502 and other components in system 1500. In at least one embodiment, interface bus 1510, in one embodiment, may be a processor bus, such as a version of a Direct Media Interface (DMI) bus. In at least one embodiment, interface 1510 is not limited to a DMI bus, and may include one or more Peripheral Component Interconnect buses (e.g., PCI, PCI Express), memory busses, or other types of interface busses. In at least one embodiment processor(s) 1502 include an integrated memory controller 1516 and a platform controller hub 1530. In at least one embodiment, memory controller 1516 facilitates communication between a memory device and other components of system 1500, while platform controller hub (PCH) 1530 provides connections to I/O devices via a local I/O bus.

In at least one embodiment, memory device 1520 may be a dynamic random access memory (DRAM) device, a static random access memory (SRAM) device, flash memory device, phase-change memory device, or some other memory device having suitable performance to serve as process memory. In at least one embodiment memory device 1520 may operate as system memory for system 1500, to store data 1522 and instructions 1521 for use when one or more processors 1502 executes an application or process. In at least one embodiment, memory controller 1516 also couples with an optional external graphics processor 1512, which may communicate with one or more graphics processors 1508 in processors 1502 to perform graphics and media operations. In at least one embodiment, a display device 1511 may connect to processor(s) 1502. In at least one embodiment display device 1511 may include one or more of an internal display device, as in a mobile electronic device or a laptop device or an external display device attached via a display interface (e.g., DisplayPort, etc.). In at least one embodiment, display device 1511 may include a head mounted display (HMD) such as a stereoscopic display device for use in virtual reality (VR) applications or augmented reality (AR) applications.

In at least one embodiment, platform controller hub 1530 enables peripherals to connect to memory device 1520 and processor 1502 via a high-speed I/O bus. In at least one embodiment, I/O peripherals include, but are not limited to, an audio controller 1546, a network controller 1534, a firmware interface 1528, a wireless transceiver 1526, touch sensors 1525, a data storage device 1524 (e.g., hard disk drive, flash memory, etc.). In at least one embodiment, data storage device 1524 may connect via a storage interface (e.g., SATA) or via a peripheral bus, such as a Peripheral Component Interconnect bus (e.g., PCI, PCI Express). In at least one embodiment, touch sensors 1525 may include touch screen sensors, pressure sensors, or fingerprint sensors. In at least one embodiment, wireless transceiver 1526 may be a Wi-Fi transceiver, a Bluetooth transceiver, or a mobile network transceiver such as a 3G, 4G, or Long Term Evolution (LTE) transceiver. In at least one embodiment, firmware interface 1528 enables communication with system firmware, and may be, for example, a unified extensible firmware interface (UEFI). In at least one embodiment, network controller 1534 may enable a network connection to a wired network. In at least one embodiment, a high-performance network controller (not shown) couples with interface bus 1510. In at least one embodiment, audio controller 1546 is a multi-channel high definition audio controller. In at least one embodiment, system 1500 includes an optional legacy I/O controller 1540 for coupling legacy (e.g., Personal System 2 (PS/2)) devices to system. In at least one embodiment, platform controller hub 1530 may also connect to one or more Universal Serial Bus (USB) controllers 1542 connect input devices, such as keyboard and mouse 1543 combinations, a camera 1544, or other USB input devices.

In at least one embodiment, an instance of memory controller 1516 and platform controller hub 1530 may be integrated into a discreet external graphics processor, such as external graphics processor 1512. In at least one embodiment, platform controller hub 1530 and/or memory controller 1516 may be external to one or more processor(s) 1502. For example, in at least one embodiment, system 1500 may include an external memory controller 1516 and platform controller hub 1530, which may be configured as a memory controller hub and peripheral controller hub within a system chipset that is in communication with processor(s) 1502.

Inference and/or training logic 1115 are used to perform inferencing and/or training operations associated with one or more embodiments. Details regarding inference and/or training logic 1115 are provided below in conjunction with FIGS. 11A and/or 11B. In at least one embodiment portions or all of inference and/or training logic 1115 may be incorporated into graphics processor 1600. For example, in at least one embodiment, training and/or inferencing techniques described herein may use one or more of ALUs embodied in a graphics processor. Moreover, in at least one embodiment, inferencing and/or training operations described herein may be done using logic other than logic illustrated in FIG. 11A or 11B. In at least one embodiment, weight parameters may be stored in on-chip or off-chip memory and/or registers (shown or not shown) that configure ALUs of a graphics processor to perform one or more machine learning algorithms, neural network architectures, use cases, or training techniques described herein.

Such components may be used to generate synthetic data imitating failure cases in a network training process, which may help to improve performance of the network while limiting the amount of synthetic data to avoid overfitting.

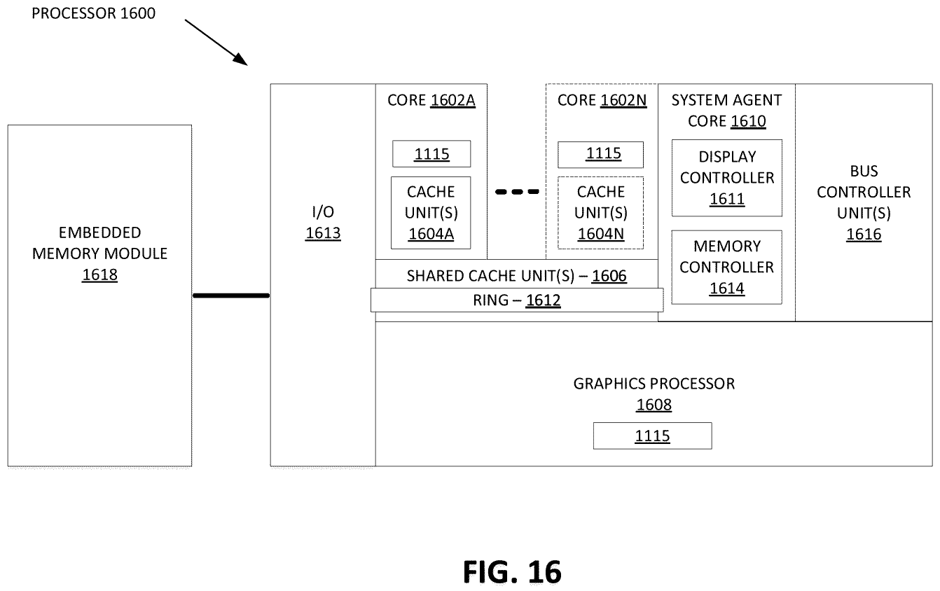

FIG. 16 is a block diagram of a processor 1600 having one or more processor cores 1602A-1602N, an integrated memory controller 1614, and an integrated graphics processor 1608, according to at least one embodiment. In at least one embodiment, processor 1600 may include additional cores up to and including additional core 1602N represented by dashed lined boxes. In at least one embodiment, each of processor cores 1602A-1602N includes one or more internal cache units 1604A-1604N. In at least one embodiment, each processor core also has access to one or more shared cached units 1606.

In at least one embodiment, internal cache units 1604A-1604N and shared cache units 1606 represent a cache memory hierarchy within processor 1600. In at least one embodiment, cache memory units 1604A-1604N may include at least one level of instruction and data cache within each processor core and one or more levels of shared mid-level cache, such as a Level 2 (L2), Level 3 (L3), Level 4 (L4), or other levels of cache, where a highest level of cache before external memory is classified as an LLC. In at least one embodiment, cache coherency logic maintains coherency between various cache units 1606 and 1604A-1604N.

In at least one embodiment, processor 1600 may also include a set of one or more bus controller units 1616 and a system agent core 1610. In at least one embodiment, one or more bus controller units 1616 manage a set of peripheral buses, such as one or more PCI or PCI express busses. In at least one embodiment, system agent core 1610 provides management functionality for various processor components. In at least one embodiment, system agent core 1610 includes one or more integrated memory controllers 1614 to manage access to various external memory devices (not shown).

In at least one embodiment, one or more of processor cores 1602A-1602N include support for simultaneous multi-threading. In at least one embodiment, system agent core 1610 includes components for coordinating and operating cores 1602A-1602N during multi-threaded processing. In at least one embodiment, system agent core 1610 may additionally include a power control unit (PCU), which includes logic and components to regulate one or more power states of processor cores 1602A-1602N and graphics processor 1608.

In at least one embodiment, processor 1600 additionally includes graphics processor 1608 to execute graphics processing operations. In at least one embodiment, graphics processor 1608 couples with shared cache units 1606, and system agent core 1610, including one or more integrated memory controllers 1614. In at least one embodiment, system agent core 1610 also includes a display controller 1611 to drive graphics processor output to one or more coupled displays. In at least one embodiment, display controller 1611 may also be a separate module coupled with graphics processor 1608 via at least one interconnect, or may be integrated within graphics processor 1608.

In at least one embodiment, a ring based interconnect unit 1612 is used to couple internal components of processor 1600. In at least one embodiment, an alternative interconnect unit may be used, such as a point-to-point interconnect, a switched interconnect, or other techniques. In at least one embodiment, graphics processor 1608 couples with ring interconnect 1612 via an I/O link 1613.

In at least one embodiment, I/O link 1613 represents at least one of multiple varieties of I/O interconnects, including an on package I/O interconnect which facilitates communication between various processor components and a high-performance embedded memory module 1618, such as an eDRAM module. In at least one embodiment, each of processor cores 1602A-1602N and graphics processor 1608 use embedded memory modules 1618 as a shared Last Level Cache.

In at least one embodiment, processor cores 1602A-1602N are homogenous cores executing a common instruction set architecture. In at least one embodiment, processor cores 1602A-1602N are heterogeneous in terms of instruction set architecture (ISA), where one or more of processor cores 1602A-1602N execute a common instruction set, while one or more other cores of processor cores 1602A-1602N executes a subset of a common instruction set or a different instruction set. In at least one embodiment, processor cores 1602A-1602N are heterogeneous in terms of microarchitecture, where one or more cores having a relatively higher power consumption couple with one or more power cores having a lower power consumption. In at least one embodiment, processor 1600 may be implemented on one or more chips or as an SoC integrated circuit.

Inference and/or training logic 1115 are used to perform inferencing and/or training operations associated with one or more embodiments. Details regarding inference and/or training logic 1115 are provided below in conjunction with FIGS. 11A and/or 11B. In at least one embodiment portions or all of inference and/or training logic 1115 may be incorporated into processor 1600. For example, in at least one embodiment, training and/or inferencing techniques described herein may use one or more of ALUs embodied in graphics processor 1608, graphics core(s) 1602A-1602N, or other components in FIG. 16. Moreover, in at least one embodiment, inferencing and/or training operations described herein may be done using logic other than logic illustrated in FIG. 11A or 11B. In at least one embodiment, weight parameters may be stored in on-chip or off-chip memory and/or registers (shown or not shown) that configure ALUs of graphics processor 1600 to perform one or more machine learning algorithms, neural network architectures, use cases, or training techniques described herein.

Such components may be used to generate synthetic data imitating failure cases in a network training process, which may help to improve performance of the network while limiting the amount of synthetic data to avoid overfitting.

### Virtualized Computing Platform

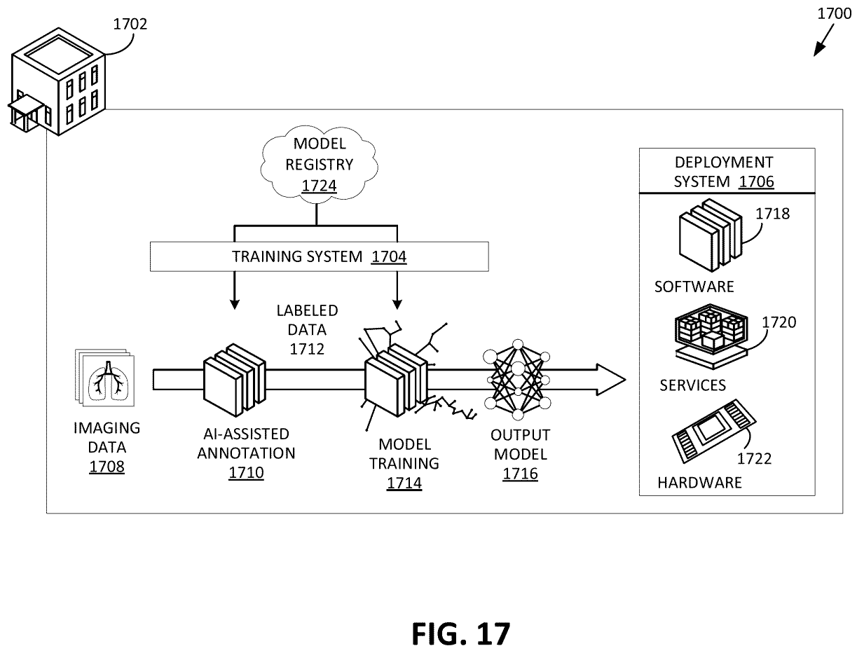

FIG. 17 is an example data flow diagram for a process 1700 of generating and deploying an image processing and inferencing pipeline, in accordance with at least one embodiment. In at least one embodiment, process 1700 may be deployed for use with imaging devices, processing devices, and/or other device types at one or more facilities 1702. Process 1700 may be executed within a training system 1704 and/or a deployment system 1706. In at least one embodiment, training system 1704 may be used to perform training, deployment, and implementation of machine learning models (e.g., neural networks, object detection algorithms, computer vision algorithms, etc.) for use in deployment system 1706. In at least one embodiment, deployment system 1706 may be configured to offload processing and compute resources among a distributed computing environment to reduce infrastructure requirements at facility 1702. In at least one embodiment, one or more applications in a pipeline may use or call upon services (e.g., inference, visualization, compute, AI, etc.) of deployment system 1706 during execution of applications.

In at least one embodiment, some of applications used in advanced processing and inferencing pipelines may use machine learning models or other AI to perform one or more processing steps. In at least one embodiment, machine learning models may be trained at facility 1702 using data 1708 (such as imaging data) generated at facility 1702 (and stored on one or more picture archiving and communication system (PACS) servers at facility 1702), may be trained using imaging or sequencing data 1708 from another facility (ies), or a combination thereof. In at least one embodiment, training system 1704 may be used to provide applications, services, and/or other resources for generating working, deployable machine learning models for deployment system 1706.

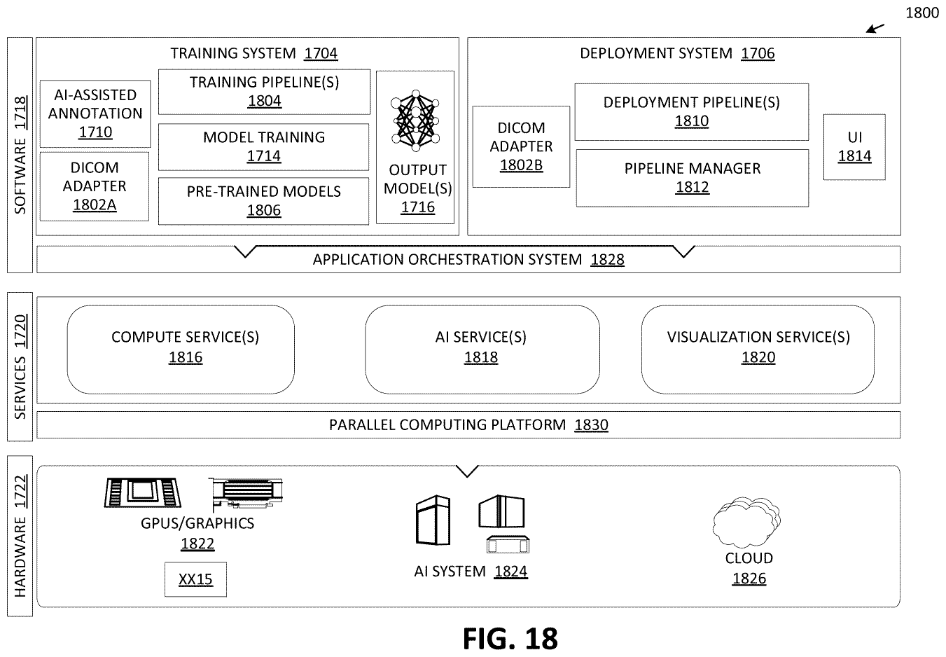

In at least one embodiment, model registry 1724 may be backed by object storage that may support versioning and object metadata. In at least one embodiment, object storage may be accessible through, for example, a cloud storage (e.g., cloud 1826 of FIG. 18) compatible application programming interface (API) from within a cloud platform. In at least one embodiment, machine learning models within model registry 1724 may uploaded, listed, modified, or deleted by developers or partners of a system interacting with an API. In at least one embodiment, an API may provide access to methods that allow users with appropriate credentials to associate models with applications, such that models may be executed as part of execution of containerized instantiations of applications.

In at least one embodiment, training pipeline 1804 (FIG. 18) may include a scenario where facility 1702 is training their own machine learning model, or has an existing machine learning model that needs to be optimized or updated. In at least one embodiment, imaging data 1708 generated by imaging device(s), sequencing devices, and/or other device types may be received. In at least one embodiment, once imaging data 1708 is received, AI-assisted annotation 1710 may be used to aid in generating annotations corresponding to imaging data 1708 to be used as ground truth data for a machine learning model. In at least one embodiment, AI-assisted annotation 1710 may include one or more machine learning models (e.g., convolutional neural networks (CNNs)) that may be trained to generate annotations corresponding to certain types of imaging data 1708 (e.g., from certain devices). In at least one embodiment, AI-assisted annotations 1710 may then be used directly, or may be adjusted or fine-tuned using an annotation tool to generate ground truth data. In at least one embodiment, AI-assisted annotations 1710, labeled clinic data 1712, or a combination thereof may be used as ground truth data for training a machine learning model. In at least one embodiment, a trained machine learning model may be referred to as output model 1716, and may be used by deployment system 1706, as described herein.

In at least one embodiment, training pipeline 1804 (FIG. 18) may include a scenario where facility 1702 needs a machine learning model for use in performing one or more processing tasks for one or more applications in deployment system 1706, but facility 1702 may not currently have such a machine learning model (or may not have a model that is optimized, efficient, or effective for such purposes). In at least one embodiment, an existing machine learning model may be selected from a model registry 1724. In at least one embodiment, model registry 1724 may include machine learning models trained to perform a variety of different inference tasks on imaging data. In at least one embodiment, machine learning models in model registry 1724 may have been trained on imaging data from different facilities than facility 1702 (e.g., facilities remotely located). In at least one embodiment, machine learning models may have been trained on imaging data from one location, two locations, or any number of locations. In at least one embodiment, when being trained on imaging data from a specific location, training may take place at that location, or at least in a manner that protects confidentiality of imaging data or restricts imaging data from being transferred off-premises. In at least one embodiment, once a model is trained- or partially trained—at one location, a machine learning model may be added to model registry 1724. In at least one embodiment, a machine learning model may then be retrained, or updated, at any number of other facilities, and a retrained or updated model may be made available in model registry 1724. In at least one embodiment, a machine learning model may then be selected from model registry 1724—and referred to as output model 1716—and may be used in deployment system 1706 to perform one or more processing tasks for one or more applications of a deployment system.

In at least one embodiment, training pipeline 1804 (FIG. 18), a scenario may include facility 1702 requiring a machine learning model for use in performing one or more processing tasks for one or more applications in deployment system 1706, but facility 1702 may not currently have such a machine learning model (or may not have a model that is optimized, efficient, or effective for such purposes). In at least one embodiment, a machine learning model selected from model registry 1724 may not be fine-tuned or optimized for imaging data 1708 generated at facility 1702 because of differences in populations, robustness of training data used to train a machine learning model, diversity in anomalies of training data, and/or other issues with training data. In at least one embodiment, AI-assisted annotation 1710 may be used to aid in generating annotations corresponding to imaging data 1708 to be used as ground truth data for retraining or updating a machine learning model. In at least one embodiment, labeled data 1712 may be used as ground truth data for training a machine learning model. In at least one embodiment, retraining or updating a machine learning model may be referred to as model training 1714. In at least one embodiment, model training 1714—e.g., AI-assisted annotations 1710, labeled clinic data 1712, or a combination thereof—may be used as ground truth data for retraining or updating a machine learning model. In at least one embodiment, a trained machine learning model may be referred to as output model 1716, and may be used by deployment system 1706, as described herein.

In at least one embodiment, deployment system 1706 may include software 1718, services 1720, hardware 1722, and/or other components, features, and functionality. In at least one embodiment, deployment system 1706 may include a software “stack,” such that software 1718 may be built on top of services 1720 and may use services 1720 to perform some or all of processing tasks, and services 1720 and software 1718 may be built on top of hardware 1722 and use hardware 1722 to execute processing, storage, and/or other compute tasks of deployment system 1706. In at least one embodiment, software 1718 may include any number of different containers, where each container may execute an instantiation of an application. In at least one embodiment, each application may perform one or more processing tasks in an advanced processing and inferencing pipeline (e.g., inferencing, object detection, feature detection, segmentation, image enhancement, calibration, etc.). In at least one embodiment, an advanced processing and inferencing pipeline may be defined based on selections of different containers that are desired or required for processing imaging data 1708, in addition to containers that receive and configure imaging data for use by each container and/or for use by facility 1702 after processing through a pipeline (e.g., to convert outputs back to a usable data type). In at least one embodiment, a combination of containers within software 1718 (e.g., that make up a pipeline) may be referred to as a virtual instrument (as described in more detail herein), and a virtual instrument may leverage services 1720 and hardware 1722 to execute some or all processing tasks of applications instantiated in containers.

In at least one embodiment, a data processing pipeline may receive input data (e.g., imaging data 1708) in a specific format in response to an inference request (e.g., a request from a user of deployment system 1706). In at least one embodiment, input data may be representative of one or more images, video, and/or other data representations generated by one or more imaging devices. In at least one embodiment, data may undergo pre-processing as part of data processing pipeline to prepare data for processing by one or more applications. In at least one embodiment, post-processing may be performed on an output of one or more inferencing tasks or other processing tasks of a pipeline to prepare an output data for a next application and/or to prepare output data for transmission and/or use by a user (e.g., as a response to an inference request). In at least one embodiment, inferencing tasks may be performed by one or more machine learning models, such as trained or deployed neural networks, which may include output models 1716 of training system 1704.

In at least one embodiment, tasks of data processing pipeline may be encapsulated in a container(s) that each represents a discrete, fully functional instantiation of an application and virtualized computing environment that is able to reference machine learning models. In at least one embodiment, containers or applications may be published into a private (e.g., limited access) area of a container registry (described in more detail herein), and trained or deployed models may be stored in model registry 1724 and associated with one or more applications. In at least one embodiment, images of applications (e.g., container images) may be available in a container registry, and once selected by a user from a container registry for deployment in a pipeline, an image may be used to generate a container for an instantiation of an application for use by a user's system.

In at least one embodiment, developers (e.g., software developers, clinicians, doctors, etc.) may develop, publish, and store applications (e.g., as containers) for performing image processing and/or inferencing on supplied data. In at least one embodiment, development, publishing, and/or storing may be performed using a software development kit (SDK) associated with a system (e.g., to ensure that an application and/or container developed is compliant with or compatible with a system). In at least one embodiment, an application that is developed may be tested locally (e.g., at a first facility, on data from a first facility) with an SDK which may support at least some of services 1720 as a system (e.g., system 1800 of FIG. 18). In at least one embodiment, because DICOM objects may contain anywhere from one to hundreds of images or other data types, and due to a variation in data, a developer may be responsible for managing (e.g., setting constructs for, building pre-processing into an application, etc.) extraction and preparation of incoming data. In at least one embodiment, once validated by system 1800 (e.g., for accuracy), an application may be available in a container registry for selection and/or implementation by a user to perform one or more processing tasks with respect to data at a facility (e.g., a second facility) of a user.

In at least one embodiment, developers may then share applications or containers through a network for access and use by users of a system (e.g., system 1800 of FIG. 18). In at least one embodiment, completed and validated applications or containers may be stored in a container registry and associated machine learning models may be stored in model registry 1724. In at least one embodiment, a requesting entity-who provides an inference or image processing request—may browse a container registry and/or model registry 1724 for an application, container, dataset, machine learning model, etc., select a desired combination of elements for inclusion in data processing pipeline, and submit an imaging processing request. In at least one embodiment, a request may include input data (and associated patient data, in some examples) that is necessary to perform a request, and/or may include a selection of application(s) and/or machine learning models to be executed in processing a request. In at least one embodiment, a request may then be passed to one or more components of deployment system 1706 (e.g., a cloud) to perform processing of data processing pipeline. In at least one embodiment, processing by deployment system 1706 may include referencing selected elements (e.g., applications, containers, models, etc.) from a container registry and/or model registry 1724. In at least one embodiment, once results are generated by a pipeline, results may be returned to a user for reference (e.g., for viewing in a viewing application suite executing on a local, on-premises workstation or terminal).

In at least one embodiment, to aid in processing or execution of applications or containers in pipelines, services 1720 may be leveraged. In at least one embodiment, services 1720 may include compute services, artificial intelligence (AI) services, visualization services, and/or other service types. In at least one embodiment, services 1720 may provide functionality that is common to one or more applications in software 1718, so functionality may be abstracted to a service that may be called upon or leveraged by applications. In at least one embodiment, functionality provided by services 1720 may run dynamically and more efficiently, while also scaling well by allowing applications to process data in parallel (e.g., using a parallel computing platform 1830 (FIG. 18)). In at least one embodiment, rather than each application that shares a same functionality offered by a service 1720 being required to have a respective instance of service 1720, service 1720 may be shared between and among various applications. In at least one embodiment, services may include an inference server or engine that may be used for executing detection or segmentation tasks, as non-limiting examples. In at least one embodiment, a model training service may be included that may provide machine learning model training and/or retraining capabilities. In at least one embodiment, a data augmentation service may further be included that may provide GPU accelerated data (e.g., DICOM, RIS, CIS, REST compliant, RPC, raw, etc.) extraction, resizing, scaling, and/or other augmentation. In at least one embodiment, a visualization service may be used that may add image rendering effects-such as ray-tracing, rasterization, denoising, sharpening, etc.—to add realism to two-dimensional (2D) and/or three-dimensional (3D) models. In at least one embodiment, virtual instrument services may be included that provide for beam-forming, segmentation, inferencing, imaging, and/or support for other applications within pipelines of virtual instruments.

In at least one embodiment, where a service 1720 includes an AI service (e.g., an inference service), one or more machine learning models may be executed by calling upon (e.g., as an API call) an inference service (e.g., an inference server) to execute machine learning model(s), or processing thereof, as part of application execution. In at least one embodiment, where another application includes one or more machine learning models for segmentation tasks, an application may call upon an inference service to execute machine learning models for performing one or more of processing operations associated with segmentation tasks. In at least one embodiment, software 1718 implementing advanced processing and inferencing pipeline that includes segmentation application and anomaly detection application may be streamlined because each application may call upon a same inference service to perform one or more inferencing tasks.

In at least one embodiment, hardware 1722 may include GPUs, CPUs, DPUs, graphics cards, an AI/deep learning system (e.g., an AI supercomputer, such as NVIDIA's DGX), a cloud platform, or a combination thereof. In at least one embodiment, different types of hardware 1722 may be used to provide efficient, purpose-built support for software 1718 and services 1720 in deployment system 1706. In at least one embodiment, use of GPU processing may be implemented for processing locally (e.g., at facility 1702), within an AI/deep learning system, in a cloud system, and/or in other processing components of deployment system 1706 to improve efficiency, accuracy, and efficacy of image processing and generation. In at least one embodiment, software 1718 and/or services 1720 may be optimized for GPU processing with respect to deep learning, machine learning, and/or high-performance computing, as non-limiting examples. In at least one embodiment, at least some of computing environment of deployment system 1706 and/or training system 1704 may be executed in a datacenter one or more supercomputers or high performance computing systems, with GPU optimized software (e.g., hardware and software combination of NVIDIA's DGX System). In at least one embodiment, hardware 1722 may include any number of GPUs that may be called upon to perform processing of data in parallel, as described herein. In at least one embodiment, cloud platform may further include GPU processing for GPU-optimized execution of deep learning tasks, machine learning tasks, or other computing tasks. In at least one embodiment, cloud platform may further include DPU processing to transmit data received over a network and/or through a network controller or other network interface directly to (e.g., a memory of) one or more GPU(s). In at least one embodiment, cloud platform (e.g., NVIDIA's NGC) may be executed using an AI/deep learning supercomputer(s) and/or GPU-optimized software (e.g., as provided on NVIDIA's DGX Systems) as a hardware abstraction and scaling platform. In at least one embodiment, cloud platform may integrate an application container clustering system or orchestration system (e.g., KUBERNETES) on multiple GPUs to enable seamless scaling and load balancing.

FIG. 18 is a system diagram for an example system 1800 for generating and deploying an imaging deployment pipeline, in accordance with at least one embodiment. In at least one embodiment, system 1800 may be used to implement process 1700 of FIG. 17 and/or other processes including advanced processing and inferencing pipelines. In at least one embodiment, system 1800 may include training system 1704 and deployment system 1706. In at least one embodiment, training system 1704 and deployment system 1706 may be implemented using software 1718, services 1720, and/or hardware 1722, as described herein.

In at least one embodiment, system 1800 (e.g., training system 1704 and/or deployment system 1706) may implemented in a cloud computing environment (e.g., using cloud 1826). In at least one embodiment, system 1800 may be implemented locally with respect to a healthcare services facility, or as a combination of both cloud and local computing resources. In at least one embodiment, access to APIs in cloud 1826 may be restricted to authorized users through enacted security measures or protocols. In at least one embodiment, a security protocol may include web tokens that may be signed by an authentication (e.g., AuthN, AuthZ, Gluecon, etc.) service and may carry appropriate authorization. In at least one embodiment, APIs of virtual instruments (described herein), or other instantiations of system 1800, may be restricted to a set of public IPs that have been vetted or authorized for interaction.

In at least one embodiment, various components of system 1800 may communicate between and among one another using any of a variety of different network types, including but not limited to local area networks (LANs) and/or wide area networks (WANs) via wired and/or wireless communication protocols. In at least one embodiment, communication between facilities and components of system 1800 (e.g., for transmitting inference requests, for receiving results of inference requests, etc.) may be communicated over data bus(ses), wireless data protocols (Wi-Fi), wired data protocols (e.g., Ethernet), etc.

In at least one embodiment, training system 1704 may execute training pipelines 1804, similar to those described herein with respect to FIG. 17. In at least one embodiment, where one or more machine learning models are to be used in deployment pipelines 1810 by deployment system 1706, training pipelines 1804 may be used to train or retrain one or more (e.g. pre-trained) models, and/or implement one or more of pre-trained models 1806 (e.g., without a need for retraining or updating). In at least one embodiment, as a result of training pipelines 1804, output model(s) 1716 may be generated. In at least one embodiment, training pipelines 1804 may include any number of processing steps, such as but not limited to imaging data (or other input data) conversion or adaption In at least one embodiment, for different machine learning models used by deployment system 1706, different training pipelines 1804 may be used. In at least one embodiment, training pipeline 1804 similar to a first example described with respect to FIG. 17 may be used for a first machine learning model, training pipeline 1804 similar to a second example described with respect to FIG. 17 may be used for a second machine learning model, and training pipeline 1804 similar to a third example described with respect to FIG. 17 may be used for a third machine learning model. In at least one embodiment, any combination of tasks within training system 1704 may be used depending on what is required for each respective machine learning model. In at least one embodiment, one or more of machine learning models may already be trained and ready for deployment so machine learning models may not undergo any processing by training system 1704, and may be implemented by deployment system 1706.

In at least one embodiment, output model(s) 1716 and/or pre-trained model(s) 1806 may include any types of machine learning models depending on implementation or embodiment. In at least one embodiment, and without limitation, machine learning models used by system 1800 may include machine learning model(s) using linear regression, logistic regression, decision trees, support vector machines (SVM), Naïve Bayes, k-nearest neighbor (Knn), K means clustering, random forest, dimensionality reduction algorithms, gradient boosting algorithms, neural networks (e.g., auto-encoders, convolutional, recurrent, perceptrons, Long/Short Term Memory (LSTM), Hopfield, Boltzmann, deep belief, deconvolutional, generative adversarial, liquid state machine, etc.), and/or other types of machine learning models.

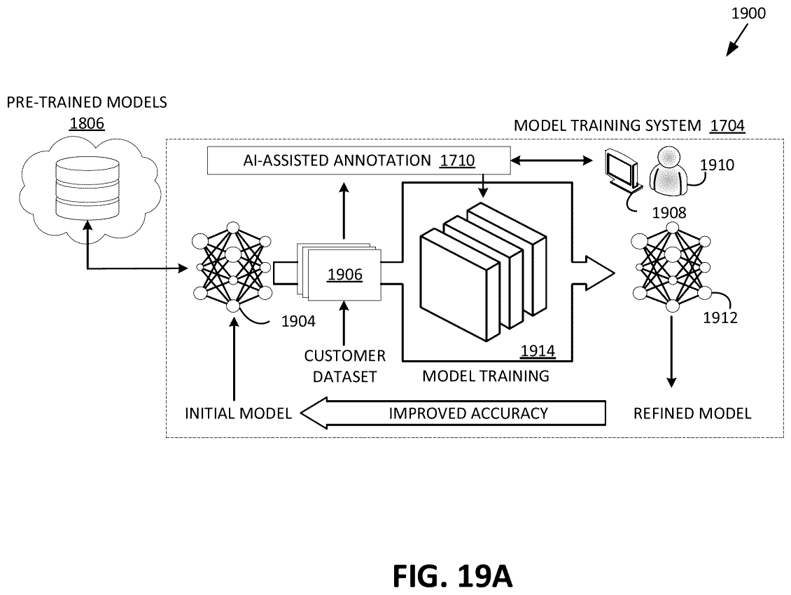

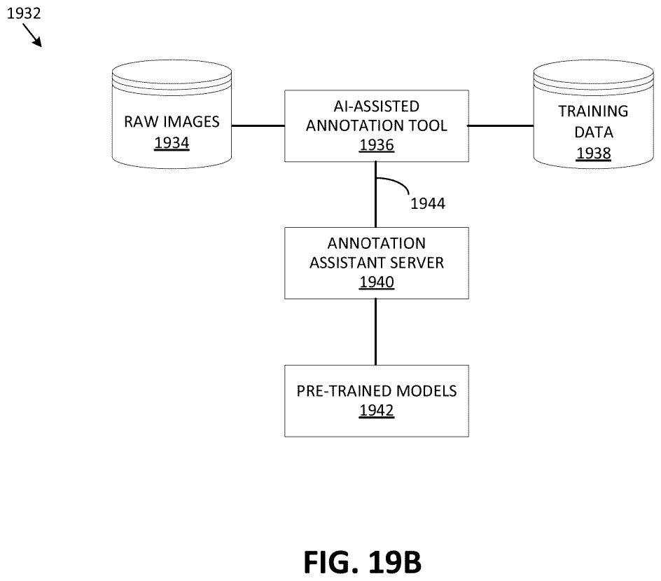

In at least one embodiment, training pipelines 1804 may include AI-assisted annotation, as described in more detail herein with respect to at least FIG. 19B. In at least one embodiment, labeled data 1712 (e.g., traditional annotation) may be generated by any number of techniques. In at least one embodiment, labels or other annotations may be generated within a drawing program (e.g., an annotation program), a computer aided design (CAD) program, a labeling program, another type of program suitable for generating annotations or labels for ground truth, and/or may be hand drawn, in some examples. In at least one embodiment, ground truth data may be synthetically produced (e.g., generated from computer models or renderings), real produced (e.g., designed and produced from real-world data), machine-automated (e.g., using feature analysis and learning to extract features from data and then generate labels), human annotated (e.g., labeler, or annotation expert, defines location of labels), and/or a combination thereof. In at least one embodiment, for each instance of imaging data 1708 (or other data type used by machine learning models), there may be corresponding ground truth data generated by training system 1704. In at least one embodiment, AI-assisted annotation may be performed as part of deployment pipelines 1810; either in addition to, or in lieu of AI-assisted annotation included in training pipelines 1804. In at least one embodiment, system 1800 may include a multi-layer platform that may include a software layer (e.g., software 1718) of diagnostic applications (or other application types) that may perform one or more medical imaging and diagnostic functions. In at least one embodiment, system 1800 may be communicatively coupled to (e.g., via encrypted links) PACS server networks of one or more facilities. In at least one embodiment, system 1800 may be configured to access and referenced data from PACS servers to perform operations, such as training machine learning models, deploying machine learning models, image processing, inferencing, and/or other operations.

In at least one embodiment, a software layer may be implemented as a secure, encrypted, and/or authenticated API through which applications or containers may be invoked (e.g., called) from an external environment(s) (e.g., facility 1702). In at least one embodiment, applications may then call or execute one or more services 1720 for performing compute, AI, or visualization tasks associated with respective applications, and software 1718 and/or services 1720 may leverage hardware 1722 to perform processing tasks in an effective and efficient manner.

In at least one embodiment, deployment system 1706 may execute deployment pipelines 1810. In at least one embodiment, deployment pipelines 1810 may include any number of applications that may be sequentially, non-sequentially, or otherwise applied to imaging data (and/or other data types) generated by imaging devices, sequencing devices, genomics devices, etc.—including AI-assisted annotation, as described above. In at least one embodiment, as described herein, a deployment pipeline 1810 for an individual device may be referred to as a virtual instrument for a device (e.g., a virtual ultrasound instrument, a virtual CT scan instrument, a virtual sequencing instrument, etc.). In at least one embodiment, for a single device, there may be more than one deployment pipeline 1810 depending on information desired from data generated by a device. In at least one embodiment, where detections of anomalies are desired from an MRI machine, there may be a first deployment pipeline 1810, and where image enhancement is desired from output of an MRI machine, there may be a second deployment pipeline 1810.

In at least one embodiment, an image generation application may include a processing task that includes use of a machine learning model. In at least one embodiment, a user may desire to use their own machine learning model, or to select a machine learning model from model registry 1724. In at least one embodiment, a user may implement their own machine learning model or select a machine learning model for inclusion in an application for performing a processing task. In at least one embodiment, applications may be selectable and customizable, and by defining constructs of applications, deployment, and implementation of applications for a particular user are presented as a more seamless user experience. In at least one embodiment, by leveraging other features of system 1800—such as services 1720 and hardware 1722—deployment pipelines 1810 may be even more user friendly, provide for easier integration, and produce more accurate, efficient, and timely results.

In at least one embodiment, deployment system 1706 may include a user interface 1814 (e.g., a graphical user interface, a web interface, etc.) that may be used to select applications for inclusion in deployment pipeline(s) 1810, arrange applications, modify, or change applications or parameters or constructs thereof, use and interact with deployment pipeline(s) 1810 during set-up and/or deployment, and/or to otherwise interact with deployment system 1706. In at least one embodiment, although not illustrated with respect to training system 1704, user interface 1814 (or a different user interface) may be used for selecting models for use in deployment system 1706, for selecting models for training, or retraining, in training system 1704, and/or for otherwise interacting with training system 1704.

In at least one embodiment, pipeline manager 1812 may be used, in addition to an application orchestration system 1828, to manage interaction between applications or containers of deployment pipeline(s) 1810 and services 1720 and/or hardware 1722. In at least one embodiment, pipeline manager 1812 may be configured to facilitate interactions from application to application, from application to service 1720, and/or from application or service to hardware 1722. In at least one embodiment, although illustrated as included in software 1718, this is not intended to be limiting, and in some examples (e.g., as illustrated in FIG. 16) pipeline manager 1812 may be included in services 1720. In at least one embodiment, application orchestration system 1828 (e.g., Kubernetes, DOCKER, etc.) may include a container orchestration system that may group applications into containers as logical units for coordination, management, scaling, and deployment. In at least one embodiment, by associating applications from deployment pipeline(s) 1810 (e.g., a reconstruction application, a segmentation application, etc.) with individual containers, each application may execute in a self-contained environment (e.g., at a kernel level) to increase speed and efficiency.

In at least one embodiment, each application and/or container (or image thereof) may be individually developed, modified, and deployed (e.g., a first user or developer may develop, modify, and deploy a first application and a second user or developer may develop, modify, and deploy a second application separate from a first user or developer), which may allow for focus on, and attention to, a task of a single application and/or container(s) without being hindered by tasks of another application(s) or container(s). In at least one embodiment, communication, and cooperation between different containers or applications may be aided by pipeline manager 1812 and application orchestration system 1828. In at least one embodiment, so long as an expected input and/or output of each container or application is known by a system (e.g., based on constructs of applications or containers), application orchestration system 1828 and/or pipeline manager 1812 may facilitate communication among and between, and sharing of resources among and between, each of applications or containers. In at least one embodiment, because one or more of applications or containers in deployment pipeline(s) 1810 may share same services and resources, application orchestration system 1828 may orchestrate, load balance, and determine sharing of services or resources between and among various applications or containers. In at least one embodiment, a scheduler may be used to track resource requirements of applications or containers, current usage or planned usage of these resources, and resource availability. In at least one embodiment, a scheduler may thus allocate resources to different applications and distribute resources between and among applications in view of requirements and availability of a system. In some examples, a scheduler (and/or other component of application orchestration system 1828) may determine resource availability and distribution based on constraints imposed on a system (e.g., user constraints), such as quality of service (QoS), urgency of need for data outputs (e.g., to determine whether to execute real-time processing or delayed processing), etc.

In at least one embodiment, services 1720 leveraged by and shared by applications or containers in deployment system 1706 may include compute services 1816, AI services 1818, visualization services 1820, and/or other service types. In at least one embodiment, applications may call (e.g., execute) one or more of services 1720 to perform processing operations for an application. In at least one embodiment, compute services 1816 may be leveraged by applications to perform super-computing or other high-performance computing (HPC) tasks. In at least one embodiment, compute service(s) 1816 may be leveraged to perform parallel processing (e.g., using a parallel computing platform 1830) for processing data through one or more of applications and/or one or more tasks of a single application, substantially simultaneously. In at least one embodiment, parallel computing platform 1830 (e.g., NVIDIA's CUDA) may enable general purpose computing on GPUs (GPGPU) (e.g., GPUs 1822). In at least one embodiment, a software layer of parallel computing platform 1830 may provide access to virtual instruction sets and parallel computational elements of GPUs, for execution of compute kernels. In at least one embodiment, parallel computing platform 1830 may include memory and, in some embodiments, a memory may be shared between and among multiple containers, and/or between and among different processing tasks within a single container. In at least one embodiment, inter-process communication (IPC) calls may be generated for multiple containers and/or for multiple processes within a container to use same data from a shared segment of memory of parallel computing platform 1830 (e.g., where multiple different stages of an application or multiple applications are processing same information). In at least one embodiment, rather than making a copy of data and moving data to different locations in memory (e.g., a read/write operation), same data in same location of a memory may be used for any number of processing tasks (e.g., at a same time, at different times, etc.). In at least one embodiment, as data is used to generate new data as a result of processing, this information of a new location of data may be stored and shared between various applications. In at least one embodiment, location of data and a location of updated or modified data may be part of a definition of how a payload is understood within containers.

In at least one embodiment, AI services 1818 may be leveraged to perform inferencing services for executing machine learning model(s) associated with applications (e.g., tasked with performing one or more processing tasks of an application). In at least one embodiment, AI services 1818 may leverage AI system 1824 to execute machine learning model(s) (e.g., neural networks, such as CNNs) for segmentation, reconstruction, object detection, feature detection, classification, and/or other inferencing tasks. In at least one embodiment, applications of deployment pipeline(s) 1810 may use one or more of output models 1716 from training system 1704 and/or other models of applications to perform inference on imaging data. In at least one embodiment, two or more examples of inferencing using application orchestration system 1828 (e.g., a scheduler) may be available. In at least one embodiment, a first category may include a high priority/low latency path that may achieve higher service level agreements, such as for performing inference on urgent requests during an emergency, or for a radiologist during diagnosis. In at least one embodiment, a second category may include a standard priority path that may be used for requests that may be non-urgent or where analysis may be performed at a later time. In at least one embodiment, application orchestration system 1828 may distribute resources (e.g., services 1720 and/or hardware 1722) based on priority paths for different inferencing tasks of AI services 1818.

In at least one embodiment, shared storage may be mounted to AI services 1818 within system 1800. In at least one embodiment, shared storage may operate as a cache (or other storage device type) and may be used to process inference requests from applications. In at least one embodiment, when an inference request is submitted, a request may be received by a set of API instances of deployment system 1706, and one or more instances may be selected (e.g., for best fit, for load balancing, etc.) to process a request. In at least one embodiment, to process a request, a request may be entered into a database, a machine learning model may be located from model registry 1724 if not already in a cache, a validation step may ensure appropriate machine learning model is loaded into a cache (e.g., shared storage), and/or a copy of a model may be saved to a cache. In at least one embodiment, a scheduler (e.g., of pipeline manager 1812) may be used to launch an application that is referenced in a request if an application is not already running or if there are not enough instances of an application. In at least one embodiment, if an inference server is not already launched to execute a model, an inference server may be launched. Any number of inference servers may be launched per model. In at least one embodiment, in a pull model, in which inference servers are clustered, models may be cached whenever load balancing is advantageous. In at least one embodiment, inference servers may be statically loaded in corresponding, distributed servers.

In at least one embodiment, inferencing may be performed using an inference server that runs in a container. In at least one embodiment, an instance of an inference server may be associated with a model (and optionally a plurality of versions of a model). In at least one embodiment, if an instance of an inference server does not exist when a request to perform inference on a model is received, a new instance may be loaded. In at least one embodiment, when starting an inference server, a model may be passed to an inference server such that a same container may be used to serve different models so long as inference server is running as a different instance.

In at least one embodiment, during application execution, an inference request for a given application may be received, and a container (e.g., hosting an instance of an inference server) may be loaded (if not already), and a start procedure may be called. In at least one embodiment, pre-processing logic in a container may load, decode, and/or perform any additional pre-processing on incoming data (e.g., using a CPU(s) and/or GPU(s) and/or DPU(s)). In at least one embodiment, once data is prepared for inference, a container may perform inference as necessary on data. In at least one embodiment, this may include a single inference call on one image (e.g., a hand X-ray), or may require inference on hundreds of images (e.g., a chest CT). In at least one embodiment, an application may summarize results before completing, which may include, without limitation, a single confidence score, pixel level-segmentation, voxel-level segmentation, generating a visualization, or generating text to summarize findings. In at least one embodiment, different models or applications may be assigned different priorities. For example, some models may have a real-time (TAT <1 min) priority while others may have lower priority (e.g., TAT <11 min). In at least one embodiment, model execution times may be measured from requesting institution or entity and may include partner network traversal time, as well as execution on an inference service.

In at least one embodiment, transfer of requests between services 1720 and inference applications may be hidden behind a software development kit (SDK), and robust transport may be provided through a queue. In at least one embodiment, a request will be placed in a queue via an API for an individual application/tenant ID combination and an SDK will pull a request from a queue and give a request to an application. In at least one embodiment, a name of a queue may be provided in an environment from where an SDK will pick it up. In at least one embodiment, asynchronous communication through a queue may be useful as it may allow any instance of an application to pick up work as it becomes available. Results may be transferred back through a queue, to ensure no data is lost. In at least one embodiment, queues may also provide an ability to segment work, as highest priority work may go to a queue with most instances of an application connected to it, while lowest priority work may go to a queue with a single instance connected to it that processes tasks in an order received. In at least one embodiment, an application may run on a GPU-accelerated instance generated in cloud 1826, and an inference service may perform inferencing on a GPU.

In at least one embodiment, visualization services 1820 may be leveraged to generate visualizations for viewing outputs of applications and/or deployment pipeline(s) 1810. In at least one embodiment, GPUs 1822 may be leveraged by visualization services 1820 to generate visualizations. In at least one embodiment, rendering effects, such as ray-tracing, may be implemented by visualization services 1820 to generate higher quality visualizations. In at least one embodiment, visualizations may include, without limitation, 2D image renderings, 3D volume renderings, 3D volume reconstruction, 2D tomographic slices, virtual reality displays, augmented reality displays, etc. In at least one embodiment, virtualized environments may be used to generate a virtual interactive display or environment (e.g., a virtual environment) for interaction by users of a system (e.g., doctors, nurses, radiologists, etc.). In at least one embodiment, visualization services 1820 may include an internal visualizer, cinematics, and/or other rendering or image processing capabilities or functionality (e.g., ray tracing, rasterization, internal optics, etc.).

In at least one embodiment, hardware 1722 may include GPUs 1822, AI system 1824, cloud 1826, and/or any other hardware used for executing training system 1704 and/or deployment system 1706. In at least one embodiment, GPUs 1822 (e.g., NVIDIA's TESLA and/or QUADRO GPUs) may include any number of GPUs that may be used for executing processing tasks of compute services 1816, AI services 1818, visualization services 1820, other services, and/or any of features or functionality of software 1718. For example, with respect to AI services 1818, GPUs 1822 may be used to perform pre-processing on imaging data (or other data types used by machine learning models), post-processing on outputs of machine learning models, and/or to perform inferencing (e.g., to execute machine learning models). In at least one embodiment, cloud 1826, AI system 1824, and/or other components of system 1800 may use GPUs 1822. In at least one embodiment, cloud 1826 may include a GPU-optimized platform for deep learning tasks. In at least one embodiment, AI system 1824 may use GPUs, and cloud 1826—or at least a portion tasked with deep learning or inferencing—may be executed using one or more AI systems 1824. As such, although hardware 1722 is illustrated as discrete components, this is not intended to be limiting, and any components of hardware 1722 may be combined with, or leveraged by, any other components of hardware 1722.

In at least one embodiment, AI system 1824 may include a purpose-built computing system (e.g., a super-computer or an HPC) configured for inferencing, deep learning, machine learning, and/or other artificial intelligence tasks. In at least one embodiment, AI system 1824 (e.g., NVIDIA's DGX) may include GPU-optimized software (e.g., a software stack) that may be executed using a plurality of GPUs 1822, in addition to DPUs, CPUs, RAM, storage, and/or other components, features, or functionality. In at least one embodiment, one or more AI systems 1824 may be implemented in cloud 1826 (e.g., in a data center) for performing some or all of AI-based processing tasks of system 1800.

In at least one embodiment, cloud 1826 may include a GPU-accelerated infrastructure (e.g., NVIDIA's NGC) that may provide a GPU-optimized platform for executing processing tasks of system 1800. In at least one embodiment, cloud 1826 may include an AI system(s) 1824 for performing one or more of AI-based tasks of system 1800 (e.g., as a hardware abstraction and scaling platform). In at least one embodiment, cloud 1826 may integrate with application orchestration system 1828 leveraging multiple GPUs to enable seamless scaling and load balancing between and among applications and services 1720. In at least one embodiment, cloud 1826 may tasked with executing at least some of services 1720 of system 1800, including compute services 1816, AI services 1818, and/or visualization services 1820, as described herein. In at least one embodiment, cloud 1826 may perform small and large batch inference (e.g., executing NVIDIA's TENSOR RT), provide an accelerated parallel computing API and platform 1830 (e.g., NVIDIA's CUDA), execute application orchestration system 1828 (e.g., KUBERNETES), provide a graphics rendering API and platform (e.g., for ray-tracing, 2D graphics, 3D graphics, and/or other rendering techniques to produce higher quality cinematics), and/or may provide other functionality for system 1800.

FIG. 19A illustrates a data flow diagram for a process 1900 to train, retrain, or update a machine learning model, in accordance with at least one embodiment. In at least one embodiment, process 1900 may be executed using, as a non-limiting example, system 1800 of FIG. 18. In at least one embodiment, process 1900 may leverage services 1720 and/or hardware 1722 of system 1800, as described herein. In at least one embodiment, refined models 1912 generated by process 1900 may be executed by deployment system 1706 for one or more containerized applications in deployment pipelines 1810.

In at least one embodiment, model training 1714 may include retraining or updating an initial model 1904 (e.g., a pre-trained model) using new training data (e.g., new input data, such as customer dataset 1906, and/or new ground truth data associated with input data). In at least one embodiment, to retrain, or update, initial model 1904, output or loss layer(s) of initial model 1904 may be reset, or deleted, and/or replaced with an updated or new output or loss layer(s). In at least one embodiment, initial model 1904 may have previously fine-tuned parameters (e.g., weights and/or biases) that remain from prior training, so training or retraining 1714 may not take as long or require as much processing as training a model from scratch. In at least one embodiment, during model training 1714, by having reset or replaced output or loss layer(s) of initial model 1904, parameters may be updated and re-tuned for a new data set based on loss calculations associated with accuracy of output or loss layer(s) at generating predictions on new, customer dataset 1906 (e.g., image data 1708 of FIG. 17).

In at least one embodiment, pre-trained models 1806 may be stored in a data store, or registry (e.g., model registry 1724 of FIG. 17). In at least one embodiment, pre-trained models 1806 may have been trained, at least in part, at one or more facilities other than a facility executing process 1900. In at least one embodiment, to protect privacy and rights of patients, subjects, or clients of different facilities, pre-trained models 1806 may have been trained, on-premise, using customer or patient data generated on-premise. In at least one embodiment, pre-trained models 1806 may be trained using cloud 1826 and/or other hardware 1722, but confidential, privacy protected patient data may not be transferred to, used by, or accessible to any components of cloud 1826 (or other off premise hardware). In at least one embodiment, where a pre-trained model 1806 is trained at using patient data from more than one facility, pre-trained model 1806 may have been individually trained for each facility prior to being trained on patient or customer data from another facility. In at least one embodiment, such as where a customer or patient data has been released of privacy concerns (e.g., by waiver, for experimental use, etc.), or where a customer or patient data is included in a public data set, a customer or patient data from any number of facilities may be used to train pre-trained model 1806 on-premise and/or off premise, such as in a datacenter or other cloud computing infrastructure.

In at least one embodiment, when selecting applications for use in deployment pipelines 1810, a user may also select machine learning models to be used for specific applications. In at least one embodiment, a user may not have a model for use, so a user may select a pre-trained model 1806 to use with an application. In at least one embodiment, pre-trained model 1806 may not be optimized for generating accurate results on customer dataset 1906 of a facility of a user (e.g., based on patient diversity, demographics, types of medical imaging devices used, etc.). In at least one embodiment, prior to deploying pre-trained model 1806 into deployment pipeline 1810 for use with an application(s), pre-trained model 1806 may be updated, retrained, and/or fine-tuned for use at a respective facility.

In at least one embodiment, a user may select pre-trained model 1806 that is to be updated, retrained, and/or fine-tuned, and pre-trained model 1806 may be referred to as initial model 1904 for training system 1704 within process 1900. In at least one embodiment, customer dataset 1906 (e.g., imaging data, genomics data, sequencing data, or other data types generated by devices at a facility) may be used to perform model training 1714 (which may include, without limitation, transfer learning) on initial model 1904 to generate refined model 1912. In at least one embodiment, ground truth data corresponding to customer dataset 1906 may be generated by training system 1704. In at least one embodiment, ground truth data may be generated, at least in part, by clinicians, scientists, doctors, practitioners, at a facility (e.g., as labeled clinic data 1712 of FIG. 17).

In at least one embodiment, AI-assisted annotation 1710 may be used in some examples to generate ground truth data. In at least one embodiment, AI-assisted annotation 1710 (e.g., implemented using an AI-assisted annotation SDK) may leverage machine learning models (e.g., neural networks) to generate suggested or predicted ground truth data for a customer dataset. In at least one embodiment, user 1910 may use annotation tools within a user interface (a graphical user interface (GUI)) on computing device 1908.

In at least one embodiment, user 1910 may interact with a GUI via computing device 1908 to edit or fine-tune (auto) annotations. In at least one embodiment, a polygon editing feature may be used to move vertices of a polygon to more accurate or fine-tuned locations.

In at least one embodiment, once customer dataset 1906 has associated ground truth data, ground truth data (e.g., from AI-assisted annotation, manual labeling, etc.) may be used by during model training 1714 to generate refined model 1912. In at least one embodiment, customer dataset 1906 may be applied to initial model 1904 any number of times, and ground truth data may be used to update parameters of initial model 1904 until an acceptable level of accuracy is attained for refined model 1912. In at least one embodiment, once refined model 1912 is generated, refined model 1912 may be deployed within one or more deployment pipelines 1810 at a facility for performing one or more processing tasks with respect to medical imaging data.

In at least one embodiment, refined model 1912 may be uploaded to pre-trained models 1806 in model registry 1724 to be selected by another facility. In at least one embodiment, his process may be completed at any number of facilities such that refined model 1912 may be further refined on new datasets any number of times to generate a more universal model.

FIG. 19B is an example illustration of a client-server architecture 1932 to enhance annotation tools with pre-trained annotation models, in accordance with at least one embodiment. In at least one embodiment, AI-assisted annotation tools 1936 may be instantiated based on a client-server architecture 1932. In at least one embodiment, annotation tools 1936 in imaging applications may aid radiologists, for example, identify organs and abnormalities. In at least one embodiment, imaging applications may include software tools that help user 1910 to identify, as a non-limiting example, a few extreme points on a particular organ of interest in raw images 1934 (e.g., in a 3D MRI or CT scan) and receive auto-annotated results for all 2D slices of a particular organ. In at least one embodiment, results may be stored in a data store as training data 1938 and used as (for example and without limitation) ground truth data for training. In at least one embodiment, when computing device 1908 sends extreme points for AI-assisted annotation 1710, a deep learning model, for example, may receive this data as input and return inference results of a segmented organ or abnormality. In at least one embodiment, pre-instantiated annotation tools, such as AI-Assisted Annotation Tool 1936B in FIG. 19B, may be enhanced by making API calls (e.g., API Call 1944) to a server, such as an Annotation Assistant Server 1940 that may include a set of pre-trained models 1942 stored in an annotation model registry, for example. In at least one embodiment, an annotation model registry may store pre-trained models 1942 (e.g., machine learning models, such as deep learning models) that are pre-trained to perform AI-assisted annotation on a particular organ or abnormality. These models may be further updated by using training pipelines 1804. In at least one embodiment, pre-installed annotation tools may be improved over time as new labeled clinic data 1712 is added.

### Autonomous Vehicle

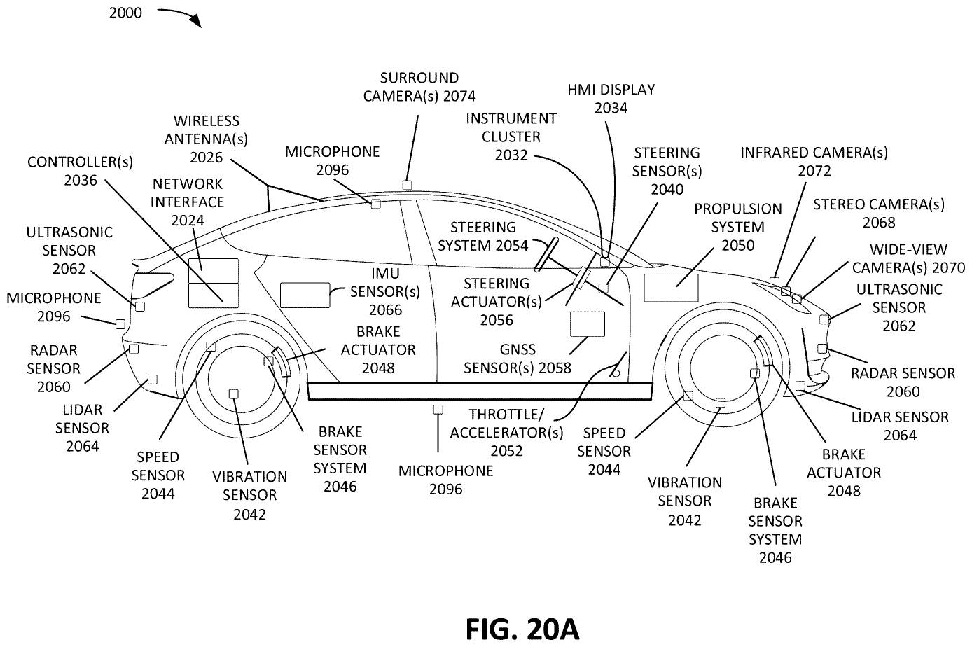

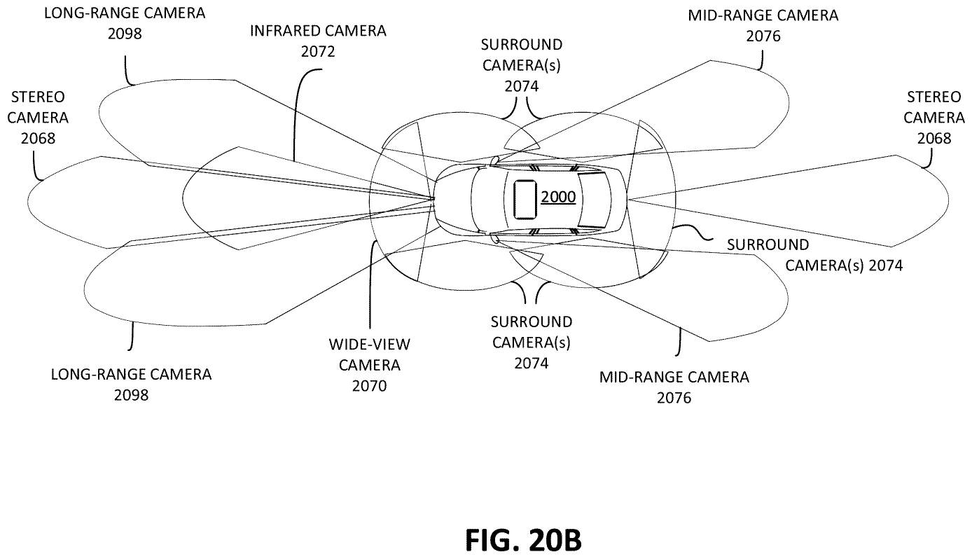

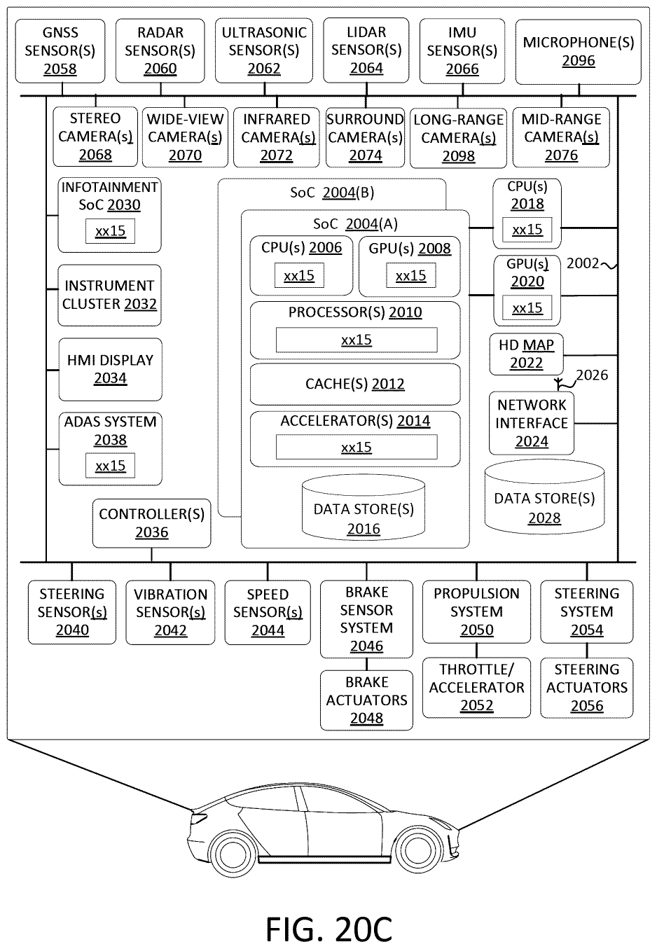

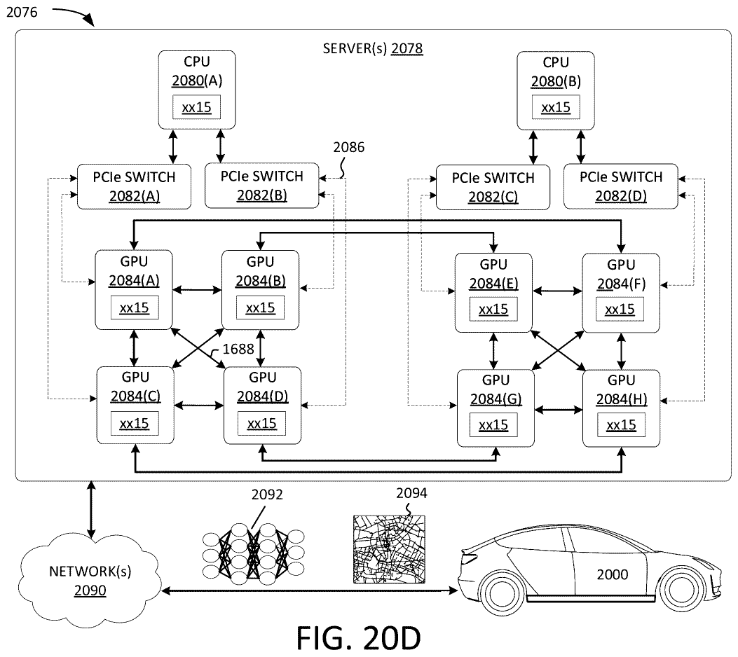

FIG. 20A illustrates an example of an autonomous vehicle 2000, according to at least one embodiment. In at least one embodiment, autonomous vehicle 2000 (alternatively referred to herein as “vehicle 2000”) may be, without limitation, a passenger vehicle, such as a car, a truck, a bus, and/or another type of vehicle that accommodates one or more passengers. In at least one embodiment, vehicle 2000 may be a semi-tractor-trailer truck used for hauling cargo. In at least one embodiment, vehicle 2000 may be an airplane, robotic vehicle, or other kind of vehicle.

Autonomous vehicles may be described in terms of automation levels, defined by National Highway Traffic Safety Administration (“NHTSA”), a division of US Department of Transportation, and Society of Automotive Engineers (“SAE”) “Taxonomy and Definitions for Terms Related to Driving Automation Systems for On-Road Motor Vehicles” (e.g., Standard No. J3016-201806, published on Jun. 15, 2018, Standard No. J3016-201609, published on Sep. 30, 2016, and previous and future versions of this standard). In one or more embodiments, vehicle 2000 may be capable of functionality in accordance with one or more of level 1-level 5 of autonomous driving levels. For example, in at least one embodiment, vehicle 2000 may be capable of conditional automation (Level 3), high automation (Level 4), and/or full automation (Level 5), depending on embodiment.

In at least one embodiment, vehicle 2000 may include, without limitation, components such as a chassis, a vehicle body, wheels (e.g., 2, 4, 6, 8, 18, etc.), tires, axles, and other components of a vehicle. In at least one embodiment, vehicle 2000 may include, without limitation, a propulsion system 2050, such as an internal combustion engine, hybrid electric power plant, an all-electric engine, and/or another propulsion system type. In at least one embodiment, propulsion system 2050 may be connected to a drive train of vehicle 2000, which may include, without limitation, a transmission, to enable propulsion of vehicle 2000. In at least one embodiment, propulsion system 2050 may be controlled in response to receiving signals from a throttle/accelerator(s) 2052.

In at least one embodiment, a steering system 2054, which may include, without limitation, a steering wheel, is used to steer a vehicle 2000 (e.g., along a desired path or route) when a propulsion system 2050 is operating (e.g., when vehicle is in motion). In at least one embodiment, a steering system 2054 may receive signals from steering actuator(s) 2056. A steering wheel may be optional for full automation (Level 5) functionality. In at least one embodiment, a brake sensor system 2046 may be used to operate vehicle brakes in response to receiving signals from brake actuator(s) 2048 and/or brake sensors.

In at least one embodiment, controller(s) 2036, which may include, without limitation, one or more system on chips (“SoCs”) (not shown in FIG. 20A) and/or graphics processing unit(s) (“GPU(s)”), provide signals (e.g., representative of commands) to one or more components and/or systems of vehicle 2000. For instance, in at least one embodiment, controller(s) 2036 may send signals to operate vehicle brakes via brake actuator(s) 2048, to operate steering system 2054 via steering actuator(s) 2056, and/or to operate propulsion system 2050 via throttle/accelerator(s) 2052. Controller(s) 2036 may include one or more onboard (e.g., integrated) computing devices (e.g., supercomputers) that process sensor signals, and output operation commands (e.g., signals representing commands) to enable autonomous driving and/or to assist a human driver in driving vehicle 2000. In at least one embodiment, controller(s) 2036 may include a first controller 2036 for autonomous driving functions, a second controller 2036 for functional safety functions, a third controller 2036 for artificial intelligence functionality (e.g., computer vision), a fourth controller 2036 for infotainment functionality, a fifth controller 2036 for redundancy in emergency conditions, and/or other controllers. In at least one embodiment, a single controller 2036 may handle two or more of above functionalities, two or more controllers 2036 may handle a single functionality, and/or any combination thereof.

In at least one embodiment, controller(s) 2036 provide signals for controlling one or more components and/or systems of vehicle 2000 in response to sensor data received from one or more sensors (e.g., sensor inputs). In at least one embodiment, sensor data may be received from, for example and without limitation, global navigation satellite systems (“GNSS”) sensor(s) 2058 (e.g., Global Positioning System sensor(s)), RADAR sensor(s) 2060, ultrasonic sensor(s) 2062, LIDAR sensor(s) 2064, inertial measurement unit (“IMU”) sensor(s) 2066 (e.g., accelerometer(s), gyroscope(s), magnetic compass(es), magnetometer(s), etc.), microphone(s) 2096, stereo camera(s) 2068, wide-view camera(s) 2070 (e.g., fisheye cameras), infrared camera(s) 2072, surround camera(s) 2074 (e.g., 360 degree cameras), long-range cameras (not shown in FIG. 20A), mid-range camera(s) (not shown in FIG. 20A), speed sensor(s) 2044 (e.g., for measuring speed of vehicle 2000), vibration sensor(s) 2042, steering sensor(s) 2040, brake sensor(s) (e.g., as part of brake sensor system 2046), and/or other sensor types.

In at least one embodiment, one or more of controller(s) 2036 may receive inputs (e.g., represented by input data) from an instrument cluster 2032 of vehicle 2000 and provide outputs (e.g., represented by output data, display data, etc.) via a human-machine interface (“HMI”) display 2034, an audible annunciator, a loudspeaker, and/or via other components of vehicle 2000. In at least one embodiment, outputs may include information such as vehicle velocity, speed, time, map data (e.g., a High Definition map (not shown in FIG. 20A), location data (e.g., vehicle 2000's location, such as on a map), direction, location of other vehicles (e.g., an occupancy grid), information about objects and status of objects as perceived by controller(s) 2036, etc. For example, in at least one embodiment, HMI display 2034 may display information about presence of one or more objects (e.g., a street sign, caution sign, traffic light changing, etc.), and/or information about driving maneuvers vehicle has made, is making, or will make (e.g., changing lanes now, taking exit 34B in two miles, etc.).

In at least one embodiment, vehicle 2000 further includes a network interface 2024 which may use wireless antenna(s) 2026 and/or modem(s) to communicate over one or more networks. For example, in at least one embodiment, network interface 2024 may be capable of communication over Long-Term Evolution (“LTE”), Wideband Code Division Multiple Access (“WCDMA”), Universal Mobile Telecommunications System (“UMTS”), Global System for Mobile communication (“GSM”), IMT-CDMA Multi-Carrier (“CDMA2000”), etc. In at least one embodiment, wireless antenna(s) 2026 may also enable communication between objects in environment (e.g., vehicles, mobile devices, etc.), using local area network(s), such as Bluetooth, Bluetooth Low Energy (“LE”), Z-Wave, ZigBee, etc., and/or low power wide-area network(s) (“LPWANs”), such as LoRaWAN, SigFox, etc.

Inference and/or training logic are used to perform inferencing and/or training operations associated with one or more embodiments. In at least one embodiment, inference and/or training logic may be used in system FIG. 20A for inferencing or predicting operations based, at least in part, on weight parameters calculated using neural network training operations, neural network functions and/or architectures, or neural network use cases described herein.

Such components can be used to generate synthetic data imitating failure cases in a network training process, which can help to improve performance of the network while limiting the amount of synthetic data to avoid overfitting.

FIG. 20B illustrates an example of camera locations and fields of view for autonomous vehicle 2000 of FIG. 20A, according to at least one embodiment. In at least one embodiment, cameras and respective fields of view are one example embodiment and are not intended to be limiting. For instance, in at least one embodiment, additional and/or alternative cameras may be included and/or cameras may be located at different locations on vehicle 2000.

In at least one embodiment, camera types for cameras may include, but are not limited to, digital cameras that may be adapted for use with components and/or systems of vehicle 2000. In at least one embodiment, one or more of camera(s) may operate at automotive safety integrity level (“ASIL”) B and/or at another ASIL. In at least one embodiment, camera types may be capable of any image capture rate, such as 60 frames per second (fps), 120 fps, 240 fps, etc., depending on embodiment. In at least one embodiment, cameras may be capable of using rolling shutters, global shutters, another type of shutter, or a combination thereof. In at least one embodiment, color filter array may include a red clear clear clear (“RCCC”) color filter array, a red clear clear blue (“RCCB”) color filter array, a red blue green clear (“RBGC”) color filter array, a Foveon X3 color filter array, a Bayer sensors (“RGGB”) color filter array, a monochrome sensor color filter array, and/or another type of color filter array. In at least one embodiment, clear pixel cameras, such as cameras with an RCCC, an RCCB, and/or an RBGC color filter array, may be used in an effort to increase light sensitivity.

In at least one embodiment, one or more of camera(s) may be used to perform advanced driver assistance systems (“ADAS”) functions (e.g., as part of a redundant or fail-safe design). For example, in at least one embodiment, a Multi-Function Mono Camera may be installed to provide functions including lane departure warning, traffic sign assist and intelligent headlamp control. In at least one embodiment, one or more of camera(s) (e.g., all of cameras) may record and provide image data (e.g., video) simultaneously.

In at least one embodiment, one or more of cameras may be mounted in a mounting assembly, such as a custom designed (three-dimensional (“3D”) printed) assembly, in order to cut out stray light and reflections from within car (e.g., reflections from dashboard reflected in windshield mirrors) which may interfere with camera's image data capture abilities. With reference to wing-mirror mounting assemblies, in at least one embodiment, wing-mirror assemblies may be custom 3D printed so that camera mounting plate matches shape of wing-mirror. In at least one embodiment, camera(s) may be integrated into wing-mirror. For side-view cameras, camera(s) may also be integrated within four pillars at each corner of cabIn at least one embodiment.

In at least one embodiment, cameras with a field of view that include portions of environment in front of vehicle 2000 (e.g., front-facing cameras) may be used for surround view, to help identify forward facing paths and obstacles, as well as aid in, with help of one or more of controllers 2036 and/or control SoCs, providing information critical to generating an occupancy grid and/or determining preferred vehicle paths. In at least one embodiment, front-facing cameras may be used to perform many of same ADAS functions as LIDAR, including, without limitation, emergency braking, pedestrian detection, and collision avoidance. In at least one embodiment, front-facing cameras may also be used for ADAS functions and systems including, without limitation, Lane Departure Warnings (“LDW”), Autonomous Cruise Control (“ACC”), and/or other functions such as traffic sign recognition.

In at least one embodiment, a variety of cameras may be used in a front-facing configuration, including, for example, a monocular camera platform that includes a CMOS (“complementary metal oxide semiconductor”) color imager. In at least one embodiment, wide-view camera 1970 may be used to perceive objects coming into view from periphery (e.g., pedestrians, crossing traffic or bicycles). Although only one wide-view camera 2070 is illustrated in FIG. 20B, in other embodiments, there may be any number (including zero) of wide-view camera(s) 2070 on vehicle 2000. In at least one embodiment, any number of long-range camera(s) 2098 (e.g., a long-view stereo camera pair) may be used for depth-based object detection, especially for objects for which a neural network has not yet been trained. In at least one embodiment, long-range camera(s) 2098 may also be used for object detection and classification, as well as basic object tracking.

In at least one embodiment, any number of stereo camera(s) 2068 may also be included in a front-facing configuration. In at least one embodiment, one or more of stereo camera(s) 2068 may include an integrated control unit comprising a scalable processing unit, which may provide a programmable logic (“FPGA”) and a multi-core micro-processor with an integrated Controller Area Network (“CAN”) or Ethernet interface on a single chip. In at least one embodiment, such a unit may be used to generate a 3D map of environment of vehicle 2000, including a distance estimate for all points in image. In at least one embodiment, one or more of stereo camera(s) 2068 may include, without limitation, compact stereo vision sensor(s) that may include, without limitation, two camera lenses (one each on left and right) and an image processing chip that may measure distance from vehicle 2000 to target object and use generated information (e.g., metadata) to activate autonomous emergency braking and lane departure warning functions. In at least one embodiment, other types of stereo camera(s) 2068 may be used in addition to, or alternatively from, those described herein.

In at least one embodiment, cameras with a field of view that include portions of environment to side of vehicle 2000 (e.g., side-view cameras) may be used for surround view, providing information used to create and update occupancy grid, as well as to generate side impact collision warnings. For example, in at least one embodiment, surround camera(s) 2074 (e.g., four surround cameras 2074 as illustrated in FIG. 20B) could be positioned on vehicle 2000. In at least one embodiment, surround camera(s) 2074 may include, without limitation, any number and combination of wide-view camera(s) 2070, fisheye camera(s), 360 degree camera(s), and/or like. For instance, in at least one embodiment, four fisheye cameras may be positioned on front, rear, and sides of vehicle 2000. In at least one embodiment, vehicle 2000 may use three surround camera(s) 2074 (e.g., left, right, and rear), and may leverage one or more other camera(s) (e.g., a forward-facing camera) as a fourth surround-view camera.

In at least one embodiment, cameras with a field of view that include portions of environment to rear of vehicle 2000 (e.g., rear-view cameras) may be used for park assistance, surround view, rear collision warnings, and creating and updating occupancy grid. In at least one embodiment, a wide variety of cameras may be used including, but not limited to, cameras that are also suitable as a front-facing camera(s) (e.g., long-range cameras 2098 and/or mid-range camera(s) 2076, stereo camera(s) 2068), infrared camera(s) 2072, etc.), as described herein.

Inference and/or training logic are used to perform inferencing and/or training operations associated with one or more embodiments. Details regarding inference and/or training logic are provided herein. In at least one embodiment, inference and/or training logic may be used in system FIG. 20B for inferencing or predicting operations based, at least in part, on weight parameters calculated using neural network training operations, neural network functions and/or architectures, or neural network use cases described herein.

Such components can be used to generate synthetic data imitating failure cases in a network training process, which can help to improve performance of the network while limiting the amount of synthetic data to avoid overfitting.

FIG. 20C is a block diagram illustrating an example system architecture for autonomous vehicle 2000 of FIG. 20A, according to at least one embodiment. In at least one embodiment, each of components, features, and systems of vehicle 2000 in FIG. 20C are illustrated as being connected via a bus 2002. In at least one embodiment, bus 2002 may include, without limitation, a CAN data interface (alternatively referred to herein as a “CAN bus”). In at least one embodiment, a CAN bus may be a network inside vehicle 2000 used to aid in control of various features and functionality of vehicle 2000, such as actuation of brakes, acceleration, braking, steering, windshield wipers, etc. In at least one embodiment, bus 2002 may be configured to have dozens or even hundreds of nodes, each with its own unique identifier (e.g., a CAN ID). In at least one embodiment, bus 2002 may be read to find steering wheel angle, ground speed, engine revolutions per minute (“RPMs”), button positions, and/or other vehicle status indicators. In at least one embodiment, bus 2002 may be a CAN bus that is ASIL B compliant.

In at least one embodiment, in addition to, or alternatively from CAN, FlexRay and/or Ethernet may be used. In at least one embodiment, there may be any number of busses 2002, which may include, without limitation, zero or more CAN busses, zero or more FlexRay busses, zero or more Ethernet busses, and/or zero or more other types of busses using a different protocol. In at least one embodiment, two or more busses 2002 may be used to perform different functions, and/or may be used for redundancy. For example, a first bus 2002 may be used for collision avoidance functionality and a second bus 2002 may be used for actuation control. In at least one embodiment, each bus 2002 may communicate with any of components of vehicle 2000, and two or more busses 2002 may communicate with same components. In at least one embodiment, each of any number of system(s) on chip(s) (“SoC(s)”) 2004, each of controller(s) 2036, and/or each computer within vehicle may have access to same input data (e.g., inputs from sensors of vehicle 2000), and may be connected to a common bus, such CAN bus.

In at least one embodiment, vehicle 2000 may include one or more controller(s) 2036, such as those described herein with respect to FIG. 20A. Controller(s) 2036 may be used for a variety of functions. In at least one embodiment, controller(s) 2036 may be coupled to any of various other components and systems of vehicle 2000, and may be used for control of vehicle 2000, artificial intelligence of vehicle 2000, infotainment for vehicle 2000, and/or like.

In at least one embodiment, vehicle 2000 may include any number of SoCs 2004. Each of SoCs 2004 may include, without limitation, central processing units (“CPU(s)”) 2006, graphics processing units (“GPU(s)”) 2008, processor(s) 2010, cache(s) 2012, accelerator(s) 2014, data store(s) 2016, and/or other components and features not illustrated. In at least one embodiment, SoC(s) 2004 may be used to control vehicle 2000 in a variety of platforms and systems. For example, in at least one embodiment, SoC(s) 2004 may be combined in a system (e.g., system of vehicle 2000) with a High Definition (“HD”) map 2022 which may obtain map refreshes and/or updates via network interface 2024 from one or more servers (not shown in FIG. 20C).

In at least one embodiment, CPU(s) 2006 may include a CPU cluster or CPU complex (alternatively referred to herein as a “CCPLEX”). In at least one embodiment, CPU(s) 2006 may include multiple cores and/or level two (“L2”) caches. For instance, in at least one embodiment, CPU(s) 2006 may include eight cores in a coherent multi-processor configuration. In at least one embodiment, CPU(s) 2006 may include four dual-core clusters where each cluster has a dedicated L2 cache (e.g., a 2 MB L2 cache). In at least one embodiment, CPU(s) 2006 (e.g., CCPLEX) may be configured to support simultaneous cluster operation enabling any combination of clusters of CPU(s) 2006 to be active at any given time.

In at least one embodiment, one or more of CPU(s) 2006 may implement power management capabilities that include, without limitation, one or more of following features: individual hardware blocks may be clock-gated automatically when idle to save dynamic power; each core clock may be gated when core is not actively executing instructions due to execution of.

Wait for Interrupt (“WFI”)/Wait for Event (“WFE”) instructions; each core may be independently power-gated; each core cluster may be independently clock-gated when all cores are clock-gated or power-gated; and/or each core cluster may be independently power-gated when all cores are power-gated. In at least one embodiment, CPU(s) 2006 may further implement an enhanced algorithm for managing power states, where allowed power states and expected wakeup times are specified, and hardware/microcode determines best power state to enter for core, cluster, and CCPLEX. In at least one embodiment, processing cores may support simplified power state entry sequences in software with work offloaded to microcode.

In at least one embodiment, GPU(s) 2008 may include an integrated GPU (alternatively referred to herein as an “iGPU”). In at least one embodiment, GPU(s) 2008 may be programmable and may be efficient for parallel workloads. In at least one embodiment, GPU(s) 2008, in at least one embodiment, may use an enhanced tensor instruction set. In at least one embodiment, GPU(s) 2008 may include one or more streaming microprocessors, where each streaming microprocessor may include a level one (“L1”) cache (e.g., an L1 cache with at least 96 KB storage capacity), and two or more of streaming microprocessors may share an L2 cache (e.g., an L2 cache with a 512 KB storage capacity). In at least one embodiment, GPU(s) 2008 may include at least eight streaming microprocessors. In at least one embodiment, GPU(s) 2008 may use compute application programming interface(s) (API(s)). In at least one embodiment, GPU(s) 2008 may use one or more parallel computing platforms and/or programming models (e.g., NVIDIA's CUDA).

In at least one embodiment, one or more of GPU(s) 2008 may be power-optimized for best performance in automotive and embedded use cases. For example, in on embodiment, GPU(s) 2008 could be fabricated on a Fin field-effect transistor (“FinFET”). In at least one embodiment, each streaming microprocessor may incorporate a number of mixed-precision processing cores partitioned into multiple blocks. For example, and without limitation, 64 PF32 cores and 32 PF64 cores could be partitioned into four processing blocks. In at least one embodiment, each processing block could be allocated 17 FP32 cores, 8 FP64 cores, 17 INT32 cores, two mixed-precision NVIDIA TENSOR COREs for deep learning matrix arithmetic, a level zero (“L0”) instruction cache, a warp scheduler, a dispatch unit, and/or a 64 KB register file. In at least one embodiment, streaming microprocessors may include independent parallel integer and floating-point data paths to provide for efficient execution of workloads with a mix of computation and addressing calculations. In at least one embodiment, streaming microprocessors may include independent thread scheduling capability to enable finer-grain synchronization and cooperation between parallel threads. In at least one embodiment, streaming microprocessors may include a combined L1 data cache and shared memory unit in order to improve performance while simplifying programming.

In at least one embodiment, one or more of GPU(s) 2008 may include a high bandwidth memory (“HBM) and/or a 20 GB HBM2 memory subsystem to provide, in some examples, about 900 GB/second peak memory bandwidth. In at least one embodiment, in addition to, or alternatively from, HBM memory, a synchronous graphics random-access memory (“SGRAM”) may be used, such as a graphics double data rate type five synchronous random-access memory (“GDDR5”).

In at least one embodiment, GPU(s) 2008 may include unified memory technology. In at least one embodiment, address translation services (“ATS”) support may be used to allow GPU(s) 2008 to access CPU(s) 2006 page tables directly. In at least one embodiment, embodiment, when GPU(s) 1908 memory management unit (“MMU”) experiences a miss, an address translation request may be transmitted to CPU(s) 2006. In response, CPU(s) 2006 may look in its page tables for virtual-to-physical mapping for address and transmits translation back to GPU(s) 2008, in at least one embodiment. In at least one embodiment, unified memory technology may allow a single unified virtual address space for memory of both CPU(s) 2006 and GPU(s) 2008, thereby simplifying GPU(s) 2008 programming and porting of applications to GPU(s) 2008.

In at least one embodiment, GPU(s) 2008 may include any number of access counters that may keep track of frequency of access of GPU(s) 2008 to memory of other processors. In at least one embodiment, access counter(s) may help ensure that memory pages are moved to physical memory of processor that is accessing pages most frequently, thereby improving efficiency for memory ranges shared between processors.

In at least one embodiment, one or more of SoC(s) 2004 may include any number of cache(s) 2012, including those described herein. For example, in at least one embodiment, cache(s) 2012 could include a level three (“L3”) cache that is available to both CPU(s) 2006 and GPU(s) 2008 (e.g., that is connected both CPU(s) 2006 and GPU(s) 2008). In at least one embodiment, cache(s) 2012 may include a write-back cache that may keep track of states of lines, such as by using a cache coherence protocol (e.g., MEI, MESI, MSI, etc.). In at least one embodiment, L3 cache may include 4 MB or more, depending on embodiment, although smaller cache sizes may be used.

In at least one embodiment, one or more of SoC(s) 2004 may include one or more accelerator(s) 2014 (e.g., hardware accelerators, software accelerators, or a combination thereof). In at least one embodiment, SoC(s) 2004 may include a hardware acceleration cluster that may include optimized hardware accelerators and/or large on-chip memory. In at least one embodiment, large on-chip memory (e.g., 4 MB of SRAM), may enable hardware acceleration cluster to accelerate neural networks and other calculations. In at least one embodiment, hardware acceleration cluster may be used to complement GPU(s) 2008 and to off-load some of tasks of GPU(s) 2008 (e.g., to free up more cycles of GPU(s) 2008 for performing other tasks). In at least one embodiment, accelerator(s) 2014 could be used for targeted workloads (e.g., perception, convolutional neural networks (“CNNs”), recurrent neural networks (“RNNs”), etc.) that are stable enough to be amenable to acceleration. In at least one embodiment, a CNN may include a region-based or regional convolutional neural networks (“RCNNs”) and Fast RCNNs (e.g., as used for object detection) or other type of CNN.

In at least one embodiment, accelerator(s) 2014 (e.g., hardware acceleration cluster) may include a deep learning accelerator(s) (“DLA(s)”). DLA(s) may include, without limitation, one or more Tensor processing units (“TPU(s)”) that may be configured to provide an additional ten trillion operations per second for deep learning applications and inferencing. In at least one embodiment, TPU(s) may be accelerators configured to, and optimized for, performing image processing functions (e.g., for CNNs, RCNNs, etc.). DLA(s) may further be optimized for a specific set of neural network types and floating point operations, as well as inferencing. In at least one embodiment, design of DLA(s) may provide more performance per millimeter than a typical general-purpose GPU, and typically vastly exceeds performance of a CPU. In at least one embodiment, TPU(s) may perform several functions, including a single-instance convolution function, supporting, for example, INT8, INT16, and FP16 data types for both features and weights, as well as post-processor functions. In at least one embodiment, DLA(s) may quickly and efficiently execute neural networks, especially CNNs, on processed or unprocessed data for any of a variety of functions, including, for example and without limitation: a CNN for object identification and detection using data from camera sensors; a CNN for distance estimation using data from camera sensors; a CNN for emergency vehicle detection and identification and detection using data from microphones 2096; a CNN for facial recognition and vehicle owner identification using data from camera sensors; and/or a CNN for security and/or safety related events.

In at least one embodiment, DLA(s) may perform any function of GPU(s) 2008, and by using an inference accelerator, for example, a designer may target either DLA(s) or GPU(s) 2008 for any function. For example, in at least one embodiment, designer may focus processing of CNNs and floating point operations on DLA(s) and leave other functions to GPU(s) 2008 and/or other accelerator(s) 2014.

In at least one embodiment, accelerator(s) 2014 (e.g., hardware acceleration cluster) may include a programmable vision accelerator(s) (“PVA”), which may alternatively be referred to herein as a computer vision accelerator. In at least one embodiment, PVA(s) may be designed and configured to accelerate computer vision algorithms for advanced driver assistance system (“ADAS”) 2038, autonomous driving, augmented reality (“AR”) applications, and/or virtual reality (“VR”) applications. PVA(s) may provide a balance between performance and flexibility. For example, in at least one embodiment, each PVA(s) may include, for example and without limitation, any number of reduced instruction set computer (“RISC”) cores, direct memory access (“DMA”), and/or any number of vector processors.

In at least one embodiment, RISC cores may interact with image sensors (e.g., image sensors of any of cameras described herein), image signal processor(s), and/or like. In at least one embodiment, each of RISC cores may include any amount of memory. In at least one embodiment, RISC cores may use any of a number of protocols, depending on embodiment. In at least one embodiment, RISC cores may execute a real-time operating system (“RTOS”). In at least one embodiment, RISC cores may be implemented using one or more integrated circuit devices, application specific integrated circuits (“ASICs”), and/or memory devices. For example, in at least one embodiment, RISC cores could include an instruction cache and/or a tightly coupled RAM.

In at least one embodiment, DMA may enable components of PVA(s) to access system memory independently of CPU(s) 2006. In at least one embodiment, DMA may support any number of features used to provide optimization to PVA including, but not limited to, supporting multi-dimensional addressing and/or circular addressing. In at least one embodiment, DMA may support up to six or more dimensions of addressing, which may include, without limitation, block width, block height, block depth, horizontal block stepping, vertical block stepping, and/or depth stepping.

In at least one embodiment, vector processors may be programmable processors that may be designed to efficiently and flexibly execute programming for computer vision algorithms and provide signal processing capabilities. In at least one embodiment, PVA may include a PVA core and two vector processing subsystem partitions. In at least one embodiment, PVA core may include a processor subsystem, DMA engine(s) (e.g., two DMA engines), and/or other peripherals. In at least one embodiment, vector processing subsystem may operate as primary processing engine of PVA, and may include a vector processing unit (“VPU”), an instruction cache, and/or vector memory (e.g., “VMEM”). In at least one embodiment, VPU may include a digital signal processor such as, for example, a single instruction, multiple data (“SIMD”), very long instruction word (“VLIW”) digital signal processor. In at least one embodiment, a combination of SIMD and VLIW may enhance throughput and speed.

In at least one embodiment, each of vector processors may include an instruction cache and may be coupled to dedicated memory. As a result, in at least one embodiment, each of vector processors may be configured to execute independently of other vector processors. In at least one embodiment, vector processors that are included in a particular PVA may be configured to employ data parallelism. For instance, in at least one embodiment, plurality of vector processors included in a single PVA may execute same computer vision algorithm, but on different regions of an image. In at least one embodiment, vector processors included in a particular PVA may simultaneously execute different computer vision algorithms, on same image, or even execute different algorithms on sequential images or portions of an image. In at least one embodiment, among other things, any number of PVAs may be included in hardware acceleration cluster and any number of vector processors may be included in each of PVAs. In at least one embodiment, PVA(s) may include additional error correcting code (“ECC”) memory, to enhance overall system safety.

In at least one embodiment, accelerator(s) 2014 (e.g., hardware acceleration cluster) may include a computer vision network on-chip and static random-access memory (“SRAM”), for providing a high-bandwidth, low latency SRAM for accelerator(s) 2014. In at least one embodiment, on-chip memory may include at least 4 MB SRAM, consisting of, for example and without limitation, eight field-configurable memory blocks, that may be accessible by both PVA and DLA. In at least one embodiment, each pair of memory blocks may include an advanced peripheral bus (“APB”) interface, configuration circuitry, a controller, and a multiplexer. In at least one embodiment, any type of memory may be used. In at least one embodiment, PVA and DLA may access memory via a backbone that provides PVA and DLA with high-speed access to memory. In at least one embodiment, backbone may include a computer vision network on-chip that interconnects PVA and DLA to memory (e.g., using APB).

In at least one embodiment, computer vision network on-chip may include an interface that determines, before transmission of any control signal/address/data, that both PVA and DLA provide ready and valid signals. In at least one embodiment, an interface may provide for separate phases and separate channels for transmitting control signals/addresses/data, as well as burst-type communications for continuous data transfer. In at least one embodiment, an interface may comply with International Organization for Standardization (“ISO”) 26262 or International Electrotechnical Commission (“IEC”) 61508 standards, although other standards and protocols may be used.

In at least one embodiment, one or more of SoC(s) 2004 may include a real-time ray-tracing hardware accelerator. In at least one embodiment, real-time ray-tracing hardware accelerator may be used to quickly and efficiently determine positions and extents of objects (e.g., within a world model), to generate real-time visualization simulations, for RADAR signal interpretation, for sound propagation synthesis and/or analysis, for simulation of SONAR systems, for general wave propagation simulation, for comparison to LIDAR data for purposes of localization and/or other functions, and/or for other uses.

In at least one embodiment, accelerator(s) 2014 (e.g., hardware accelerator cluster) have a wide array of uses for autonomous driving. In at least one embodiment, PVA may be a programmable vision accelerator that may be used for key processing stages in ADAS and autonomous vehicles. In at least one embodiment, PVA's capabilities are a good match for algorithmic domains needing predictable processing, at low power and low latency. In other words, PVA performs well on semi-dense or dense regular computation, even on small data sets, which need predictable run-times with low latency and low power. In at least one embodiment, autonomous vehicles, such as vehicle 2000, PVAs are designed to run classic computer vision algorithms, as they are efficient at object detection and operating on integer math.

For example, according to at least one embodiment of technology, PVA is used to perform computer stereo vision. In at least one embodiment, semi-global matching-based algorithm may be used in some examples, although this is not intended to be limiting. In at least one embodiment, applications for Level 3-5 autonomous driving use motion estimation/stereo matching on-the-fly (e.g., structure from motion, pedestrian recognition, lane detection, etc.). In at least one embodiment, PVA may perform computer stereo vision function on inputs from two monocular cameras.

In at least one embodiment, PVA may be used to perform dense optical flow. For example, in at least one embodiment, PVA could process raw RADAR data (e.g., using a 4D Fast Fourier Transform) to provide processed RADAR data. In at least one embodiment, PVA is used for time of flight depth processing, by processing raw time of flight data to provide processed time of flight data, for example.

In at least one embodiment, DLA may be used to run any type of network to enhance control and driving safety, including for example and without limitation, a neural network that outputs a measure of confidence for each object detection. In at least one embodiment, confidence may be represented or interpreted as a probability, or as providing a relative “weight” of each detection compared to other detections. In at least one embodiment, confidence enables a system to make further decisions regarding which detections should be considered as true positive detections rather than false positive detections. For example, In at least one embodiment, a system may set a threshold value for confidence and consider only detections exceeding threshold value as true positive detections. In an embodiment in which an automatic emergency braking (“AEB”) system is used, false positive detections would cause vehicle to automatically perform emergency braking, which is obviously undesirable. In at least one embodiment, highly confident detections may be considered as triggers for AEB. In at least one embodiment, DLA may run a neural network for regressing confidence value. In at least one embodiment, neural network may take as its input at least some subset of parameters, such as bounding box dimensions, ground plane estimate obtained (e.g. from another subsystem), output from IMU sensor(s) 2066 that correlates with vehicle 2000 orientation, distance, 3D location estimates of object obtained from neural network and/or other sensors (e.g., LIDAR sensor(s) 2064 or RADAR sensor(s) 2060), among others.

In at least one embodiment, one or more of SoC(s) 2004 may include data store(s) 2016 (e.g., memory). In at least one embodiment, data store(s) 2016 may be on-chip memory of SoC(s) 2004, which may store neural networks to be executed on GPU(s) 2008 and/or DLA. In at least one embodiment, data store(s) 2016 may be large enough in capacity to store multiple instances of neural networks for redundancy and safety. In at least one embodiment, data store(s) 2016 may comprise L2 or L3 cache(s).

In at least one embodiment, one or more of SoC(s) 2004 may include any number of processor(s) 2010 (e.g., embedded processors). In at least one embodiment, processor(s) 2010 may include a boot and power management processor that may be a dedicated processor and subsystem to handle boot power and management functions and related security enforcement. In at least one embodiment, boot and power management processor may be a part of SoC(s) 2004 boot sequence and may provide runtime power management services. In at least one embodiment, boot power and management processor may provide clock and voltage programming, assistance in system low power state transitions, management of SoC(s) 2004 thermals and temperature sensors, and/or management of SoC(s) 2004 power states. In at least one embodiment, each temperature sensor may be implemented as a ring-oscillator whose output frequency is proportional to temperature, and SoC(s) 2004 may use ring-oscillators to detect temperatures of CPU(s) 2006, GPU(s) 2008, and/or accelerator(s) 2014. In at least one embodiment, if temperatures are determined to exceed a threshold, then boot and power management processor may enter a temperature fault routine and put SoC(s) 2004 into a lower power state and/or put vehicle 2000 into a chauffeur to safe stop mode (e.g., bring vehicle 2000 to a safe stop).

In at least one embodiment, processor(s) 2010 may further include a set of embedded processors that may serve as an audio processing engine. In at least one embodiment, audio processing engine may be an audio subsystem that enables full hardware support for multi-channel audio over multiple interfaces, and a broad and flexible range of audio I/O interfaces. In at least one embodiment, audio processing engine is a dedicated processor core with a digital signal processor with dedicated RAM.

In at least one embodiment, processor(s) 2010 may further include an always on processor engine that may provide necessary hardware features to support low power sensor management and wake use cases. In at least one embodiment, always on processor engine may include, without limitation, a processor core, a tightly coupled RAM, supporting peripherals (e.g., timers and interrupt controllers), various I/O controller peripherals, and routing logic.

In at least one embodiment, processor(s) 2010 may further include a safety cluster engine that includes, without limitation, a dedicated processor subsystem to handle safety management for automotive applications. In at least one embodiment, safety cluster engine may include, without limitation, two or more processor cores, a tightly coupled RAM, support peripherals (e.g., timers, an interrupt controller, etc.), and/or routing logic. In a safety mode, two or more cores may operate, in at least one embodiment, in a lockstep mode and function as a single core with comparison logic to detect any differences between their operations. In at least one embodiment, processor(s) 2010 may further include a real-time camera engine that may include, without limitation, a dedicated processor subsystem for handling real-time camera management. In at least one embodiment, processor(s) 2010 may further include a high-dynamic range signal processor that may include, without limitation, an image signal processor that is a hardware engine that is part of camera processing pipeline.

In at least one embodiment, processor(s) 2010 may include a video image compositor that may be a processing block (e.g., implemented on a microprocessor) that implements video post-processing functions needed by a video playback application to produce final image for player window. In at least one embodiment, video image compositor may perform lens distortion correction on wide-view camera(s) 2070, surround camera(s) 2074, and/or on in-cabin monitoring camera sensor(s). In at least one embodiment, in-cabin monitoring camera sensor(s) are preferably monitored by a neural network running on another instance of SoC(s) 2004, configured to identify in cabin events and respond accordingly. In at least one embodiment, an in-cabin system may perform, without limitation, lip reading to activate cellular service and place a phone call, dictate emails, change vehicle's destination, activate or change vehicle's infotainment system and settings, or provide voice-activated web surfing. In at least one embodiment, certain functions are available to driver when vehicle is operating in an autonomous mode and are disabled otherwise.

In at least one embodiment, video image compositor may include enhanced temporal noise reduction for both spatial and temporal noise reduction. For example, in at least one embodiment, where motion occurs in a video, noise reduction weights spatial information appropriately, decreasing weight of information provided by adjacent frames. In at least one embodiment, where an image or portion of an image does not include motion, temporal noise reduction performed by video image compositor may use information from previous image to reduce noise in current image.

In at least one embodiment, video image compositor may also be configured to perform stereo rectification on input stereo lens frames. In at least one embodiment, video image compositor may further be used for user interface composition when operating system desktop is in use, and GPU(s) 2008 are not required to continuously render new surfaces. In at least one embodiment, when GPU(s) 2008 are powered on and active doing 3D rendering, video image compositor may be used to offload GPU(s) 2008 to improve performance and responsiveness.

In at least one embodiment, one or more of SoC(s) 2004 may further include a mobile industry processor interface (“MIPI”) camera serial interface for receiving video and input from cameras, a high-speed interface, and/or a video input block that may be used for camera and related pixel input functions. In at least one embodiment, one or more of SoC(s) 2004 may further include an input/output controller(s) that may be controlled by software and may be used for receiving I/O signals that are uncommitted to a specific role.

In at least one embodiment, one or more of SoC(s) 2004 may further include a broad range of peripheral interfaces to enable communication with peripherals, audio encoders/decoders (“codecs”), power management, and/or other devices. SoC(s) 2004 may be used to process data from cameras (e.g., connected over Gigabit Multimedia Serial Link and Ethernet), sensors (e.g., LIDAR sensor(s) 2064, RADAR sensor(s) 2060, etc. that may be connected over Ethernet), data from bus 2002 (e.g., speed of vehicle 2000, steering wheel position, etc.), data from GNSS sensor(s) 2058 (e.g., connected over Ethernet or CAN bus), etc. In at least one embodiment, one or more of SoC(s) 2004 may further include dedicated high-performance mass storage controllers that may include their own DMA engines, and that may be used to free CPU(s) 2006 from routine data management tasks.

In at least one embodiment, SoC(s) 2004 may be an end-to-end platform with a flexible architecture that spans automation levels 3-5, thereby providing a comprehensive functional safety architecture that leverages and makes efficient use of computer vision and ADAS techniques for diversity and redundancy, provides a platform for a flexible, reliable driving software stack, along with deep learning tools. In at least one embodiment, SoC(s) 2004 may be faster, more reliable, and even more energy-efficient and space-efficient than conventional systems. For example, in at least one embodiment, accelerator(s) 2014, when combined with CPU(s) 2006, GPU(s) 2008, and data store(s) 2016, may provide for a fast, efficient platform for level 3-5 autonomous vehicles.

In at least one embodiment, computer vision algorithms may be executed on CPUs, which may be configured using high-level programming language, such as C programming language, to execute a wide variety of processing algorithms across a wide variety of visual data. However, in at least one embodiment, CPUs are oftentimes unable to meet performance requirements of many computer vision applications, such as those related to execution time and power consumption, for example. In at least one embodiment, many CPUs are unable to execute complex object detection algorithms in real-time, which is used in in-vehicle ADAS applications and in practical Level 3-5 autonomous vehicles.

Embodiments described herein allow for multiple neural networks to be performed simultaneously and/or sequentially, and for results to be combined together to enable Level 3-5 autonomous driving functionality. For example, in at least one embodiment, a CNN executing on DLA or discrete GPU (e.g., GPU(s) 2020) may include text and word recognition, allowing supercomputer to read and understand traffic signs, including signs for which neural network has not been specifically trained. In at least one embodiment, DLA may further include a neural network that is able to identify, interpret, and provide semantic understanding of sign, and to pass that semantic understanding to path planning modules running on CPU Complex.

In at least one embodiment, multiple neural networks may be run simultaneously, as for Level 3, 4, or 5 driving. For example, in at least one embodiment, a warning sign consisting of “Caution: flashing lights indicate icy conditions,” along with an electric light, may be independently or collectively interpreted by several neural networks. In at least one embodiment, a sign itself may be identified as a traffic sign by a first deployed neural network (e.g., a neural network that has been trained) and a text “flashing lights indicate icy conditions” may be interpreted by a second deployed neural network, which informs vehicle's path planning software (preferably executing on CPU Complex) that when flashing lights are detected, icy conditions exist. In at least one embodiment, a flashing light may be identified by operating a third deployed neural network over multiple frames, informing vehicle's path-planning software of presence (or absence) of flashing lights. In at least one embodiment, all three neural networks may run simultaneously, such as within DLA and/or on GPU(s) 2008.

In at least one embodiment, a CNN for facial recognition and vehicle owner identification may use data from camera sensors to identify presence of an authorized driver and/or owner of vehicle 2000. In at least one embodiment, an always on sensor processing engine may be used to unlock vehicle when owner approaches driver door and turn on lights, and, in security mode, to disable vehicle when owner leaves vehicle. In this way, SoC(s) 2004 provide for security against theft and/or carjacking.

In at least one embodiment, a CNN for emergency vehicle detection and identification may use data from microphones 2096 to detect and identify emergency vehicle sirens. In at least one embodiment, SoC(s) 2004 use CNN for classifying environmental and urban sounds, as well as classifying visual data. In at least one embodiment, CNN running on DLA is trained to identify relative closing speed of emergency vehicle (e.g., by using Doppler effect). In at least one embodiment, CNN may also be trained to identify emergency vehicles specific to local area in which vehicle is operating, as identified by GNSS sensor(s) 2058. In at least one embodiment, when operating in Europe, CNN will seek to detect European sirens, and when in United States CNN will seek to identify only North American sirens. In at least one embodiment, once an emergency vehicle is detected, a control program may be used to execute an emergency vehicle safety routine, slowing vehicle, pulling over to side of road, parking vehicle, and/or idling vehicle, with assistance of ultrasonic sensor(s) 2062, until emergency vehicle(s) passes.

In at least one embodiment, vehicle 2000 may include CPU(s) 2018 (e.g., discrete CPU(s), or dCPU(s)), that may be coupled to SoC(s) 2004 via a high-speed interconnect (e.g., PCIe). In at least one embodiment, CPU(s) 2018 may include an X86 processor, for example. CPU(s) 1918 may be used to perform any of a variety of functions, including arbitrating potentially inconsistent results between ADAS sensors and SoC(s) 2004, and/or monitoring status and health of controller(s) 2036 and/or an infotainment system on a chip (“infotainment SoC”) 2030, for example.

In at least one embodiment, vehicle 2000 may include GPU(s) 2020 (e.g., discrete GPU(s), or dGPU(s)), that may be coupled to SoC(s) 2004 via a high-speed interconnect (e.g., NVIDIA's NVLINK). In at least one embodiment, GPU(s) 2020 may provide additional artificial intelligence functionality, such as by executing redundant and/or different neural networks, and may be used to train and/or update neural networks based at least in part on input (e.g., sensor data) from sensors of vehicle 2000.

In at least one embodiment, vehicle 2000 may further include network interface 2024 which may include, without limitation, wireless antenna(s) 2026 (e.g., one or more wireless antennas 2026 for different communication protocols, such as a cellular antenna, a Bluetooth antenna, etc.). In at least one embodiment, network interface 2024 may be used to enable wireless connectivity over Internet with cloud (e.g., with server(s) and/or other network devices), with other vehicles, and/or with computing devices (e.g., client devices of passengers). In at least one embodiment, to communicate with other vehicles, a direct link may be established between vehicle 2000 and other vehicle and/or an indirect link may be established (e.g., across networks and over Internet). In at least one embodiment, direct links may be provided using a vehicle-to-vehicle communication link. vehicle-to-vehicle communication link may provide vehicle 2000 information about vehicles in proximity to vehicle 2000 (e.g., vehicles in front of, on side of, and/or behind vehicle 2000). In at least one embodiment, aforementioned functionality may be part of a cooperative adaptive cruise control functionality of vehicle 2000.

In at least one embodiment, network interface 2024 may include a SoC that provides modulation and demodulation functionality and enables controller(s) 2036 to communicate over wireless networks. In at least one embodiment, network interface 2024 may include a radio frequency front-end for up-conversion from baseband to radio frequency, and down conversion from radio frequency to baseband. In at least one embodiment, frequency conversions may be performed in any technically feasible fashion. For example, frequency conversions could be performed through well-known processes, and/or using super-heterodyne processes. In at least one embodiment, radio frequency front end functionality may be provided by a separate chip. In at least one embodiment, network interface may include wireless functionality for communicating over LTE, WCDMA, UMTS, GSM, CDMA2000, Bluetooth, Bluetooth LE, Wi-Fi, Z-Wave, ZigBee, LoRaWAN, and/or other wireless protocols.

In at least one embodiment, vehicle 2000 may further include data store(s) 2028 which may include, without limitation, off-chip (e.g., off SoC(s) 2004) storage. In at least one embodiment, data store(s) 2028 may include, without limitation, one or more storage elements including RAM, SRAM, dynamic random-access memory (“DRAM”), video random-access memory (“VRAM”), Flash, hard disks, and/or other components and/or devices that may store at least one bit of data.

In at least one embodiment, vehicle 2000 may further include GNSS sensor(s) 2058 (e.g., GPS and/or assisted GPS sensors), to assist in mapping, perception, occupancy grid generation, and/or path planning functions. In at least one embodiment, any number of GNSS sensor(s) 2058 may be used, including, for example and without limitation, a GPS using a USB connector with an Ethernet to Serial (e.g., RS-232) bridge.

In at least one embodiment, vehicle 2000 may further include RADAR sensor(s) 2060. RADAR sensor(s) 2060 may be used by vehicle 2000 for long-range vehicle detection, even in darkness and/or severe weather conditions. In at least one embodiment, RADAR functional safety levels may be ASIL B. RADAR sensor(s) 2060 may use CAN and/or bus 2002 (e.g., to transmit data generated by RADAR sensor(s) 2060) for control and to access object tracking data, with access to Ethernet to access raw data in some examples. In at least one embodiment, wide variety of RADAR sensor types may be used. For example, and without limitation, RADAR sensor(s) 2060 may be suitable for front, rear, and side RADAR use. In at least one embodiment, one or more of RADAR sensors(s) 2060 are Pulse Doppler RADAR sensor(s).

In at least one embodiment, RADAR sensor(s) 2060 may include different configurations, such as long-range with narrow field of view, short-range with wide field of view, short-range side coverage, etc. In at least one embodiment, long-range RADAR may be used for adaptive cruise control functionality. In at least one embodiment, long-range RADAR systems may provide a broad field of view realized by two or more independent scans, such as within a 250 m range. In at least one embodiment, RADAR sensor(s) 2060 may help in distinguishing between static and moving objects, and may be used by ADAS system 2038 for emergency brake assist and forward collision warning. Sensors 2060(s) included in a long-range RADAR system may include, without limitation, monostatic multimodal RADAR with multiple (e.g., six or more) fixed RADAR antennae and a high-speed CAN and FlexRay interface. In at least one embodiment, with six antennae, central four antennae may create a focused beam pattern, designed to record vehicle 2000's surroundings at higher speeds with minimal interference from traffic in adjacent lanes. In at least one embodiment, other two antennae may expand field of view, making it possible to quickly detect vehicles entering or leaving vehicle 2000's lane.

In at least one embodiment, mid-range RADAR systems may include, as an example, a range of up to 160 m (front) or 80 m (rear), and a field of view of up to 42 degrees (front) or 150 degrees (rear). In at least one embodiment, short-range RADAR systems may include, without limitation, any number of RADAR sensor(s) 2060 designed to be installed at both ends of rear bumper. When installed at both ends of rear bumper, in at least one embodiment, a RADAR sensor system may create two beams that constantly monitor blind spot in rear and next to vehicle. In at least one embodiment, short-range RADAR systems may be used in ADAS system 2038 for blind spot detection and/or lane change assist.

In at least one embodiment, vehicle 2000 may further include ultrasonic sensor(s) 2062. Ultrasonic sensor(s) 2062, which may be positioned at front, back, and/or sides of vehicle 2000, may be used for park assist and/or to create and update an occupancy grid. In at least one embodiment, a wide variety of ultrasonic sensor(s) 2062 may be used, and different ultrasonic sensor(s) 2062 may be used for different ranges of detection (e.g., 2.5 m, 4 m). In at least one embodiment, ultrasonic sensor(s) 2062 may operate at functional safety levels of ASIL B.

In at least one embodiment, vehicle 2000 may include LIDAR sensor(s) 2064. LIDAR sensor(s) 2064 may be used for object and pedestrian detection, emergency braking, collision avoidance, and/or other functions. In at least one embodiment, LIDAR sensor(s) 2064 may be functional safety level ASIL B. In at least one embodiment, vehicle 2000 may include multiple LIDAR sensors 2064 (e.g., two, four, six, etc.) that may use Ethernet (e.g., to provide data to a Gigabit Ethernet switch).

In at least one embodiment, LIDAR sensor(s) 2064 may be capable of providing a list of objects and their distances for a 360-degree field of view. In at least one embodiment, commercially available LIDAR sensor(s) 2064 may have an advertised range of approximately 100 m, with an accuracy of 2 cm-3 cm, and with support for a 100 Mbps Ethernet connection, for example. In at least one embodiment, one or more non-protruding LIDAR sensors 2064 may be used. In such an embodiment, LIDAR sensor(s) 2064 may be implemented as a small device that may be embedded into front, rear, sides, and/or corners of vehicle 2000. In at least one embodiment, LIDAR sensor(s) 2064, in such an embodiment, may provide up to a 120-degree horizontal and 35-degree vertical field-of-view, with a 200 m range even for low-reflectivity objects. In at least one embodiment, front-mounted LIDAR sensor(s) 2064 may be configured for a horizontal field of view between 45 degrees and 135 degrees.

In at least one embodiment, LIDAR technologies, such as 3D flash LIDAR, may also be used. 3D Flash LIDAR uses a flash of a laser as a transmission source, to illuminate surroundings of vehicle 2000 up to approximately 200 m. In at least one embodiment, a flash LIDAR unit includes, without limitation, a receptor, which records laser pulse transit time and reflected light on each pixel, which in turn corresponds to range from vehicle 2000 to objects. In at least one embodiment, flash LIDAR may allow for highly accurate and distortion-free images of surroundings to be generated with every laser flash. In at least one embodiment, four flash LIDAR sensors may be deployed, one at each side of vehicle 2000. In at least one embodiment, 3D flash LIDAR systems include, without limitation, a solid-state 3D staring array LIDAR camera with no moving parts other than a fan (e.g., a non-scanning LIDAR device). In at least one embodiment, flash LIDAR device(s) may use a 5 nanosecond class I (eye-safe) laser pulse per frame and may capture reflected laser light in form of 3D range point clouds and co-registered intensity data.

In at least one embodiment, vehicle may further include IMU sensor(s) 2066. In at least one embodiment, IMU sensor(s) 2066 may be located at a center of rear axle of vehicle 2000, in at least one embodiment. In at least one embodiment, IMU sensor(s) 2066 may include, for example and without limitation, accelerometer(s), magnetometer(s), gyroscope(s), magnetic compass(es), and/or other sensor types. In at least one embodiment, such as in six-axis applications, IMU sensor(s) 2066 may include, without limitation, accelerometers and gyroscopes. In at least one embodiment, such as in nine-axis applications, IMU sensor(s) 2066 may include, without limitation, accelerometers, gyroscopes, and magnetometers.

In at least one embodiment, IMU sensor(s) 2066 may be implemented as a miniature, high performance GPS-Aided Inertial Navigation System (“GPS/INS”) that combines micro-electro-mechanical systems (“MEMS”) inertial sensors, a high-sensitivity GPS receiver, and advanced Kalman filtering algorithms to provide estimates of position, velocity, and attitude. In at least one embodiment, IMU sensor(s) 2066 may enable vehicle 2000 to estimate heading without requiring input from a magnetic sensor by directly observing and correlating changes in velocity from GPS to IMU sensor(s) 2066. In at least one embodiment, IMU sensor(s) 2066 and GNSS sensor(s) 2058 may be combined in a single integrated unit.

In at least one embodiment, vehicle 2000 may include microphone(s) 2096 placed in and/or around vehicle 2000. In at least one embodiment, microphone(s) 2096 may be used for emergency vehicle detection and identification, among other things.

In at least one embodiment, vehicle 2000 may further include any number of camera types, including stereo camera(s) 2068, wide-view camera(s) 2070, infrared camera(s) 2072, surround camera(s) 2074, long-range camera(s) 2098, mid-range camera(s) 2076, and/or other camera types. In at least one embodiment, cameras may be used to capture image data around an entire periphery of vehicle 2000. In at least one embodiment, types of cameras used depends on vehicle 2000. In at least one embodiment, any combination of camera types may be used to provide necessary coverage around vehicle 2000. In at least one embodiment, number of cameras may differ depending on embodiment. For example, in at least one embodiment, vehicle 2000 could include six cameras, seven cameras, ten cameras, twelve cameras, or another number of cameras. Cameras may support, as an example and without limitation, Gigabit Multimedia Serial Link (“GMSL”) and/or Gigabit Ethernet. In at least one embodiment, each of camera(s) is described with more detail previously herein with respect to FIG. 20A and FIG. 20B.

In at least one embodiment, vehicle 2000 may further include vibration sensor(s) 2042. In at least one embodiment, vibration sensor(s) 2042 may measure vibrations of components of vehicle 2000, such as axle(s). For example, in at least one embodiment, changes in vibrations may indicate a change in road surfaces. In at least one embodiment, when two or more vibration sensors 2042 are used, differences between vibrations may be used to determine friction or slippage of road surface (e.g., when difference in vibration is between a power-driven axle and a freely rotating axle).

In at least one embodiment, vehicle 2000 may include ADAS system 2038. ADAS system 2038 may include, without limitation, a SoC, in some examples. In at least one embodiment, ADAS system 2038 may include, without limitation, any number and combination of an autonomous/adaptive/automatic cruise control (“ACC”) system, a cooperative adaptive cruise control (“CACC”) system, a forward crash warning (“FCW”) system, an automatic emergency braking (“AEB”) system, a lane departure warning (“LDW)” system, a lane keep assist (“LKA”) system, a blind spot warning (“BSW”) system, a rear cross-traffic warning (“RCTW”) system, a collision warning (“CW”) system, a lane centering (“LC”) system, and/or other systems, features, and/or functionality.

In at least one embodiment, ACC system may use RADAR sensor(s) 2060, LIDAR sensor(s) 2064, and/or any number of camera(s). In at least one embodiment, ACC system may include a longitudinal ACC system and/or a lateral ACC system. In at least one embodiment, longitudinal ACC system monitors and controls distance to vehicle immediately ahead of vehicle 2000 and automatically adjust speed of vehicle 2000 to maintain a safe distance from vehicles ahead. In at least one embodiment, lateral ACC system performs distance keeping, and advises vehicle 2000 to change lanes when necessary. In at least one embodiment, lateral ACC is related to other ADAS applications such as LC and CW.

In at least one embodiment, CACC system uses information from other vehicles that may be received via network interface 2024 and/or wireless antenna(s) 2026 from other vehicles via a wireless link, or indirectly, over a network connection (e.g., over Internet). In at least one embodiment, direct links may be provided by a vehicle-to-vehicle (“V2V”) communication link, while indirect links may be provided by an infrastructure-to-vehicle (“I2V”) communication link. In general, V2V communication concept provides information about immediately preceding vehicles (e.g., vehicles immediately ahead of and in same lane as vehicle 2000), while I2V communication concept provides information about traffic further ahead. In at least one embodiment, CACC system may include either or both I2V and V2V information sources. In at least one embodiment, given information of vehicles ahead of vehicle 2000, CACC system may be more reliable and it has potential to improve traffic flow smoothness and reduce congestion on road.

In at least one embodiment, FCW system is designed to alert driver to a hazard, so that driver may take corrective action. In at least one embodiment, FCW system uses a front-facing camera and/or RADAR sensor(s) 2060, coupled to a dedicated processor, DSP, FPGA, and/or ASIC, that is electrically coupled to driver feedback, such as a display, speaker, and/or vibrating component. In at least one embodiment, FCW system may provide a warning, such as in form of a sound, visual warning, vibration and/or a quick brake pulse.

In at least one embodiment, AEB system detects an impending forward collision with another vehicle or other object, and may automatically apply brakes if driver does not take corrective action within a specified time or distance parameter. In at least one embodiment, AEB system may use front-facing camera(s) and/or RADAR sensor(s) 2060, coupled to a dedicated processor, DSP, FPGA, and/or ASIC. In at least one embodiment, when AEB system detects a hazard, AEB system typically first alerts driver to take corrective action to avoid collision and, if driver does not take corrective action, AEB system may automatically apply brakes in an effort to prevent, or at least mitigate, impact of predicted collision. In at least one embodiment, AEB system, may include techniques such as dynamic brake support and/or crash imminent braking.

In at least one embodiment, LDW system provides visual, audible, and/or tactile warnings, such as steering wheel or seat vibrations, to alert driver when vehicle 2000 crosses lane markings. In at least one embodiment, LDW system does not activate when driver indicates an intentional lane departure, by activating a turn signal. In at least one embodiment, LDW system may use front-side facing cameras, coupled to a dedicated processor, DSP, FPGA, and/or ASIC, that is electrically coupled to driver feedback, such as a display, speaker, and/or vibrating component. In at least one embodiment, LKA system is a variation of LDW system. LKA system provides steering input or braking to correct vehicle 2000 if vehicle 2000 starts to exit lane.

In at least one embodiment, BSW system detects and warns driver of vehicles in an automobile's blind spot. In at least one embodiment, BSW system may provide a visual, audible, and/or tactile alert to indicate that merging or changing lanes is unsafe. In at least one embodiment, BSW system may provide an additional warning when driver uses a turn signal. In at least one embodiment, BSW system may use rear-side facing camera(s) and/or RADAR sensor(s) 2060, coupled to a dedicated processor, DSP, FPGA, and/or ASIC, that is electrically coupled to driver feedback, such as a display, speaker, and/or vibrating component.

In at least one embodiment, RCTW system may provide visual, audible, and/or tactile notification when an object is detected outside rear-camera range when vehicle 2000 is backing up. In at least one embodiment, RCTW system includes AEB system to ensure that vehicle brakes are applied to avoid a crash. In at least one embodiment, RCTW system may use one or more rear-facing RADAR sensor(s) 2060, coupled to a dedicated processor, DSP, FPGA, and/or ASIC, that is electrically coupled to driver feedback, such as a display, speaker, and/or vibrating component.

In at least one embodiment, conventional ADAS systems may be prone to false positive results which may be annoying and distracting to a driver, but typically are not catastrophic, because conventional ADAS systems alert driver and allow driver to decide whether a safety condition truly exists and act accordingly. In at least one embodiment, vehicle 2000 itself decides, in case of conflicting results, whether to heed result from a primary computer or a secondary computer (e.g., first controller 2036 or second controller 2036). For example, in at least one embodiment, ADAS system 2038 may be a backup and/or secondary computer for providing perception information to a backup computer rationality module. In at least one embodiment, backup computer rationality monitor may run a redundant diverse software on hardware components to detect faults in perception and dynamic driving tasks. In at least one embodiment, outputs from ADAS system 2038 may be provided to a supervisory MCU. In at least one embodiment, if outputs from primary computer and secondary computer conflict, supervisory MCU determines how to reconcile conflict to ensure safe operation.

In at least one embodiment, primary computer may be configured to provide supervisory MCU with a confidence score, indicating primary computer's confidence in chosen result. In at least one embodiment, if confidence score exceeds a threshold, supervisory MCU may follow primary computer's direction, regardless of whether secondary computer provides a conflicting or inconsistent result. In at least one embodiment, where confidence score does not meet threshold, and where primary and secondary computer indicate different results (e.g., a conflict), supervisory MCU may arbitrate between computers to determine appropriate outcome.

In at least one embodiment, supervisory MCU may be configured to run a neural network(s) that is trained and configured to determine, based at least in part on outputs from primary computer and secondary computer, conditions under which secondary computer provides false alarms. In at least one embodiment, neural network(s) in supervisory MCU may learn when secondary computer's output may be trusted, and when it cannot. For example, in at least one embodiment, when secondary computer is a RADAR-based FCW system, a neural network(s) in supervisory MCU may learn when FCW system is identifying metallic objects that are not, in fact, hazards, such as a drainage grate or manhole cover that triggers an alarm. In at least one embodiment, when secondary computer is a camera-based LDW system, a neural network in supervisory MCU may learn to override LDW when bicyclists or pedestrians are present and a lane departure is, in fact, safest maneuver. In at least one embodiment, supervisory MCU may include at least one of a DLA or GPU suitable for running neural network(s) with associated memory. In at least one embodiment, supervisory MCU may comprise and/or be included as a component of SoC(s) 2004.

In at least one embodiment, ADAS system 2038 may include a secondary computer that performs ADAS functionality using traditional rules of computer vision. In at least one embodiment, secondary computer may use classic computer vision rules (if-then), and presence of a neural network(s) in supervisory MCU may improve reliability, safety and performance. For example, in at least one embodiment, diverse implementation and intentional non-identity makes overall system more fault-tolerant, especially to faults caused by software (or software-hardware interface) functionality. For example, in at least one embodiment, if there is a software bug or error in software running on primary computer, and non-identical software code running on secondary computer provides same overall result, then supervisory MCU may have greater confidence that overall result is correct, and bug in software or hardware on primary computer is not causing material error.

In at least one embodiment, output of ADAS system 2038 may be fed into primary computer's perception block and/or primary computer's dynamic driving task block. For example, in at least one embodiment, if ADAS system 2038 indicates a forward crash warning due to an object immediately ahead, perception block may use this information when identifying objects. In at least one embodiment, secondary computer may have its own neural network which is trained and thus reduces risk of false positives, as described herein.

In at least one embodiment, vehicle 2000 may further include infotainment SoC 2030 (e.g., an in-vehicle infotainment system (IVI)). Although illustrated and described as a SoC, infotainment system 2030, in at least one embodiment, may not be a SoC, and may include, without limitation, two or more discrete components. In at least one embodiment, infotainment SoC 2030 may include, without limitation, a combination of hardware and software that may be used to provide audio (e.g., music, a personal digital assistant, navigational instructions, news, radio, etc.), video (e.g., TV, movies, streaming, etc.), phone (e.g., hands-free calling), network connectivity (e.g., LTE, WiFi, etc.), and/or information services (e.g., navigation systems, rear-parking assistance, a radio data system, vehicle related information such as fuel level, total distance covered, brake fuel level, oil level, door open/close, air filter information, etc.) to vehicle 2000. For example, infotainment SoC 2030 could include radios, disk players, navigation systems, video players, USB and Bluetooth connectivity, carputers, in-car entertainment, WiFi, steering wheel audio controls, hands free voice control, a heads-up display (“HUD”), HMI display 2034, a telematics device, a control panel (e.g., for controlling and/or interacting with various components, features, and/or systems), and/or other components. In at least one embodiment, infotainment SoC 2030 may further be used to provide information (e.g., visual and/or audible) to user(s) of vehicle, such as information from ADAS system 2038, autonomous driving information such as planned vehicle maneuvers, trajectories, surrounding environment information (e.g., intersection information, vehicle information, road information, etc.), and/or other information.

In at least one embodiment, infotainment SoC 2030 may include any amount and type of GPU functionality. In at least one embodiment, infotainment SoC 2030 may communicate over bus 2002 (e.g., CAN bus, Ethernet, etc.) with other devices, systems, and/or components of vehicle 2000. In at least one embodiment, infotainment SoC 2030 may be coupled to a supervisory MCU such that GPU of infotainment system may perform some self-driving functions in event that primary controller(s) 2036 (e.g., primary and/or backup computers of vehicle 2000) fail. In at least one embodiment, infotainment SoC 2030 may put vehicle 2000 into a chauffeur to safe stop mode, as described herein.

In at least one embodiment, vehicle 2000 may further include instrument cluster 2032 (e.g., a digital dash, an electronic instrument cluster, a digital instrument panel, etc.). In at least one embodiment, instrument cluster 2032 may include, without limitation, a controller and/or supercomputer (e.g., a discrete controller or supercomputer). In at least one embodiment, instrument cluster 2032 may include, without limitation, any number and combination of a set of instrumentation such as a speedometer, fuel level, oil pressure, tachometer, odometer, turn indicators, gearshift position indicator, seat belt warning light(s), parking-brake warning light(s), engine-malfunction light(s), supplemental restraint system (e.g., airbag) information, lighting controls, safety system controls, navigation information, etc. In some examples, information may be displayed and/or shared among infotainment SoC 2030 and instrument cluster 2032. In at least one embodiment, instrument cluster 2032 may be included as part of infotainment SoC 2030, or vice versa.

Inference and/or training logic are used to perform inferencing and/or training operations associated with one or more embodiments. Details regarding inference and/or training logic are provided herein. In at least one embodiment, inference and/or training logic may be used in system FIG. 20C for inferencing or predicting operations based, at least in part, on weight parameters calculated using neural network training operations, neural network functions and/or architectures, or neural network use cases described herein.

Such components can be used to generate synthetic data imitating failure cases in a network training process, which can help to improve performance of the network while limiting the amount of synthetic data to avoid overfitting.

FIG. 20D is a diagram of a system 2076 for communication between cloud-based server(s) and autonomous vehicle 2000 of FIG. 20A, according to at least one embodiment. In at least one embodiment, system 2076 may include, without limitation, server(s) 2078, network(s) 2090, and any number and type of vehicles, including vehicle 2000. In at least one embodiment, server(s) 2078 may include, without limitation, a plurality of GPUs 2084(A)-2084(H) (collectively referred to herein as GPUs 2084), PCIe switches 2082(A)-2082(D) (collectively referred to herein as PCIe switches 2082), and/or CPUs 2080(A)-2080(B) (collectively referred to herein as CPUs 2080). GPUs 2084, CPUs 2080, and PCIe switches 2082 may be interconnected with high-speed interconnects such as, for example and without limitation, NVLink interfaces 2088 developed by NVIDIA and/or PCIe connections 2086. In at least one embodiment, GPUs 2084 are connected via an NVLink and/or NVSwitch SoC and GPUs 2084 and PCIe switches 2082 are connected via PCIe interconnects. In at least one embodiment, although eight GPUs 2084, two CPUs 2080, and four PCIe switches 2082 are illustrated, this is not intended to be limiting. In at least one embodiment, each of server(s) 2078 may include, without limitation, any number of GPUs 2084, CPUs 2080, and/or PCIe switches 2082, in any combination. For example, in at least one embodiment, server(s) 2078 could each include eight, sixteen, thirty-two, and/or more GPUs 2084.

In at least one embodiment, server(s) 2078 may receive, over network(s) 2090 and from vehicles, image data representative of images showing unexpected or changed road conditions, such as recently commenced road-work. In at least one embodiment, server(s) 2078 may transmit, over network(s) 2090 and to vehicles, neural networks 2092, updated neural networks 2092, and/or map information 2094, including, without limitation, information regarding traffic and road conditions. In at least one embodiment, updates to map information 2094 may include, without limitation, updates for HD map 2022, such as information regarding construction sites, potholes, detours, flooding, and/or other obstructions. In at least one embodiment, neural networks 2092, updated neural networks 2092, and/or map information 2094 may have resulted from new training and/or experiences represented in data received from any number of vehicles in environment, and/or based at least in part on training performed at a data center (e.g., using server(s) 2078 and/or other servers).

In at least one embodiment, server(s) 2078 may be used to train machine learning models (e.g., neural networks) based at least in part on training data. In at least one embodiment, training data may be generated by vehicles, and/or may be generated in a simulation (e.g., using a game engine). In at least one embodiment, any amount of training data is tagged (e.g., where associated neural network benefits from supervised learning) and/or undergoes other pre-processing. In at least one embodiment, any amount of training data is not tagged and/or pre-processed (e.g., where associated neural network does not require supervised learning). In at least one embodiment, once machine learning models are trained, machine learning models may be used by vehicles (e.g., transmitted to vehicles over network(s) 2090, and/or machine learning models may be used by server(s) 2078 to remotely monitor vehicles.

In at least one embodiment, server(s) 2078 may receive data from vehicles and apply data to up-to-date real-time neural networks for real-time intelligent inferencing. In at least one embodiment, server(s) 2078 may include deep-learning supercomputers and/or dedicated AI computers powered by GPU(s) 2084, such as a DGX and DGX Station machines developed by NVIDIA. However, in at least one embodiment, server(s) 2078 may include deep learning infrastructure that use CPU-powered data centers.

In at least one embodiment, deep-learning infrastructure of server(s) 2078 may be capable of fast, real-time inferencing, and may use that capability to evaluate and verify health of processors, software, and/or associated hardware in vehicle 2000. For example, in at least one embodiment, deep-learning infrastructure may receive periodic updates from vehicle 2000, such as a sequence of images and/or objects that vehicle 2000 has located in that sequence of images (e.g., via computer vision and/or other machine learning object classification techniques). In at least one embodiment, deep-learning infrastructure may run its own neural network to identify objects and compare them with objects identified by vehicle 2000 and, if results do not match and deep-learning infrastructure concludes that AI in vehicle 2000 is malfunctioning, then server(s) 2078 may transmit a signal to vehicle 2000 instructing a fail-safe computer of vehicle 2000 to assume control, notify passengers, and complete a safe parking maneuver.

In at least one embodiment, server(s) 2078 may include GPU(s) 2084 and one or more programmable inference accelerators (e.g., NVIDIA's TensorRT 3). In at least one embodiment, combination of GPU-powered servers and inference acceleration may make real-time responsiveness possible. In at least one embodiment, such as where performance is less critical, servers powered by CPUs, FPGAs, and other processors may be used for inferencing. In at least one embodiment, inference and/or training logic are used to perform one or more embodiments. Details regarding inference and/or training logic are provided elsewhere herein.

Such components may be used to generate synthetic data imitating failure cases in a network training process, which may help to improve performance of the network while limiting the amount of synthetic data to avoid overfitting.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. Term “connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. Use of term “set” (e.g., “a set of items”) or “subset,” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B, and at least one of C each to be present. In addition, unless otherwise noted or contradicted by context, term “plurality” indicates a state of being plural (e.g., “a plurality of items” indicates multiple items). A plurality is at least two items, but may be more when so indicated either explicitly or by context. Further, unless stated otherwise or otherwise clear from context, phrase “based on” means “based at least in part on” and not “based solely on.”

Operations of processes described herein may be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. A set of non-transitory computer-readable storage media, in at least one embodiment, comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

All references, including publications, patent applications, and patents, cited herein are hereby incorporated by reference to same extent as if each reference were individually and specifically indicated to be incorporated by reference and were set forth in its entirety herein.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. Terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. Obtaining, acquiring, receiving, or inputting analog and digital data may be accomplished in a variety of ways such as by receiving data as a parameter of a function call or a call to an application programming interface. In some implementations, process of obtaining, acquiring, receiving, or inputting analog or digital data may be accomplished by transferring data via a serial or parallel interface. In another implementation, process of obtaining, acquiring, receiving, or inputting analog or digital data may be accomplished by transferring data via a computer network from providing entity to acquiring entity. References may also be made to providing, outputting, transmitting, sending, or presenting analog or digital data. In various examples, process of providing, outputting, transmitting, sending, or presenting analog or digital data may be accomplished by transferring data as an input or output parameter of a function call, a parameter of an application programming interface or interprocess communication mechanism.

Although discussion above sets forth example implementations of described techniques, other architectures may be used to implement described functionality, and are intended to be within scope of this disclosure. Furthermore, although specific distributions of responsibilities are defined above for purposes of discussion, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A method comprising:
detecting a first action associated with an asset of an environment in accordance with a simulation of the asset in the environment;
identifying short-term historical data associated with the asset, wherein the short-term historical data comprises one or more first prior simulation events of the simulation associated with the asset that occurred during a first time period;
determining, based on long-term historical data comprising one or more simulation events associated with one or more assets of the environment that occurred during a second time period that is longer than and comprises the first time period, one or more second prior simulation events of the simulation associated with at least one of the first action or an additional asset in the environment; and
generating a simulation command for a second action associated with the asset in accordance with the simulation of the asset in the environment based on the one or more first prior simulation events and the one or more second prior simulation events.

2. The method of claim 1, wherein identifying the short-term historical data associated with the asset comprises:
determining an identifier (ID) associated with the asset;
identifying one or more entries of a short-term historical data structure corresponding to the determined ID, wherein the short-term historical data structure comprises short-term historical data associated with at least one of the one or more assets of the environment in accordance with the simulation; and
extracting the short-term historical data associated with the asset from the identified one or more entries.

3. The method of claim 1, further comprising:
obtaining a natural language description of a scene of the simulation in view of the first action associated with the asset;
identifying one or more entries of a long-term historical data structure that satisfy one or more relevance criteria based at least on the obtained natural language description; and
extracting the long-term historical data from the identified one or more entries.

4. The method of claim 3, wherein identifying the one or more entries of the long-term historical data structure that satisfy the one or more relevance criteria based on the obtained natural language description comprises:
obtaining a relevance score for at least one of the identified one or more entries; and
determining that the obtained relevance score for at least one of the identified one or more entries exceeds a threshold relevance score.

5. The method of claim 4, wherein obtaining the relevance score for at least one of the identified one or more entries comprises:
providing the natural language description of the scene as an input to a simulation event relevance artificial intelligence (AI) model;
obtaining one or more outputs of the simulation event relevance AI model, wherein the one or more outputs comprise a set of relevance scores each corresponding to a respective entry of a portion of entries of the long-term historical data structure, the portion of the entries comprising the identified one or more entries; and
extracting the relevance score for at least one of the identified one or more entries from the set of relevance scores.

6. The method of claim 1, wherein generating the simulation command comprises:
providing an indication of the one or more first prior simulation events and the one or more second prior simulation events as an input to a command generation AI model;
obtaining one or more outputs of the command generation AI model, wherein the one or more outputs comprise a set of simulation commands pertaining to actions associated with the asset in accordance with the simulation; and
extracting the simulation command for the second action from the set of simulation commands.

7. The method of claim 1, wherein the asset comprises at least one of: a virtual object, a virtual avatar, or a non-playable character.

8. The method of claim 1, further comprising:
executing, by one or more processors, the simulation command to cause the second action associated with the asset to be performed in accordance with the simulation of the asset, wherein the one or more processors are comprised in at least one of:
a control system for an autonomous or semi-autonomous machine;
a perception system for an autonomous or semi-autonomous machine;
a system for performing simulation operations;
a system for performing digital twin operations;
a system for performing light transport simulation;
a system for performing collaborative content creation for three-dimensional (3D) assets;
a system for performing deep learning operations;
a system implemented using an edge device;
a system implemented using a robot;
a system for performing conversational AI operations;
a system for performing operations using one or more large language models (LLMs);
a system for performing operations using one or more small language models (SLMs);
a system for performing operations using one or more vision language models (VLMs);
a system for performing operations using one or more multi-modal language models (MMLMs);
a system for performing synthetic data generation;
a system for generating synthetic data using AI;
a system for presenting at least one of virtual reality content, augmented reality content, or mixed reality content;
a system incorporating one or more virtual machines (VMs);
a system using or deploying one or more inference microservices;
a system that incorporates one or more machine learning models deployed in a service or microservice along with an OS-level virtualization package;
a system implemented at least partially in a data center; or
a system implemented at least partially using cloud computing resources.

9. A system comprising:
a memory; and
a set of one or more processors coupled to the memory, the set of one or more processors to perform operations comprising:
receiving data associated with a current scene of a simulation including one or more assets in a simulated environment;
generating a scene description of the current scene based on the received data and short-term historical data associated with at least one of the one or more assets, wherein the short-term historical data comprises one or more prior simulation events of the simulation, the one or more prior simulation events associated with the one or more assets that occurred during a prior time window preceding a current time window associated with the current scene;
updating a simulation memory data store to include the generated scene description; and
modifying the current scene of the simulation based on the updated simulation memory data store.

10. The system of claim 9, wherein generating the scene description of the current scene comprises:
providing the received data and the short-term historical data as an input to a scene description generator artificial intelligence (AI) model; and
obtaining one or more outputs of the scene description generator AI model, wherein the one or more outputs comprise the generated scene description.

11. The system of claim 9, wherein the operations further comprise:
providing the scene description as an input to an embedding engine;
obtaining one or more outputs of the embedding engine, the one or more outputs comprising a fixed-length embedding vector representing the scene description; and
updating the simulation memory data store to further comprise the fixed-length embedding vector.

12. The system of claim 9, wherein the operations further comprise:
updating a short-term historical data structure to include a simulation event indicating the generated scene description, wherein the short-term historical data structure stores the short-term historical data associated with the one or more assets of the simulated environment.

13. The system of claim 12, wherein updating the simulation memory data store to further comprise the generated scene description comprises:
determining that one or more time period criteria associated with the simulation event indicating the generated scene description are satisfied;
responsive to the determination, copying the generated scene description to an entry of the simulation memory data store; and
removing the simulation event indicating the generated scene description from the short-term historical data structure.

14. The system of claim 9, wherein modifying the current scene of the simulation based on the updated simulation memory data store comprises:
detecting an action associated with at least one asset of the one or more assets in the simulated environment;
obtaining a natural language description of the current scene of the simulation in view of the action;
determining that a degree of relevance between the natural language description of the current scene and the generated scene description satisfies one or more relevancy criteria;
responsive to the determination, providing at least the natural language description of the current scene and the generated scene description as an input to a command generation AI model;
obtaining one or more outputs of the command generation AI model, the one or more outputs of the comprising a set of simulation commands pertaining to additional actions associated with the asset in accordance with the simulation; and
executing at least one of the set of commands to modify the current scene of the simulation.

15. The system of claim 9, wherein the system is comprised in at least one of:
a control system for an autonomous or semi-autonomous machine;
a perception system for an autonomous or semi-autonomous machine;
a system for performing simulation operations;
a system for performing digital twin operations;
a system for performing light transport simulation;
a system for performing collaborative content creation for three-dimensional (3D) assets;
a system for performing deep learning operations;
a system implemented using an edge device;
a system implemented using a robot;
a system for performing conversational AI operations;
a system for performing operations using one or more large language models (LLMs);
a system for performing operations using one or more small language models (SLMs);
a system for performing operations using one or more vision language models (VLMs);
a system for performing operations using one or more multi-modal language models (MMLMs);
a system for performing synthetic data generation;
a system for generating synthetic data using AI;
a system for presenting at least one of virtual reality content, augmented reality content, or mixed reality content;
a system incorporating one or more virtual machines (VMs);
a system using or deploying one or more inference microservices;
a system that incorporates one or more machine learning models deployed in a service or microservice along with an OS-level virtualization package;
a system implemented at least partially in a data center; or
a system implemented at least partially using cloud computing resources.

16. At least one processor comprising processing circuitry to:
detect a first action associated with an asset of an environment in accordance with a simulation of the environment;
identify short-term historical data associated with the asset, wherein the short-term historical data comprises one or more first prior simulation events of the simulation associated with the asset that occurred during a first time period;
determine, based on long-term historical data comprising one or more simulation events associated with one or more assets of the environment that occurred during a second time period that is longer than and comprises the first time period, one or more second prior simulation events of the simulation associated with at least one of the first action or an additional asset in the environment; and
generate a simulation command for a second action associated with the asset in accordance with the simulation of the environment based on the one or more first prior simulation events and the one or more second prior simulation events.

17. The at least one processor of claim 16, wherein to identify the short-term historical data associated with the asset, the processing circuitry is to:
determine an identifier (ID) associated with the asset;
identify one or more entries of a short-term historical data structure corresponding to the determined ID, wherein the short-term historical data structure comprises short-term historical data associated with at least one of the one or more assets of the environment in the simulation; and
extract the short-term historical data associated with the asset from the identified one or more entries.

18. The at least one processor of claim 16, wherein the processing circuitry is further to:
obtain a natural language description of a scene of the simulation in view of the first action associated with the asset;
identify one or more entries of a long-term historical data structure that satisfy one or more relevance criteria based at least on the obtained natural language description; and
extract the long-term historical data from the identified one or more entries.

19. The at least one processor of claim 18, wherein to identify the one or more entries of the long-term historical data structure that satisfy the one or more relevance criteria based on the obtained natural language description, the processing circuitry is further to:
obtain a relevance score for at least one of the identified one or more entries; and
determine that the obtained relevance score for at least one of the identified one or more entries exceeds a threshold relevance score.

20. The at least one processor of claim 19, wherein the at least one processor is comprised in at least one of:
a control system for an autonomous or semi-autonomous machine;
a perception system for an autonomous or semi-autonomous machine;
a system for performing simulation operations;
a system for performing digital twin operations;
a system for performing light transport simulation;
a system for performing collaborative content creation for three-dimensional (3D) assets;
a system for performing deep learning operations;
a system implemented using an edge device;
a system implemented using a robot;
a system for performing conversational AI operations;
a system for performing operations using one or more large language models (LLMs);
a system for performing operations using one or more small language models (SLMs);
a system for performing operations using one or more vision language models (VLMs);
a system for performing operations using one or more multi-modal language models (MMLMs);
a system for performing synthetic data generation;
a system for generating synthetic data using AI;
a system for presenting at least one of virtual reality content, augmented reality content, or mixed reality content;
a system incorporating one or more virtual machines (VMs);
a system using or deploying one or more inference microservices;
a system that incorporates one or more machine learning models deployed in a service or microservice along with an OS-level virtualization package;
a system implemented at least partially in a data center; or
a system implemented at least partially using cloud computing resources.
